(19) United States
(12) Patent Application Publication
(10) Pub. No.: US 2025/0021707 A1
(43) Pub. Date: Jan. 16, 2025

(54) BUILDING STRUCTURE AUTOMATIC DESIGN AND AUTOMATIC DRAWING

(71) Applicant: Shisheng Pan, Parsippany, NJ (US)

(72) Inventor: Shisheng Pan, Parsippany, NJ (US)

(21) Appl. No.: 18/896,524

(22) Filed: Sep. 25, 2024

Related U.S. Application Data
(63) Continuation-in-part of application No. 29/940,686, filed on May 3, 2024.

(30) Foreign Application Priority Data
Mar. 7, 2024 (CN) 202410258437.9
Mar. 7, 2024 (CN) 202430114404.8

(51) Int. Cl. G06F 30/12; G06F 30/13; G06F 30/23

(52) U.S. Cl. CPC G06F 30/12; G06F 30/13; G06F 30/23

(57) ABSTRACT

A method for automatic design and automatic drawing of building structures is implemented by operating a graphical display interface and a control operation via FSDT and AUD programs. With FSDT program, the user can obtain structural items from architectural drawings, draw and modify columns, walls, beams, slabs, and drop panels, add point loads, line loads, and slab load automatically, set up Ready-to-Run Etabs model and Safe model automatically, design and check concrete column one by one automatically. The user can transfer the Etabs and Safe results into FSDT and AUD programs automatically. With AUD program, the user can get structural drawing information from FSDT program and architectural drawings automatically, make Typical Pile Cap Details and add pile caps on plan automatically, draw and modify shear wall plans, plan rebars, column schedule, Typical Pile Cap Details, CAD Beam, column above-below symbols, column number symbols, section symbols, different elevation symbols automatically.

### CROSS-REFERENCE TO RELATED PATENT APPLICATION

This application is a U.S. Utility Patent Application which claims priority to currently pending Chinese Utility Patent Application Serial No.202410258437.9 filed on Mar. 7, 2024, Chinese Design Patent Application Serial No. 202430114404.8 filed on Mar. 7, 2024, and U.S. Design patent application No. 29/940,686 filed May 3, 2024, the contents of all of which are hereby incorporated by reference in their entireties.

### FIELD OF THE DISCLOSURE

The invention discloses a method for the design and drawing of building structures. In particular, the method is related to automatic design and automatic drawing of a concrete building structure. The method is implemented by operating a graphical display interface used to display drawing results, and a control operation interface used to display parameters and command function keys, receive user operation commands, and perform automatic design and automatic drawing of building structures.

### BACKGROUND OF THE DISCLOSURE

The purpose of building structure design is to design the building structure and make the structural drawings, such as Floor Framing Plan, Column Schedule, Shear Wall Plan, Foundation Plan, Typical Details, Sections and others, based on architectural drawings and the calculation results of Etabs and Safe programs.

In the process of building structure design, structural engineers need to obtain structural items from architectural drawings, including columns, walls, slab, slab opens and others into structural drawings. Usually, many structural engineers do it with the AutoCAD program, which is time consuming. Some software can import structural items from architectural drawings directly, but there is still a lot of subsequent work to do.

Many structure engineers use Etabs and Safe programs to analyze the structure of the concrete building. Hence, they need to add all columns, walls, slabs, slab opens and others in Etabs and Safe programs. This is time consuming. One may import the floor data from AutoCAD drawings into Etabs directly, but after importing the data, there are still a lot of things to do in order to run the Etabs model. Safe program has the same drawbacks.

After Run Etabs model, structural engineers get some forces for structural items, some initial reinforcement for structural items, then they need use some forces to design structural items, need a simply automatic way to show force somewhere in structure. Same thing for reinforcement in structural items, structure engineers need a simply automatic way to show reinforcement somewhere, and automatically transfer them to the rebars shown in the CAD drawings. Unfortunately, now lot of these things are done by hand with AutoCAD.

After finishing the building structure design, structural engineers need to make structural drawings. At present, structural engineers still often use AutoCAD to perform this task. AutoCAD is indeed a very good drawing tool, very convenient to use, and can be used in almost all industries. However, it is designed for almost all industries and is not professional-specific software. For example, it is not specially for building structural drawings. One significant drawback is that it does not have special units for columns, walls, and beams. Columns, walls, and beams can only be drawn by drawing some lines.

Thus, the basic unit of AutoCAD is merely a line, a circle, or a word. Although AutoCAD can make several lines together to make a block of a beam, it is inconvenient to change. A user needs to use a block editor, and there is no way to connect it with other structural items.

Assuming one needs to copy some structural items from one floor to another floor, In AutoCAD, if it is one file for one floor, and the coordinates are the same, one does not need base points to copy and paste, but the user needs to open two files at the same time. If all the floors are in one file in AutoCAD, just opening one file is enough, but copying and pasting without base points are not possible.

When structural engineers perform building design and drawing, they often need to change a column size and location, change the wall dimension, add more beams, etc. They need to tell an architect to change the column size, location, and wall dimensions. They need to change them in structural drawings, in calculation model, such as Etabs model and Safe model. This is very time-consuming. Every structural engineer hopes that there is a program to perform this task automatically. Hopefully, if there are some changes in architectural drawings, like just changing a column size and location, then the structural drawings and Etabs and Safe models will change automatically based on the new architectural drawings.

### SUMMARY OF THE INVENTION

The basic unit of the instant invention is a wall, a beam, a column, a floor slab, or other structural items, and this unit even includes the unit mark and its property. As for a beam, FSDT program can just click one or two points on screen, then a beam is added, including the data of beam such as beam size, beam mark, loads and others. Sometimes, clicking is not even required, such as when adding slab edge beams. By just clicking a button, more than fifty edge beams can be added.

This invention enables the function of treating the beam as a block, and it is very easy to modify some lines in the beam and automatically link them to other structural items. Furthermore, a lot of drawing work does not need to be done manually based on this invention. The program will automatically complete those drawing work, such as adding reinforcements to the plan. The program can automatically fix the error when the walls obtained from architectural drawings are not connected correctly.

Our invention makes three parts: architectural drawings, structural drawings and calculation model in one system, with structural items for three parts being all automatically associated.

In this invention, all floors are in one file and in the same coordinate system. Therefore, the columns can be aligned up and down for all floors. One can copy and paste items from one floor to another floor without base points.

The invention introduces a Flor Structural Data Transfer Program (FSDT). FSDT is a software program that can obtain floor structural data from AutoCAD Drawings automatically and setup Ready-to-Run Etabs model automatically. Hence, this invention has overcome the prior arts' time-consuming problem of adding the structural items in Etabs to make a model.

With a lot of powerful functions as shown below, after importing the floor data from AutoCAD drawings into this FSDT program, it is very easy and fast to edit the columns, beams, walls, and slabs, change the dimensions, add loads, assign concrete strengths, etc. Then a user can get Ready-to-Run Etabs and Safe models automatically. Importing the data made by FSDT into Etabs and Safe programs, the user can run the model immediately. Furthermore, once one finishes running the Etabs model, the user can transfer the Etabs results, such as column forces, wall reactions, and shear wall reinforcement into this FSDT program, and then export them to Excel file to read the Etabs result easily. The user can also transfer the Safe results into FSDT program.

In addition, the invention also encompasses AUD program which can receive the concrete reinforcement from Etabs and the floor slab reinforcement from Safe program. AUD is a software program that allows a user to draw structural drawings automatically. AUD program can get information from architectural drawings automatically, draw the foundation, drop panel, the rebar on the structural plan automatically, draw column number symbols, CAD beams, section symbols, column above-below symbols, and others on plan automatically, make column schedule CAD drawing automatically, make pile cap typical details automatically, make column and wall locations (X, Y coordinates) plan automatically, etc. All drawings made in AUD program can be exported into AutoCAD.

In FSDT program, the user can input the story data, obtain structural items from AutoCAD architectural drawings, including columns, walls, beams, slabs and other structural items, then the user can add, delete, move and edit grid lines, columns, walls, beams, change floor slab dimensions, assign slab property, slab thickness and loads, add the floor dead and live loads, add the line load for wall weight around floor perimeter, add point loads, can add point loads on floor slab for above columns automatically, input the wind load and seismic load, assign concrete strength to all columns, walls, beams and slabs. Set-up ready to run Etabs model, export Etabs model e2k file for whole building automatically. Set-up ready to run Safe model, export Safe model f2k file for each floor of whole building automatically. All columns, walls, beams, slab dimensions and other structural items, dead load, live load, wind load and seismic load, concrete strength, load combination, are all imported into analysis model Etabs and Safe programs automatically.

Then the user can transfer the Etabs results, such as column forces, wall reactions and shear wall reinforcement into FSDT. Transfer the Safe results, such as column forces and wall reactions into FSDT, and slab reinforcement into AUD.

Specially, the invention can design and check all concrete columns for whole building with slenderness considered automatically with FSDT program, make AutoCAD column schedule with AUD program automatically.

With AUD program, the user can get structural drawing information from FSDT program and architectural drawings, make Typical Pile Cap Details and add piles on plan automatically, draw shear wall plan automatically, draw plan rebars automatically, draw CAD beams, column above-below symbols, column number symbols, section symbols and different elevation symbols automatically, draw Typical Pile Cap Details automatically.

The method is implemented by operating a graphical display interface and a control operation interface operatively coupled with the graphical display interface. The graphical display interface is used to display drawing results, and the control operation interface is operatively coupled with a processor and used to display parameters and commands, function keys, receive user operation commands, perform automatic processing of structural design, calculate model establishment, and make structural drawings. The method includes:
Step 1: Read the architectural drawings, obtain structural item information and other non-structural item information related to the structural drawings from the architectural drawings, add FL Lines and base points automatically. Structural items include grid lines, columns, walls, beams, floor slabs and slab opens, information related to structural drawings includes stairs, elevators and CMU walls, etc.
Step 2: Edit the structural items and add loads automatically. The editing of the structural items includes the automatic addition and modification of columns, walls, beams, floor slabs, slab opens, and drop panels, comparison and adjustment of columns between associated floors. Adding loads including floor loads, line loads and point loads on slabs and beams.
Step 3: Export the whole building calculation model data file for Etabs, and floor data file for Safe automatically. Etabs and Safe programs can import the calculation model data file and run the model immediately. If the calculation results meet the predetermined standards, go to step 5, otherwise go to step 4.
Step 4: Obtain the calculation results from the Etabs and Safe programs, adjust and edit the structure items according to the calculation results, and repeat step 3.
Step 5: Design and check all column capacities for whole building with slenderness considered automatically in FSDT and make column schedule automatically with AUD program.
Step 6: Based on Safe results, design beams and make floor framing plans automatically, including CAD beams and slab reinforcement with AUD program.
Step 7: Based on Etabs results, design foundation automatically, including pile cap and footing, and make foundation plan drawings with AUD program automatically.
Step 8: Draw and modify column above-below symbols, section symbols, CAD beams, column number symbols, different elevation symbols and others automatically with AUD program.
Step 9: Based on Etabs results, design shear walls and make shear wall plans automatically with AUD program.
Step 10: Draw and modify CAD drawings for Typical Pile Cap Details automatically with AUD program.
Step 11: Export special Architectural items as the background of structural drawings automatically, which include columns, walls, slabs, opens, Stair, CMU walls, and others.
Step 12: Display or print the structural drawings.

Embodiments of the present disclosure may include: in All user interfaces of FSDT and AUD programs, all order numbers for buttons, checkboxs and others can be shown with one click, then the user can find them in the manual of program easily, since the order numbers of buttons, checkboxs or others in manual are same as in the user interfaces of FSDT and AUD programs. In the same way, if the user likes to find where the item is (the item that is shown in the manual) on the interfaces of FSDT and AUID programs, it can be found very easily based on the order number in the manual.

Embodiments of the present disclosure may include: in FSDT and AUD programs, all command buttons, the parameters of structural items are put in one special user interface so that they can be always seen and can be clicked immediately when needed. At this time, the main drawing layout can be placed on the main monitor, and the user interface dedicated to placing command buttons and parameters can be placed on another monitor. In this way, it is very convenient and fast to operate. The purpose of the FSDT and AUD programs is to minimize operation time, thereby reducing design and drawing time.

Embodiments of the present disclosure may include: when add column or beam, section definition is no more required in FSDT and AUD programs, now it is made automatically when need. To add a beam with FSDT program, the user only needs to open a beam interface, and confirm or input the beam width, beam height, dead load and live load, then add the beam on plan automatically. The beam section dimensions and parameters are always shown in the interface. Column, walls and pile cap can also be added in the same way, without loads, and the definition of the pile cap is made automatically during the process of addition.

Embodiments of the present disclosure may include: obtaining structural items from architectural drawings into FSDT and AUD programs automatically.

Embodiments may also include: reading the contents of AutoCAD architectural drawing files. Selecting one structure item in a floor of the architectural drawing and clicking the “Add” function key to automatically obtain the structural items of this type with the same layer for all floors in the architectural drawings. Selecting all other types of structure items in the architectural drawings in sequence, and automatically obtaining all information on all types of structure items on all floors in the architectural drawings. If a structure item has more than one CAD layer, selecting each layer of the structure in the architectural drawings to automatically obtain the information of a structure item for all CAD layers in the architectural drawings.

Embodiments may also include: all AutoCAD layer names for all structural items and parameters information are automatically saved, so next time some structural items are changed in the architectural drawings, just importing the architectural drawings again, the user obtains structural items from architectural drawings automatically, and the structural model is automatically generated immediately based on the saved AutoCAD layer names and parameters information.

Embodiments may also include: the saved all AutoCAD layer names for all structural items and other parameters are shown in some special tables, the user can change the layer names, delete and add the layer names directly, change some parameters, to let the user change and control the final structural items easily. FSDT program even can save the layer names for different projects and different situations.

Embodiments may also include: adding a virtual floor FL0 at the coordinate origin. Adding base points in all real floors and in FL0. When transferring the structural items in the architectural drawing to the structural drawing, moving the structural items according to the relationship between each floor base point and the FL0 base point so that all the base point positions of the real floor are the same as the FL0 base point, the real floors are moved to near the coordinate origin, and all floors are automatically aligned up and down.

Embodiments may also include: selecting multiple straight lines around the open location in sequence on the graphical user interface, clicking the “Add Open” function key to automatically add a rectangular slab open in the area surrounded by the selected straight lines.

Embodiments may also include: as an alternative method, just inputting the CAD layer names for columns, walls and other structural items which are in architectural drawings. Then, the user can import structural floor data from architectural drawings directly and automatically. For this method, the user needs to make a special AutoCAD drawing, called FSDT drawing, which includes all structural items and some necessary information. The user needs to add FL lines and base points for each floor. Then, using the FSDT program to import this FSDT drawing to make the FSDT model directly. There are many options in this method.

Embodiments of the present disclosure may include: drawing and modifying the grid lines automatically.

Embodiments may also include: there are X Grid Line Table and Y Grid Line Table. Adding grid lines and changing the grid lines with these two tables automatically. Reordering the grid lines by clicking one button with Delt R=0 automatically. Clicking a button to add grid lines at wall points, column points, slab points. Clicking a button to move some points on structural items to grid lines based on Delt R value automatically. Exporting the grid lines information to Excel file, making some changes and then importing the grid lines information from Excel file to FSDT.

Embodiments of the present disclosure may include: drawing and modifying columns automatically.

Embodiments may also include: adding columns, transferring columns to walls, finding and deleting duplicate columns automatically. Changing the column sizes, moving columns and deleting columns easily and automatically. Assigning column numbers with certain rule automatically, for one floor and all floors, can reorder the column numbers automatically.

Embodiments may also include: showing columns and walls above or below, then the user can compare the columns for two floors, to see if the column is continuous to go or stop at some floor, to see the columns are aligned or not, to find pick-up columns. The user can match all column centers of one floor to another floor, match all column sizes of one floor to another floor.

Embodiments may also include: after getting the columns from architectural drawings, the user may click a button to use the columns below for current floor or for all floors automatically.

Embodiments of the present disclosure may include drawing and modifying walls automatically.

Embodiments may also include: adding wall with two methods, one is to input X and Y coordinates of a wall in the Wall Point Table, another one is to input wall center line and thickness in Wall Line Table.

Embodiments may also include: connecting some lines which are not connected together to form real walls automatically when importing walls from architectural drawing.

Embodiments may also include: after getting the walls from architectural drawings, the user can click a button to use the walls below for current floor or for all floors automatically.

Embodiments may also include: inputting wall numbers, wall thickness, then clicking a button to assign the wall thickness, or assigning the wall thickness on screen by clicking one wall by one wall,

Embodiments may also include: correcting the walls for some mistakes automatically. Cutting the shear walls into some part-walls automatically and importing into Etabs model to meet some calculation requirements. Combining walls automatically if they are next each other. Cutting a wall automatically if another wall is connected to this wall at middle to let two walls connect together.

Embodiments of the present disclosure may include: drawing and modifying beams automatically.

Embodiments may also include: there are two kinds of beams, edge beam and interior beam. Edge beams are used for line loads of exterior walls around the perimeters of building. Clicking a button to add edge beams around the perimeters of slabs which are composed of all Non-Roof-Sub-Slabs and on parapets automatically. Interior beams are the real beams, which can be imported from AutoCAD drawings, or added by FSDT program

Embodiments may also include: clicking two points on screen to add beams, the beam size and load are added together at the same time automatically.

Embodiments may also include: changing or assigning the beam sizes and loads on beams with beam property table or screen assigning automatically. Deleting beam, extending beam, cutting beam to make them connected together at cross point, dividing long beam to short beam as required, and trimming beam with pile cap and footing automatically.

Embodiments may also include: there is an Interior Beam Table. The user can see the beam properties for all added interior beams in this table, including beam Label, beam Mark, beam size and beam loads. The user can change the beam properties by retype them in this table.

Embodiments may also include: clicking a button to let the columns and walls above the current floor be shown on plan, then the user can add a beam for pickup column or wall easily. Assigning the beam line load based on the wall force at the specified floor.

Embodiments of the present disclosure may include: drawing and modifying slabs automatically.

Embodiments may also include: whole one floor concrete slab is called Slab0. Slab0 is separated into Sub-Slab based on their different thickness or different loads. Open is also considered as Sub-Slab. Slab properties include slab coordinates, thickness, dead load DL, live load LL and slab type. Slab type includes Etabs, Safe, Both, Etabs Open, Safe Open, Both Open, None. None means the slab is not in Etabs and Safe model. Slab0 always is None, cannot be changed.

Embodiments may also include: adding point loads on floor slab for above columns automatically. Getting slab0 automatically.

Embodiments may also include: selecting one or more slabs, clicking Slab Type Drop-Down Menu to assign slab type, like Etabs, SafeOpen and others. Retyping slab T. DL, LL in Slab Property Table as required to assign new slab properties. Or using Slab Property Assign on screen method.

Embodiments may also include: clicking “SlabTag Locate” button to locate the slab tag location automatically. Selecting one or more Sub-Slab, using Left/Right Scroll Bar and Up/Dow Scroll Bar to move the slab tag.

Embodiments of the present disclosure may include: drawing and modifying drop panels automatically.

Embodiments may also include: Checking the values of DX1, DX2, DY1, DY2 and angle, changing it as required, clicking “Add Drop Panel” checkbox, then clicking a column or a point on plan, a new drop panel is added with the predetermined data. If the click point is near edge of slab, or near slab open, the added drop panel is cut automatically. Or adding all drop panels on all columns automatically just with one click.

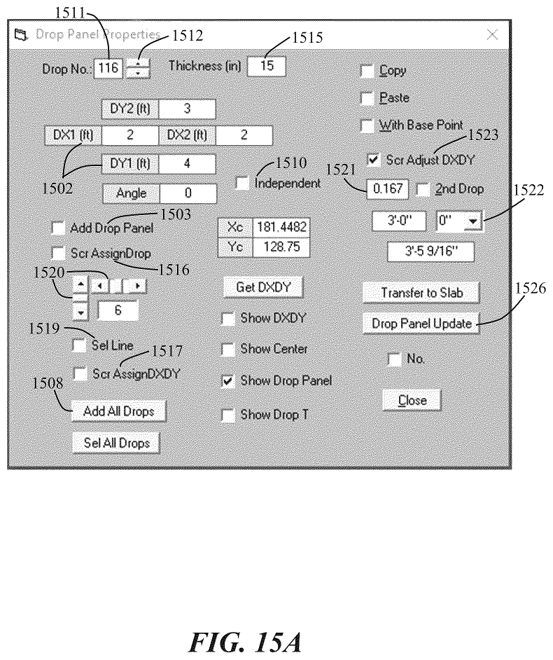

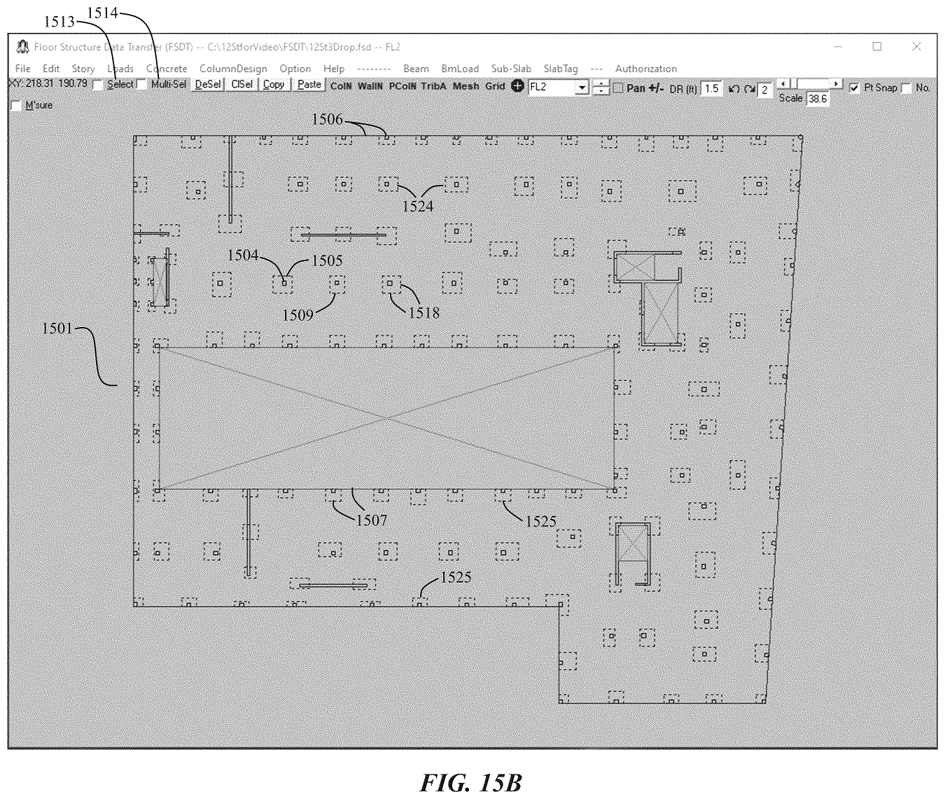

Embodiments may also include: selecting drop panels, or drop panel edge lines on plan, using Left/Right Scroll Bar and Up/Dow Scroll Bar in FIG. 15A to move the selected drop panels or drop panel edge lines.

Embodiments may also include: the drop panel sizes DX1, DX2, DY1 and DY2 can be adjusted automatically, selecting some drop panels on plan, changing these sizes, the sizes of selected drop panels on plan will be updated automatically. Or screen assigning the drop panel. Or clicking “Scr Adjust DXDY” checkbox, clicking two related columns on plan, the drop panel sizes will be adjusted based on the column spacing automatically.

Embodiments may also include: if some drop panels are not automatically adjusted based on slab edge and opens, the user can click “Drop Panel Update” button to adjust drop panels based on slab edges and opens automatically.

Embodiments of the present disclosure may include: setting up Ready-to-Run Etabs and Safe models automatically,

Embodiments may also include: after finishing all columns, beams, walls, slabs and other structural items, assigning all deal loads, live loads, wind load and seismic load, point loads, line loads and surface loads, concrete strength, making load combinations, FSDT program will setup Ready-to-Run Etabs model and Safe models automatically. The user can export e2k File for Etabs model and f2k File for Safe model. The Etabs program can import the e2k file and run the model immediately. The Safe program can import the f2k file and run the model immediately.

Embodiments may also include: all concrete shear walls are automatically segmented according to the segment length requirements determined by the user. All wall segments can be aligned for all floors of the building, and are imported into Etabs program.

Embodiments may also include: adding pier number of walls and elevation views at all pier loacations for Etabs program automatically. Getting column forces, wall reactions, wall reinforcement and slab reinforcement from Etabs and Safe programs.

Embodiments of the present disclosure may include: designing and checking conrete column one by one automatically.

Embodiments may also include: getting column sizes, column lengths and column forces for all columns and all floors of whole building from FSDT model. The data will be filled in the form automatically. Inputting concrete strength and other column design information, then designing and checking the columns with slenderness considered. Changing the column size, rebar size, column length, concrete strength, some other parameters, to see the results immediately. Checking the columns one by one or all columns together. When checking a column, the results in the table and Column Capacity Graph will be shown immediately.

Embodiments may also include: keeping some previous column design data when get new column numbers due to column layout changed. After finishing the column design and check, exporting all data required for the column schedule to an excel file. Then the user can make column schedule based on this excel file with AUD program.

Embodiments of the present disclosure may include: making AutoCAD column schedule automatically.

Embodiments may also include: reading the Column Excel File, making column schedule in AutoCAD drawing automatically. Separating the column schedule into two or more column schedules if the column schedule is too long.

Embodiments may also include: changing the parameters that control the column schedule by retyping their value except floor height which is determined by real floor height imported in column schedule data from Column Excel File.

Embodiments may also include: inputting the “Top Foundation FL” by clicking the Floor Drop-Down Manu. In each foundation floor, if there is a column that starts at this floor, then there will be a heavy line shown in column schedule which indicates the bottom of column. Top foundation floor is the floor with highest elevation in the floors in which there are pile caps or footings.

Embodiments may also include: sheet “FLElev” in Column Excel File has 5 excel columns that are Order, “Floor”, “Height”, “fc” and “FL Name in Model”.

Embodiments may also include: sheet “AllFL” in Column Excel File has “Col N” and “Col Load” Columns first, these two Excel columns are used to put the column loads in Column Schedule. And then has 4 excel columns for each floor, that is “Col N”, column section width “B”, column section height “H”, and reinforcement “Rebar”. These 4 excel columns are for concrete column data of one floor, but only typical floor column data are required to put here.

Embodiments of the present disclosure may include: obtaining structural drawing information from FSDT program and architectural drawings.

Embodiments may also include: FSDT and AUD programs not only obtain columns, walls, beams, slabs and other structural items from architectural drawings for FSDT model, Etabs and Safe models, but also obtain these items for structural drawings. And get some special items, which are not the structural model items and are not required to import into Etabs and Safe models, but will be shown in structural drawings. FSDT and AUD programs export these architectural items into AutoCAD, to be an architectural background of structural drawings (ABG).

Embodiments may also include: AUD program import FSDT file so as to get columns, walls, beams, slabs and other structural drawing information from FSDT program.

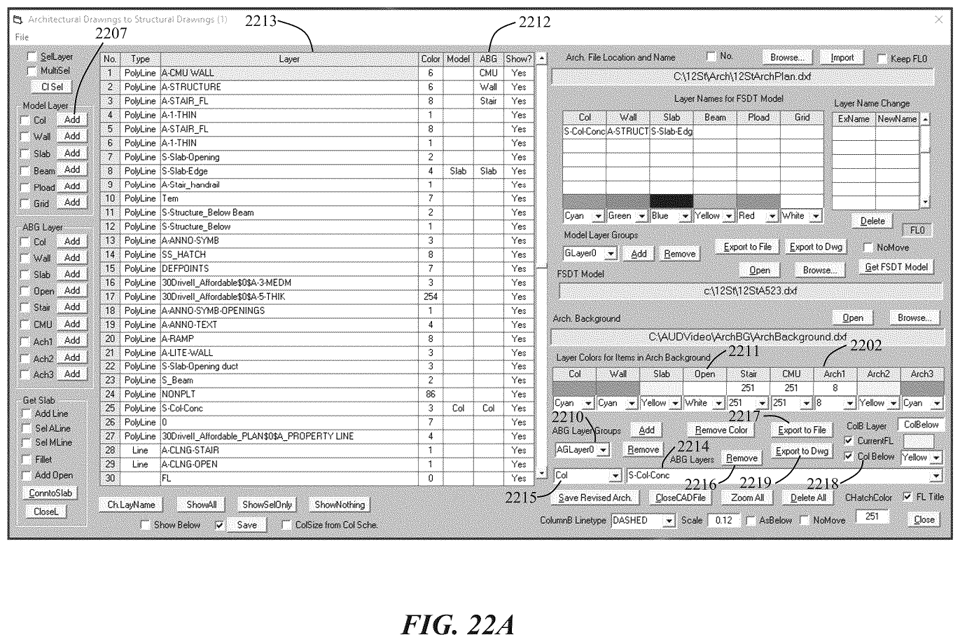

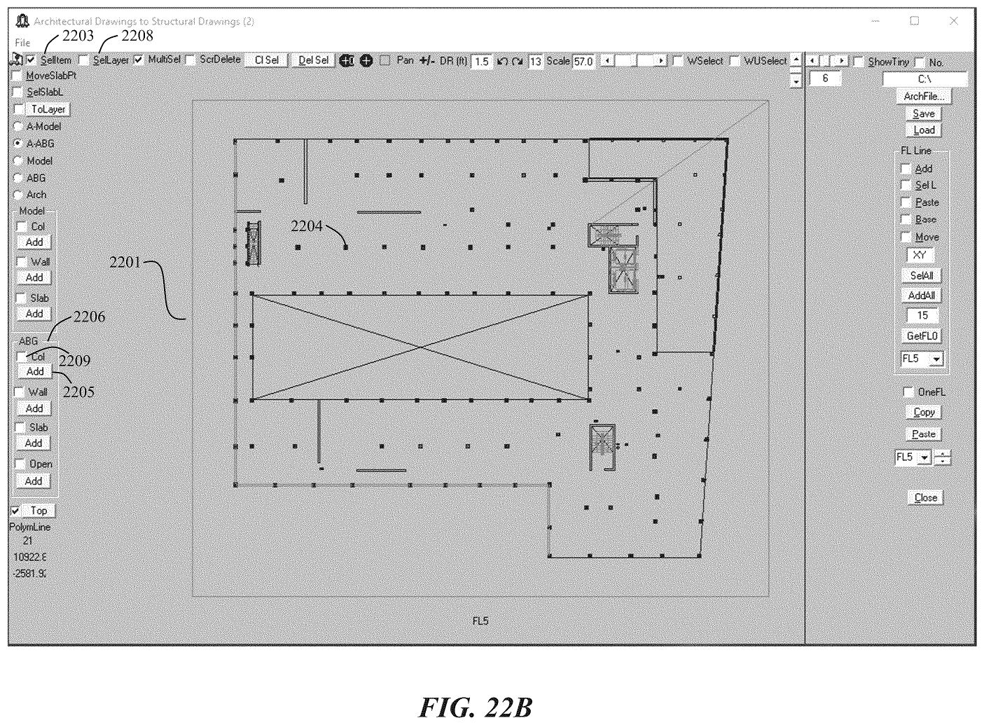

Embodiments may also include: Selecting any ABG item in the architectural drawing, then clicking the related “add” button in ABG Layer frame in FIG. 22B, the item information with the same layer on all floors in the building will be added into ABG Drawings. Or clicking ABG item checkbox, like “Col” checkbox for columns, then clicking an item which belong to column in architectural drawing, all items which have same layer with clicked column are added into ABG

### DRAWINGS

Embodiments may also include: saving all AutoCAD layer names for ABG drawings. Therefore, next time some items in architectural drawings are changed, like items moved or dimension changed, just importing the architectural drawings again, then the user gets ABG drawings from architectural drawings immediately and automatically.

Embodiments may also include: saved all AutoCAD layer names for an ABG drawings are shown in some special tables, the user can change the layer names, delete and add the layer names directly, to let the user change and control the final ABG drawings easily. FSDT and AUD programs even can save the layer names as ABG layer group for different projects and different situation with different ABG layer group name.

Embodiments may also include: clicking “Export to File” button to export ABG drawings as AutoCAD dwg file. The AutoCAD can open it and then take it as attached file of the structural drawings. If “Col Below” checkbox is checked, the columns and walls below for each floor will be exported when export ABG drawings.

Embodiments of the present disclosure may include: making Typical Pile Cap Details and adding pile caps on plan automatically.

Embodiments may also include: there are three kinds of pile caps: regular pile cap that is normal pile cap PC1 to PC9; PC-A pile cap, the pile cap that has piles with regular columns and rows; SP pile cap, special pile cap with any pile number, and the piles can be at any location. The parameters of pile cap include pile number, pile diameter, pile space, the edge of pile center to pile cap, cap depth and pile type which can be Round or HP shape.

Embodiments may also include: making Typical Pile Cap Details for regular pile cap, PC-A pile cap and SP pile cap automatically. Just change some parameters of pile cap, then the user can add Typical Pile Cap Details for regular pile cap, PC-A pile cap and SP pile cap into their three pile cap Drop-Down Menus to save them.

Embodiments may also include: selecting one Pile Cap Detail in three pile cap Drop-Down Menus, changing the pile space, pile cap edge, pile diameter D and pile type, pressing Enter key at just changed button or textbox, or pressing Enter key at pile cap Drop-Down Menu for regular Pile Cap Detail, pressing Enter key at pile cap Drop-Down Menu for PC-A Pile Cap Detail and SP Pile Cap Detail, the data of current and existing Pile Cap Detail are changed.

Embodiments may also include: selecting a pile cap option of regular pile cap, PC-A pile cap, or SP pile cap, changing some data as required, checking pile cap base as required if it is PC-A pile cap or SP pile cap, clicking “Add PC” button, clicking a point on plan, a pile cap is added on plan automatically.

Embodiments may also include: clicking “Add Col PC” button, the AUD program will find all column locations, required regular Pile Cap Details based on column force and pile capacity, and add regular pile caps for all columns on plan automatically.

Embodiments may also include: selecting the pile caps on plan, then selecting the Pile Cap Detail in three pile cap Drop-Down Menus, pressing Enter key on pile cap Drop-Down Menu or on angle of selected Pile Cap Detail, the selected pile caps on plan will be changed to new Pile Cap Detail.

Embodiments may also include: selecting the pile caps on plan, changing the pile space, pile cap edge, pile diameter D, or pile cap angle, pressing Enter key, the data of the related Pile Cap Detail will be changed automatically, and the selected pile caps on plan will be changed with the change of related Pile Cap Detail.

Embodiments may also include: selecting pile caps on plan, using Left/Right Scroll Bar and Up/Dow Scroll Bar to move the selected pile caps, or screen move the pile caps.

Embodiments may also include: getting SP pile cap from AutoCAD drawing. Transferring SP pile cap into regular pile cap or PC-A pile cap if suitable.

Embodiments may also include: pile cap Information table gives the user the information for all pile caps on plan. Changing pile cap Depth, Angle, center Xc and Yc, pressing enter key to update the pile caps on plan with these new data.

Embodiments may also include: if whole pile cap is under the concrete slab, all pile cap lines will be shown as dash lines. If part of pile cap is not under concrete slab, then the lines of pile cap which are out of slab will be shown as solid lines. When add the pile cap, these solid lines are added automatically. When move the pile cap, these solid lines are changed automatically.

Embodiments may also include: if the columns or pile caps moved, clicking “Moveto ColC” checkbox, then clicking a pile cap on plan to move automatically, so the center of the pile cap is on the center of column.

Embodiments of the present disclosure may include: getting original shear walls from the model plan of this AUD program or from AutoCAD drawing automatically

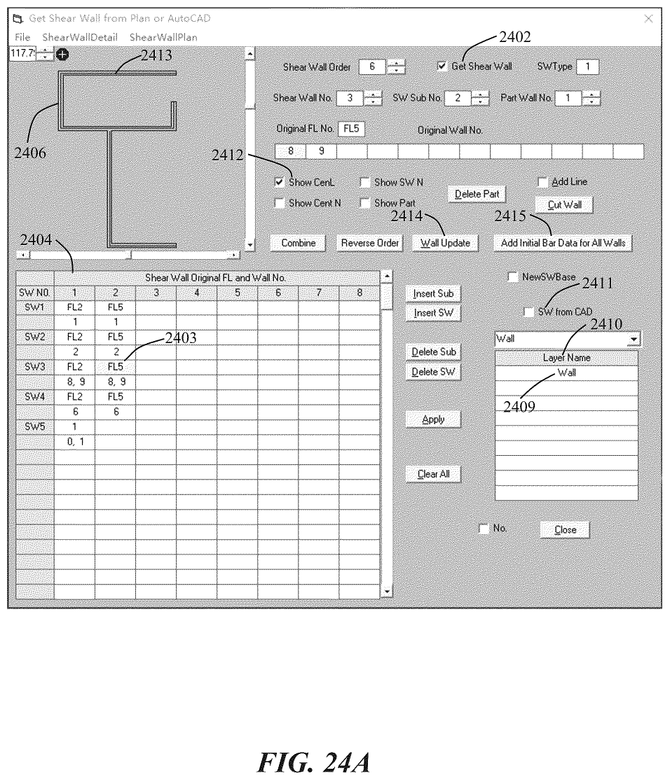

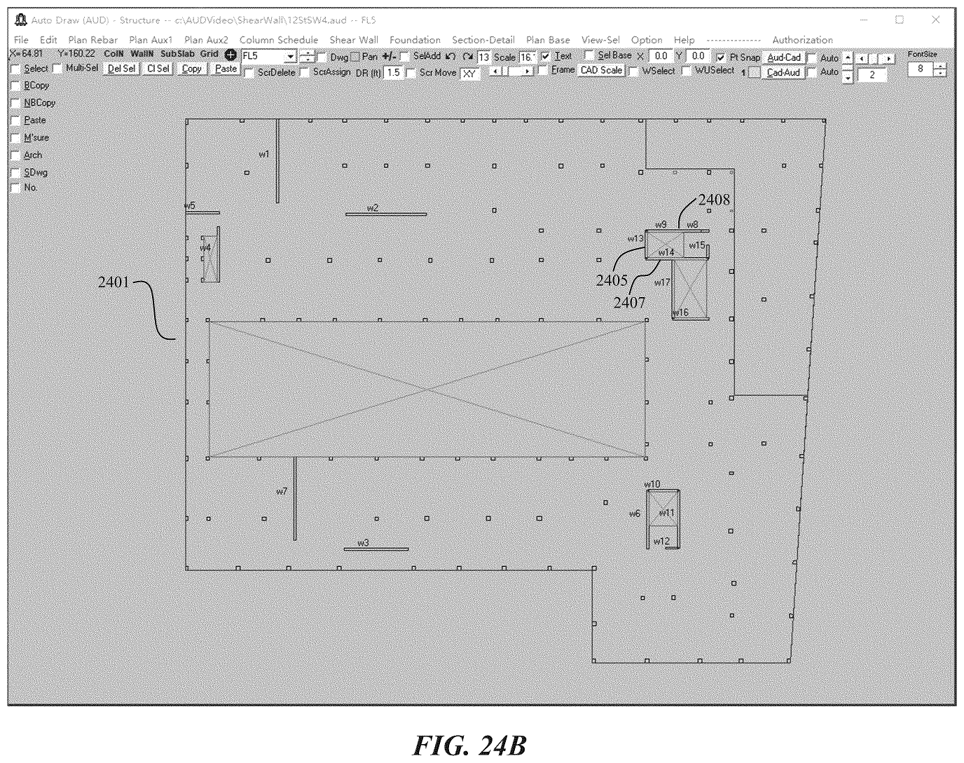

Embodiments may also include: clicking “Get Shear Wall” checkbox in FIG. 24A, clicking a FL cell in “Shear Wall Original FL and Wall No.” table to specify new shear wall location in the table, clicking a part-wall of a shear wall in model plan in FIG. 24B, the selected part shear wall is imported, or window selecting a whole shear wall in model plan by draw a box surrounding the whole shear wall on plan, whole shear wall is imported.

Embodiments may also include: opening AutoCAD program, checking “Get Shear Wall” checkbox, clicking a FL cell in “Shear Wall Original FL and Wall No.” table to specify new shear wall location, inputting the layer name as required. Clicking “SW from CAD” checkbox, go to AutoCAD drawing again and clicking a point on AutoCAD drawing, then window selecting all part walls of a shear wall. Whole Shear wall inside the box will be imported into AUD program.

Embodiments may also include: clicking “Show CenL” checkbox in FIG. 24A, the obtained shear wall will show the center lines. If the center lines are OK, then the shear wall is correct and ready to add reinforcement. Clicking “Wall Update” button to let AUD program cut and combine shear walls, modify other data as required automatically, to make the shear walls correct and ready to add reinforcement.

Embodiments of the present disclosure may include: drawing and modifying shear wall plans automatically.

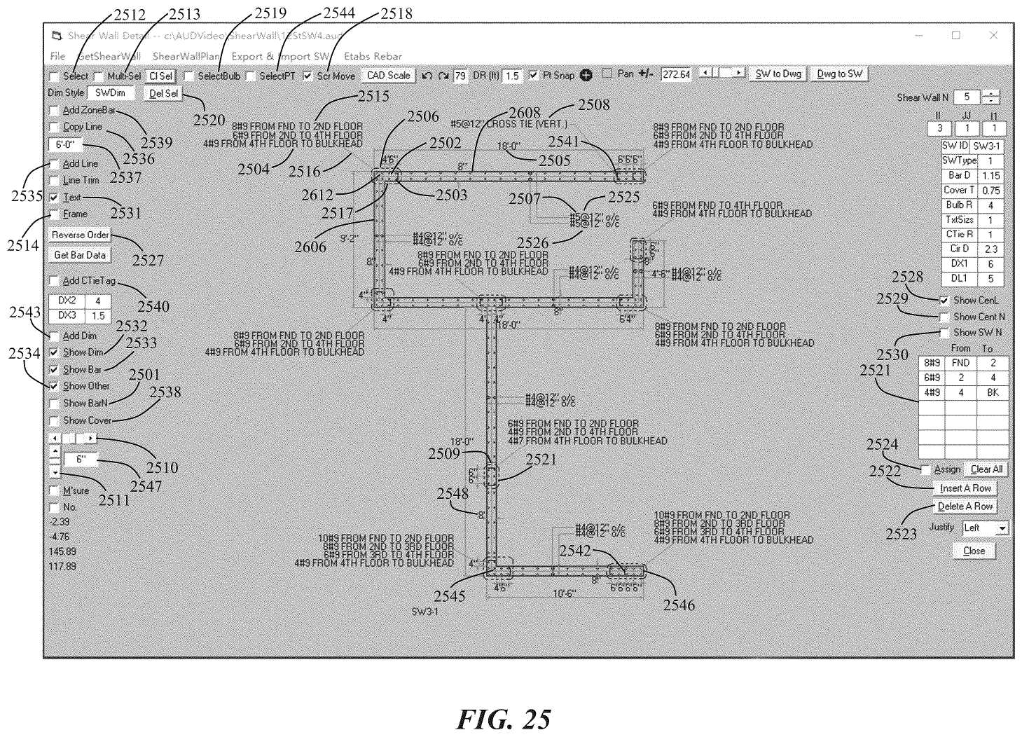

Embodiments may also include: clicking “Show BarN” checkbox in FIG. 25, the numbers for all zone bars will be shown on shear wall plan in FIG. 25, changing the zone bar number, and pressing Enter key, the zone bar number in shear wall plan is changed, the basic rebars and the dimensions are automatically changed as required too. The bar number for Zone Bar here is not the zone bar number in zone bar callout, it is the bar number shown in shear wall plan on the drawing.

Embodiments may also include: selecting dimension, zone bulb line or whole bulb, zone bar callout, basic bar callout, cross tie tag, additional line, and other items, using Left/Right Scroll Bar and Up/Dow Scroll Bar to move the selected items. Or clicking “Scr Move” checkbox, then screen move these items.

Embodiments may also include: clicking “Frame” checkbox to show the frame for text, then it will be easy to select the text by clicking the frame.

Embodiments may also include: clicking “Select” checkbox, selecting items that need to delete, clicking “Del Sel” button to delete selected items.

Embodiments may also include: selecting zone bar callouts, the zone bar information for selected zone bar callout will be shown in “From To” table, retyping the zone bar information to change, clicking “Insert A Row” button to insert a row, or clicking “Delete A Row” button to delete a row, pressing Enter key to finish the new zone bar assignation for selected zone bar callouts. Or clicking “Assign” checkbox, then clicking zone bar callout in shear wall plan one by one to screen assign zone bar callout.

Embodiments may also include: double-clicking basic bar callout text or cross tie callout text shown on shear wall plan in FIG. 25, the text will be shown in red color, changing the callout text and then pressing Enter key or clicking another point on screen, the basic bar callout or cross tie callout text is changed.

Embodiments may also include: clicking “Add Line” checkbox, clicking two points on shear wall plan, a line will be added. Or clicking “Copy Line” checkbox, checking or inputting the copy distance, clicking a line to select it as copy source, clicking the location where to add a line, a new line is copied to there.

Embodiments may also include: clicking “Show Cover” checkbox, the concrete covers for all part walls will be shown, changing the value for concrete cover on plan and pressing Enter key, the concrete cover for a single part wall is changed.

Embodiments may also include: using “Add A Line” or “Copy A Line” method to add a line, clicking “Add ZoneBar” checkbox, selecting the line which will be shown in red color, clicking the new zone bar location next to selected line, the new additional zone bar is added next to selected line.

Embodiments may also include: clicking “Add CTieTag” checkbox, clicking a cross tie in zone bar area, clicking another location, the cross tie callout is added. Double-clicking the Cross Tie, the direction of cross tie is changed.

Embodiments may also include: all normal dimensions are added by AUD program automatically. Can click “Add Dim” checkbox, then add additional dimension.

Embodiments may also include: clicking “SelectPt” checkbox, selecting some points on shear wall center lines by clicking them or using window select method to select them, using Left/Right Scroll Bar and Up/Dow Scroll Bar to move the selected points, the related shear wall length is changed. One can change the one-time move distance in the textbox to get exact wall length.

Embodiments may also include: double-clicking wall thickness value shown on shear wall plan, the value will be changed in red color, changing the wall thickness, and then pressing Enter key or clicking another point on screen, the wall thickness is changed.

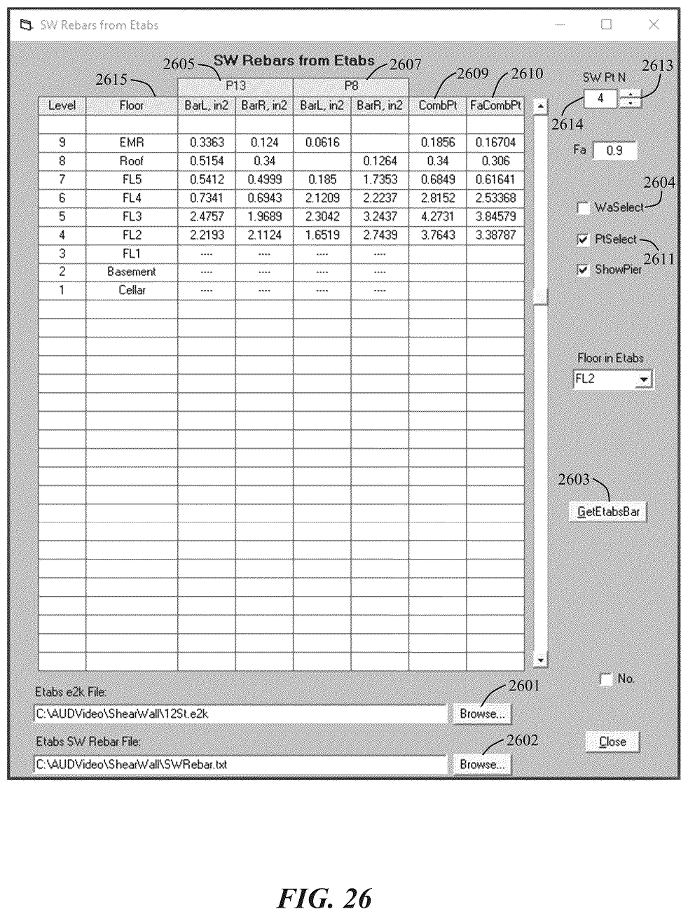

Embodiments may also include: clicking one “Browse” button in FIG. 26 to select Etabs e2k File, clicking another one “Browse” button to select Etabs SW Rebar txt File, clicking “GetEtabsBar” button to get SW Rebars from Etabs.

Embodiments may also include: clicking “WaSelect” checkbox in FIG. 26, selecting first Pier Number in FIG. 26 as current one, selecting a part-wall in FIG. 25, the Etabs rebar will be shown under first Pier Number. Selecting second Pier Number as current one, selecting another part-wall, the Etabs rebar will be shown under second Pile Number. If two walls are in different directions and connected at their ends, total rebar for these two ends are obtained and shown under “CombPt” automatically, “FaCombPt” is equal to “Fa*CombPt” and is shown too.

Embodiments may also include: clicking “PtSelect” checkbox, selecting a point in a shear wall in FIG. 25, the Etabs rebar for two part-walls will be shown under first Pier Number and second Pier Number. If two part-walls are connected to the selected point, the total rebar for these two ends are shown under “CombPt”. “FaCombPt” will be shown too.

Embodiments may also include: inputting number in Wall Pt N textbox in FIG. 26, and pressing Enter key in keyboard, or clicking the up/down scroll bar next to Shear Wall Pt N, then the Etabs rebars for the part-walls, which are connected this point, are shown in “SW Rebars from Etabs” table.

Embodiments of the present disclosure may include: drawing and modifying plan rebars automatically

Embodiments may also include: there are five kinds of rebars, that is X Top Bar, Y Top Bar, X Bottom bar, Hook Bar and Bi-Hook Bar.

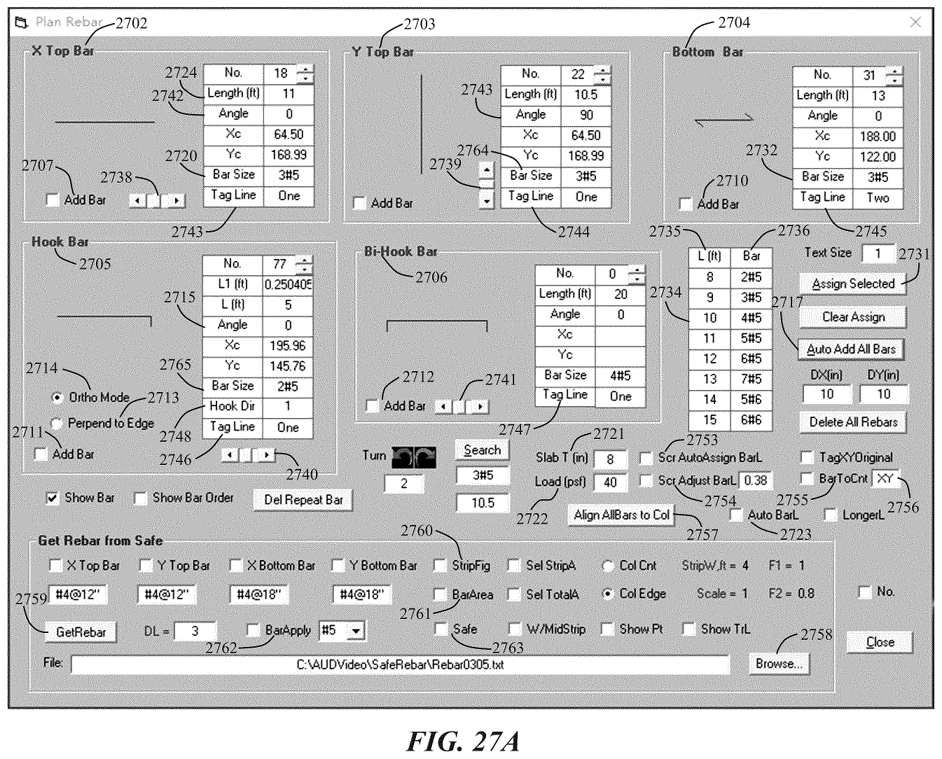

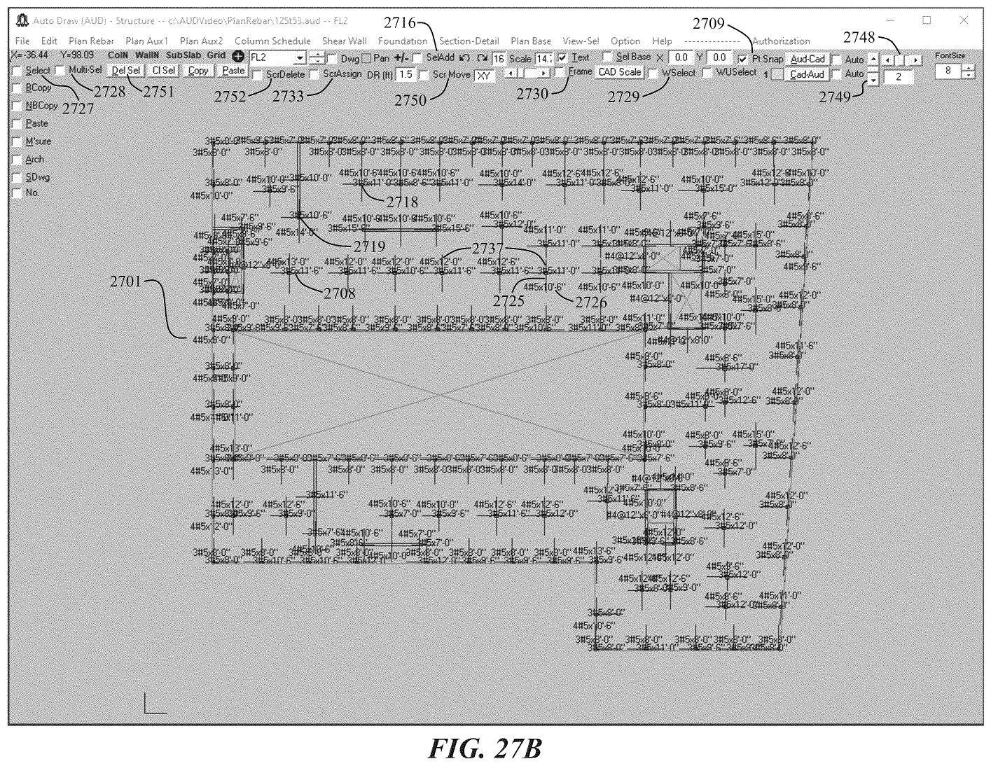

Embodiments may also include: selecting a rebar type in FIG. 27A, X Top Bar, Y Top Bar or others, confirming the parameters of rebar, clicking on the plan, the rebar is added automatically, including the rebar and its bar tag. The added Hook Bar can be perpendicular to slab edge, vertical or horizontal, or with a angle taking the value shown in Hook Bar “Angle” textbox.

Embodiments may also include: if “SelAdd” checkbox in FIG. 27B is checked, the added rebar will be selected automatically when the user adds rebar on plan, then the user can revise or move the added rebar immediately.

Embodiments may also include: clicking “Auto Add All Bars” button, AUD program will add some rebars automatically on all columns and walls. The added rebars include X Top Bar, Y Top Bar and some Hook Bar. The centers of added rebars will be on the centers of columns. The bars size can be determined by the user or calculated by AUD program based on slab thickness and load. The bar length can be determined by the user or calculated by AUD program based on column spacing. If the column is near slab edge, the Hook Bar can be added automatically based on the distance from column to slab edge.

Embodiments may also include: the bar tag can be shown in one line or two lines as the user likes and it can be changed easily. When assign the bar length, the content in bar tag and the real bar length shown on plan will be both updated automatically. When the content in bar tag is changed, the real bar length shown on plan will be modified automatically.

Embodiments may also include: selecting rebars on plan, retyping bar length, angle, Xc, Yc, bar sizes and other bar parameters in FIG. 27A as required, pressing Enter key, the bar parameters will be assigned, and the drawings on plan will be modified automatically.

Embodiments may also include: double-clicking on the parameters in FIG. 27A that the user needs to assign, like X Top Bar length, the value color will be changed to red, indicate this parameter is in assign situation. The user can select more parameters. Selecting the rebars on plan that need to assign, changing the assigning parameters as required, clicking “Assign Selected” button, the selected rebars will be assigned. Or clicking “ScrAssign” checkbox in FIG. 27B, clicking the rebars on plan one by one to screen assign rebars.

Embodiments may also include: there is a Table that includes “L(ft)” and “Bar”. “L(ft)” is the rebar length, and “Bar” is the rebar size. Selecting the rebars on plan that need to assign, clicking the rebar length or rebar size in the Table, all rebar lengths or rebar sizes of selected rebars will be assigned.

Embodiments may also include: selecting X Top Bar, Y Top Bar, or Hook Bar on plan, clicking their length scroll bars in FIG. 27A to change their bar length. Can click the text “Hook Dir” in Hook Bar frame to change the hook direction of selected Hook Bars.

Embodiments may also include: selecting rebars, using Left/Right Scroll Bar and Up/Dow Scroll Bar to move selected rebars. Or clicking “Scr Move” checkbox in FIG. 27B, then screen move the rebars on plan.

Embodiments may also include: clicking “Scr AutoAssign BarL” checkbox, clicking the X Top Bar or Y Top Bar on plan, the clicked top bar will be assigned with a length calculated by AUD program based on column spacing automatically. Or Clicking “Scr Adjust BarL” checkbox, then clicking two end points of two spans for column, the top bar located on the column center will be assigned with a length calculated by AUD program based on the length of these two spans automatically.

Embodiments may also include: getting the bar area file from Safe model. Clicking “Browse” button to selecting this bar area file, clicking “GetRebar” button to get strip bar area from Safe model. Then the AUD program can show the rebars of Safe model results on the plan, and make the plan rebars based on Safe model results.

Embodiments may also include: showing the Safe strip bar area figure for X Top Bar, Y Top Bar, X Bottom Bar or Y Bottom Bar, if the “StripFig” checkbox is checked.

Embodiments may also include: AUD will show the Safe bar area value for X Top Bar, Y Top Bar, X Bottom Bar or Y Bottom Bar, if the “BarArea” checkbox is checked. Top bar is total additional bar area for a point required and based on basic bar reinforcement. Bottom bar is for each strip's additional bottom bar area. The user can change the basic rebars, then the additional rebars shown on the plan will be changed automatically.

Embodiments may also include: clicking “BarApply” checkbox to update the final top bars and bottom bars for CAD drawing automatically based on Safe model results.

Embodiments of the present disclosure may include: drawing CAD Beam, column above-below symbols, column number symbols, section symbols, different elevation symbols automatically.

Embodiments may also include: clicking “Point to Point” checkbox, selecting a beam size in beam size Drop-Down Menu, checking or inputting the beam extension EX1 and EX2, clicking two points on plan, a CAD beam is added on plan automatically, or clicking “Point to Wall” checkbox to add a CAD beam with similar method.

Embodiments may also include: the base line of CAD beam can be a center line of CAD beam or edge of CAD beam.

Embodiments may also include: adding extensions in both ends of a CAD beam. Ex1 is the left side extension of the CAD beam, Ex2 is the right side extension of the CAD beam. Retyping them and pressing Enter key to change the length values of Ex1 and EX2, or using left/right scroll bar to change them. Can use Ex1 or Ex2 to change the beam length.

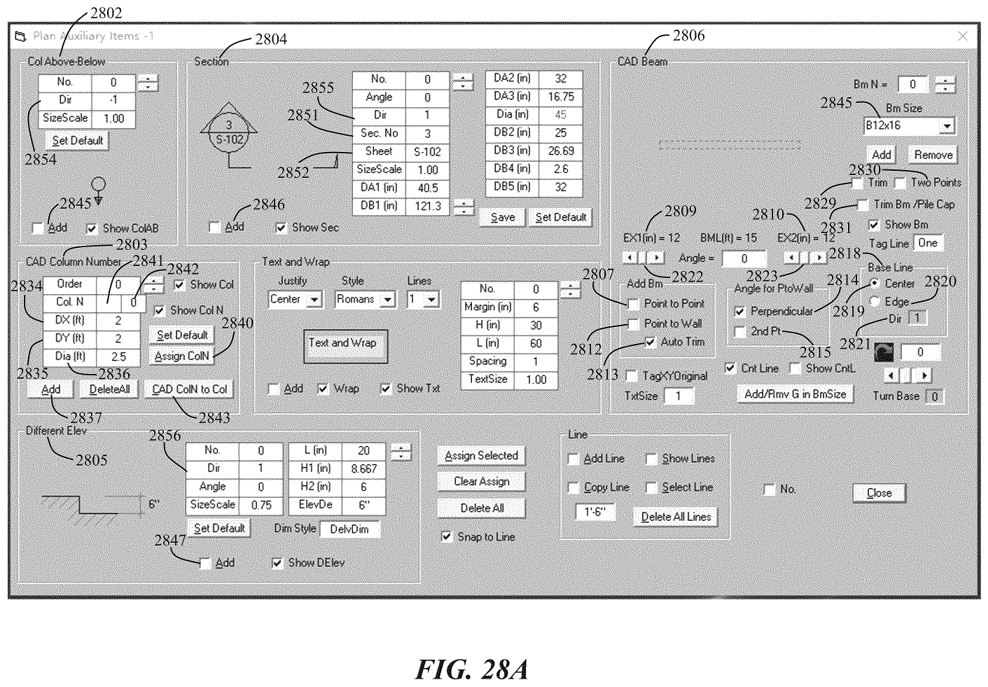

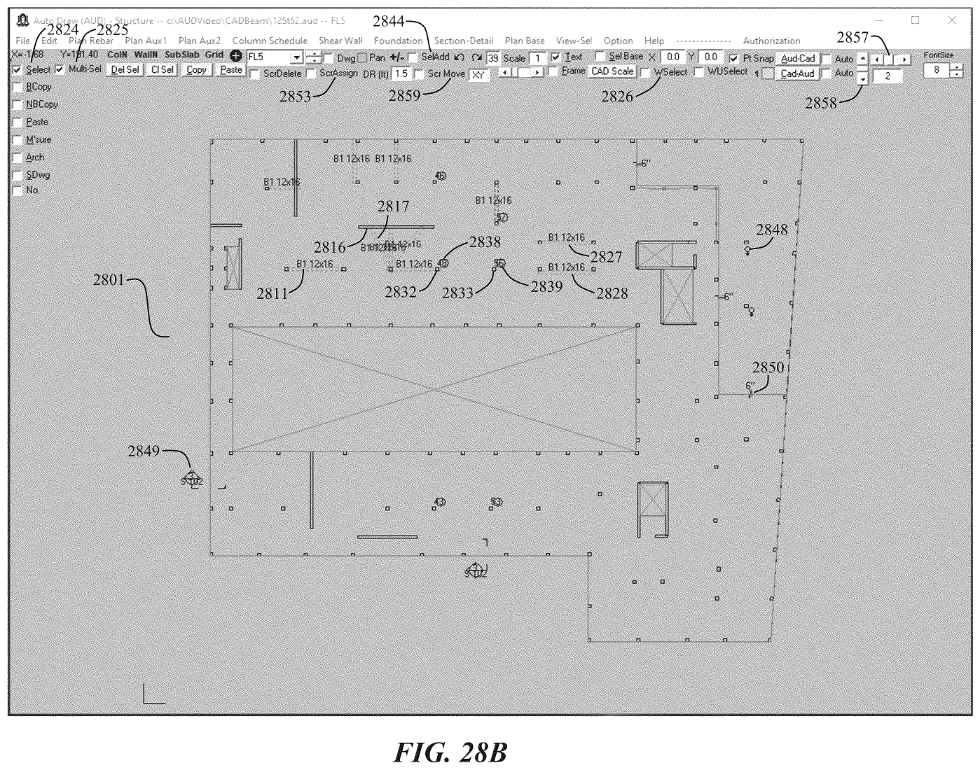

Embodiments may also include: selecting columns which need to add column number symbols, checking DX, DY and Dia values to make sure they are all correct, clicking “Add” button in “CAD Column Number” frame in FIG. 28A to add column number symbols for selected columns.

Embodiments may also include: selecting column number symbols, clicking “Assign ColN” button, the CAD numbers for selected column number symbols will be same as column numbers in structural model.

Embodiments may also include: selecting a column number symbol, the column CAD number will be shown in the first textbox for “ColN” in FIG. 28A, typing a new column CAD number in second textbox, pressing Enter key, the column CAD number of selected column number symbol will be changed.

Embodiments may also include: clicking “Add” checkbox in “Col Above-Below” frame in FIG. 28A, checking all information shown for column above-below symbol, clicking a point on plan, a column above-below symbol is added automatically. Adding section symbols, different elev. symbols with same way. The angles of section symbol and different elev. symbol are determined by AUD program based on the slab edge line near click point.

Embodiments may also include: selecting items on plan that need to assign, retyping the value of selected items, like “Sec. No” in “Section” frame as required, pressing Enter key at just typed location, the value of the selected items is changed automatically.

Embodiments may also include: double-clicking on the parameter that the user wants to assign, like “Sec. No” of section, the value color will be changed to red, indicate this parameter is in assign situation. Clicking “ScrAssign” checkbox in FIG. 28B, clicking the items on plan one by one to assign new parameters to them.

Embodiments may also include: selecting the section on plan that need to assign, clicking the text “Dir” in the section frame, the “Dir” of selected section is changed. Changing the direction of column above-below “Dir” and different elev. “Dir” with same way.

Embodiments may also include: selecting items that need to move, using Left/Right Scroll Bar and Up/Dow Scroll Bar to move the selected items. Or clicking “Scr Move” checkbox in FIG. 28B, then screen move the items.

Embodiments of the present disclosure may include: drawing and modifying Typical Pile Cap Details automatically.

Embodiments may also include: making Typical Pile Cap Details for regular pile caps, PC-A pile caps and SP pile caps in CAD drawings automatically.

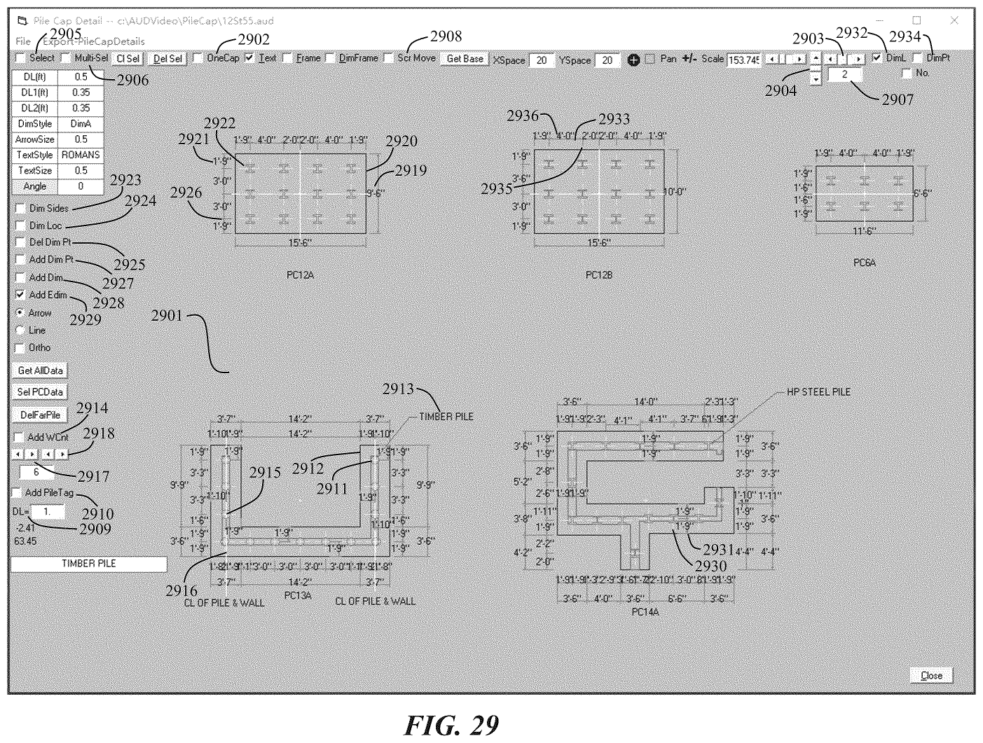

Embodiments may also include: clicking “OneCap” checkbox in FIG. 29 to check it, then clicking one Typical Pile Cap Detail in the plan, the clicked Typical Pile Cap Detail will be moved to the center of the graphic display area, and is shown with a certain scale, so that it is shown clearly in the plan.

Embodiments may also include: selecting whole pile cap, dimension line and text, wall center line text, pile tag, pile cap tag and other items, using Left/Right Scroll Bar and Up/Dow Scroll Bar to move them. Or Clicking “Scr Move” checkbox, then screen move whole pile cap, dimension line and text, wall center line text, pile tag, pile cap tag and other items.

Embodiments may also include: checking the horizontal line length “DL” of pile tag, changing it as required, clicking “Add Pile Tag” checkbox, clicking a pile in pile cap, clicking another point around pile cap, a new pile tag is added automatically. Clicking “Add WCnt” checkbox, then clicking a point at inside of the wall, a wall center line is added. Using the left Left/Right Scroll Bar to move the first point of wall center line to change the length, using the right Left/Right Scroll Bar to move the second point of wall center line to change the length.

Embodiments may also include: the regular dimensions of pile cap are given out by AUD program automatically. The dimensions can be on both sides of pile cap or only on one side of pile cap. Clicking some buttons to change the situation.

Embodiments may also include: clicking “Del Dim Pt” checkbox, clicking a point in dimension line, the dimension point will be deleted. Clicking “Add Dim Pt” checkbox, clicking a dimension line of pile cap or piles, the dimension will be selected, clicking a point on pile center or pile cap, the dimension point is added.

Embodiments may also include: clicking “Add Edim” checkbox, clicking a point on screen between the pile and the edge of SP pile cap, a new additional dimension from a pile to the edge of pile cap is added for SP pile cap.

Embodiments may also include: clicking “DimL” checkbox, then moving individual dimension line with Left/Right Scroll Bar and Up/Dow Scroll Bar. Clicking “DimPt” checkbox, then moving individual original points of dimension.

The preceding Summary is intended to serve as a brief introduction to some embodiments of the disclosure. It is not meant to be an introduction or overview of all inventive subject matter disclosed in this document. The Detailed Description that follows and the Drawings that are referred to in the Detailed Description will further describe the embodiments described in the Summary as well as other embodiments. Accordingly, to understand all the embodiments described by this document, a Summary, Detailed Description and the Drawings are provided. Moreover, the claimed subject matter is not to be limited by the illustrative details in the Summary, Detailed Description, and the Drawings, but rather is to be defined by the appended claims, because the claimed subject matter can be embodied in other specific forms without departing from the spirit of the subject matter.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

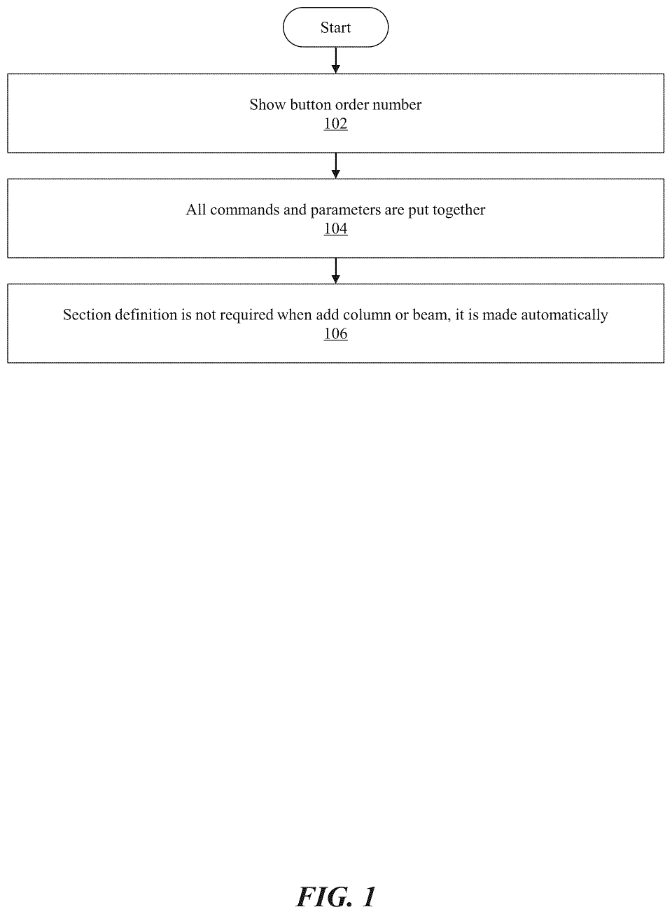

FIG. 1 is a flowchart illustrating the special characteristic of the present disclosure and invention.

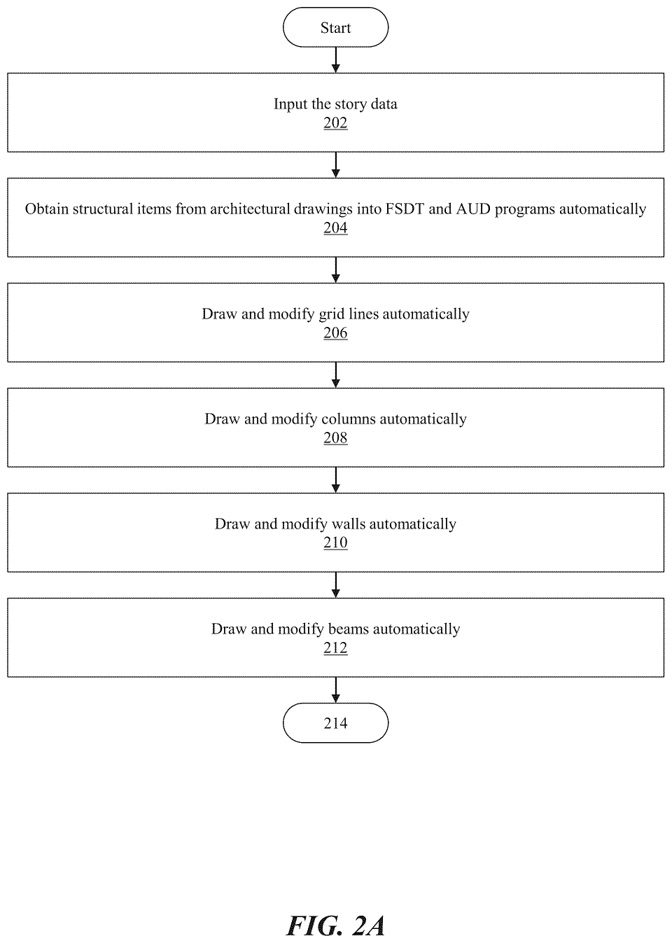

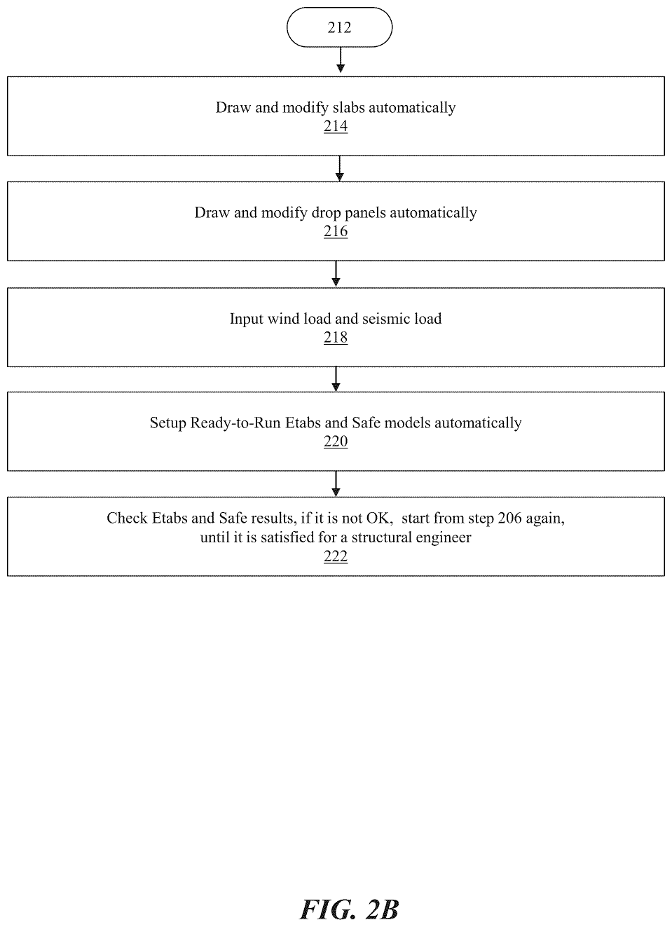

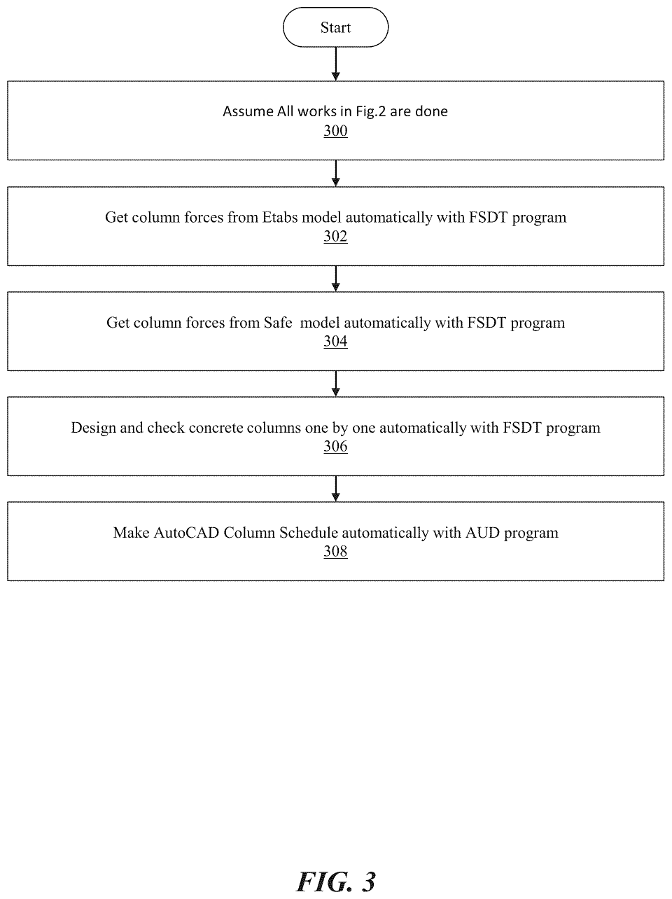

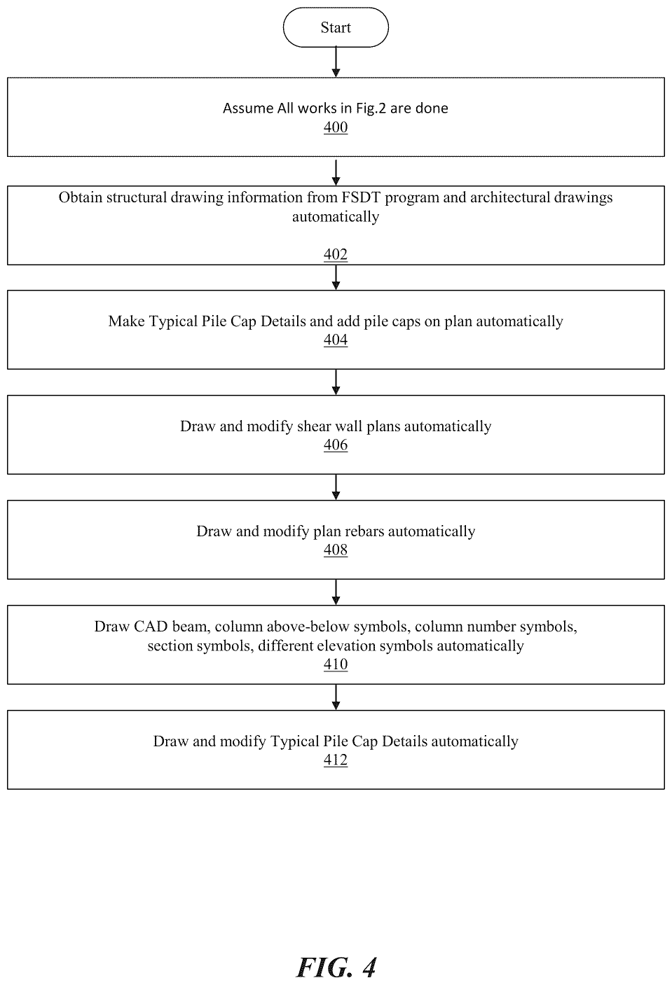

FIG. 2A is a flowchart illustrating a method to obtain structural items from architectural drawings, and Setup Ready-to-Run Etabs and Safe models automatically with FSDT program, according to some embodiments of the present disclosure.

FIG. 2B is a flowchart extending from FIG. 2A and further illustrating the method to obtain structural items from architectural drawings, and Setup Ready-to-Run Etabs and Safe models automatically, according to some embodiments of the present disclosure.

FIG. 3 is a flowchart illustrating a method to design and check concrete column one by one automatically with FSDT and draw column schedule automatically with AUD program, according to some embodiments of the present disclosure.

FIG. 4 is a flowchart illustrating a method to draw and modify the structural drawings automatically with AUD, according to some embodiments of the present disclosure.

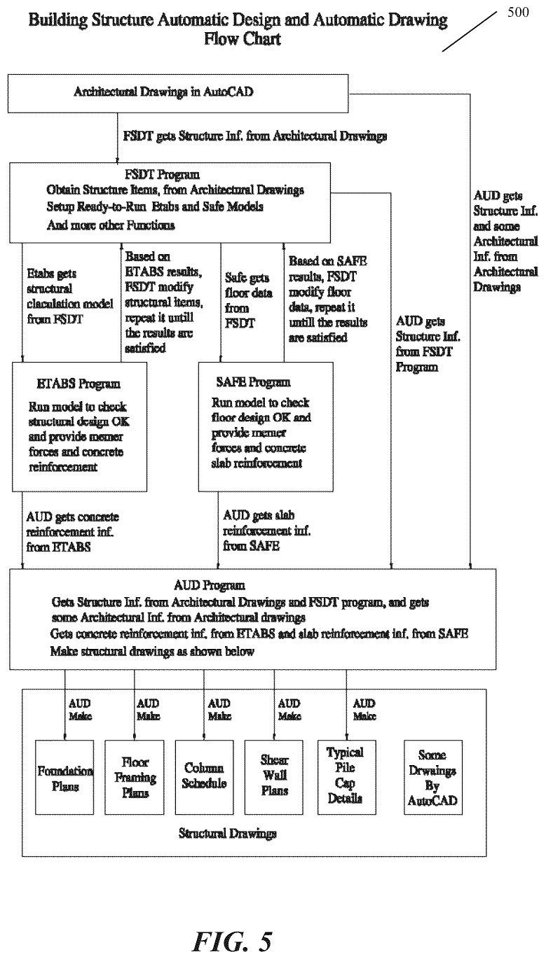

FIG. 5 is a flowchart illustrating a method of automatic design and automatic drawing of building structure, according to some embodiments of the present disclosure.

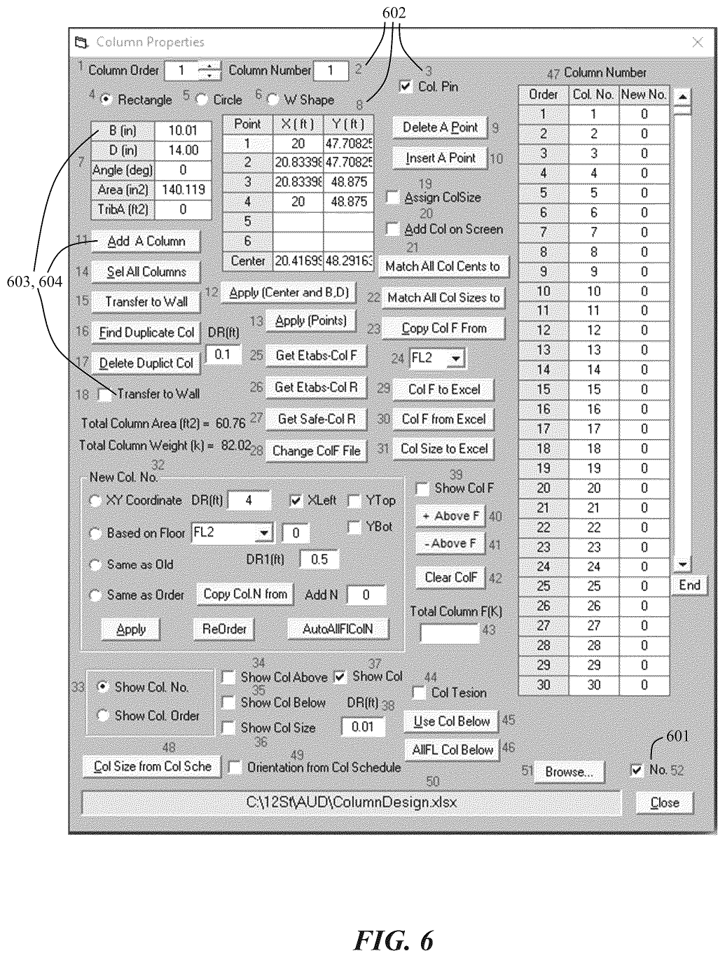

FIG. 6 is an interface used to draw and modify columns automatically, according to some embodiments of the present disclosure. This is an example regarding that all order numbers for button, checkbox, textbox, labels and others are shown in the user interface.

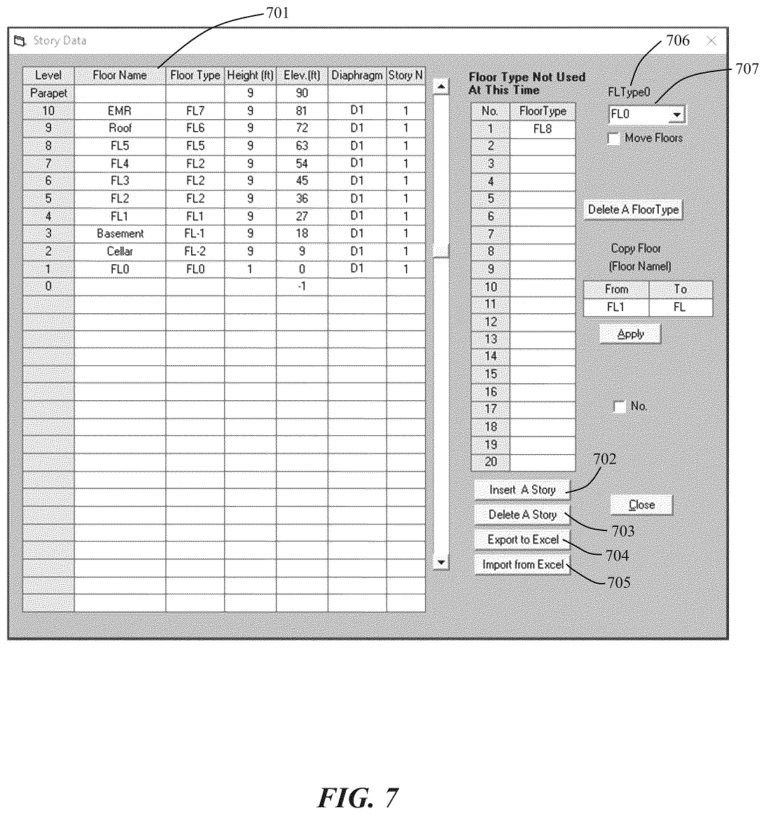

FIG. 7 is an interface used to input the story data, according to some embodiments of the present disclosure.

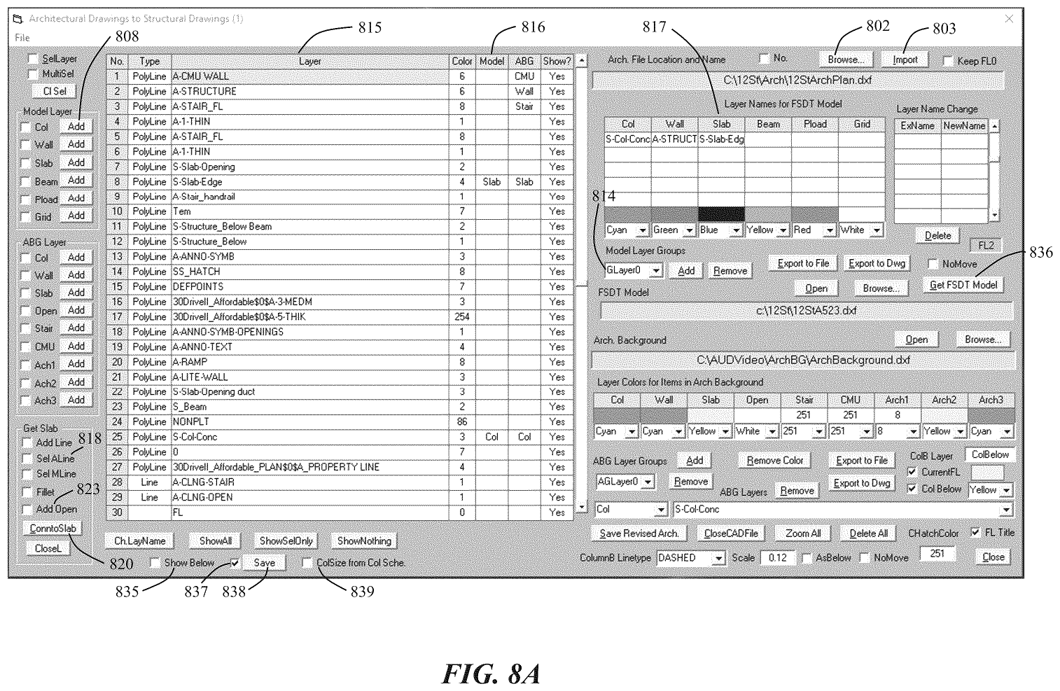

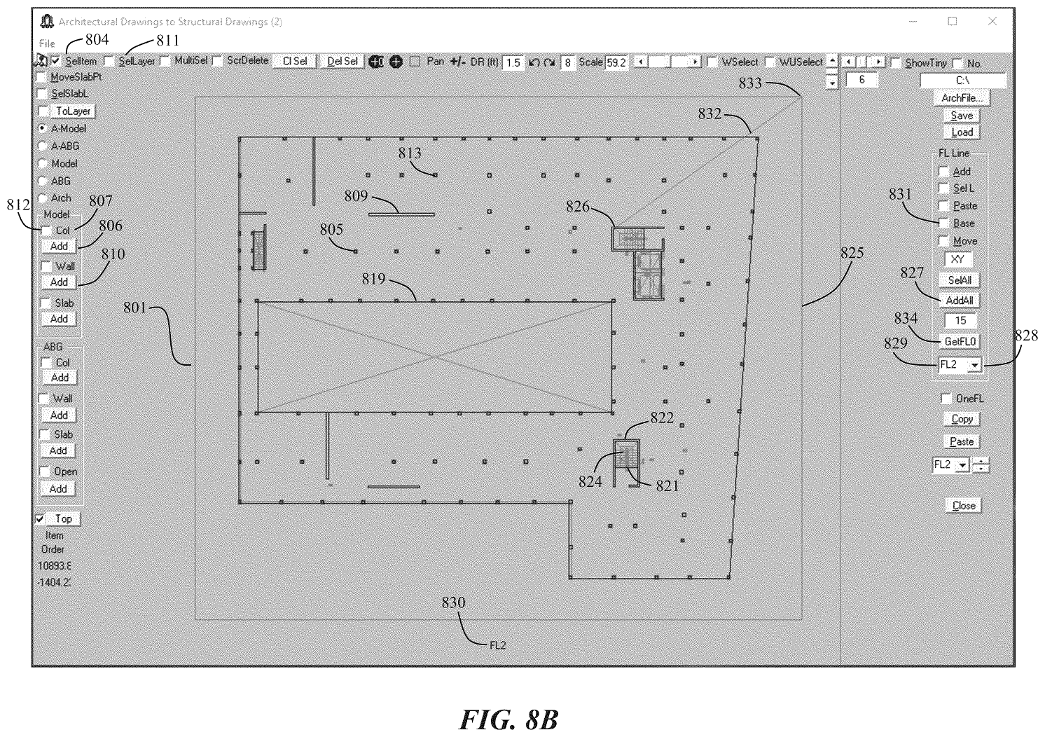

FIG. 8A is the first one of two interfaces used to obtain structural items from architectural drawings into FSDT program automatically, according to some embodiments of the present disclosure.

FIG. 8B is the second one of two interfaces used to obtain structural items from architectural drawings into FSDT program automatically, according to some embodiments of the present disclosure.

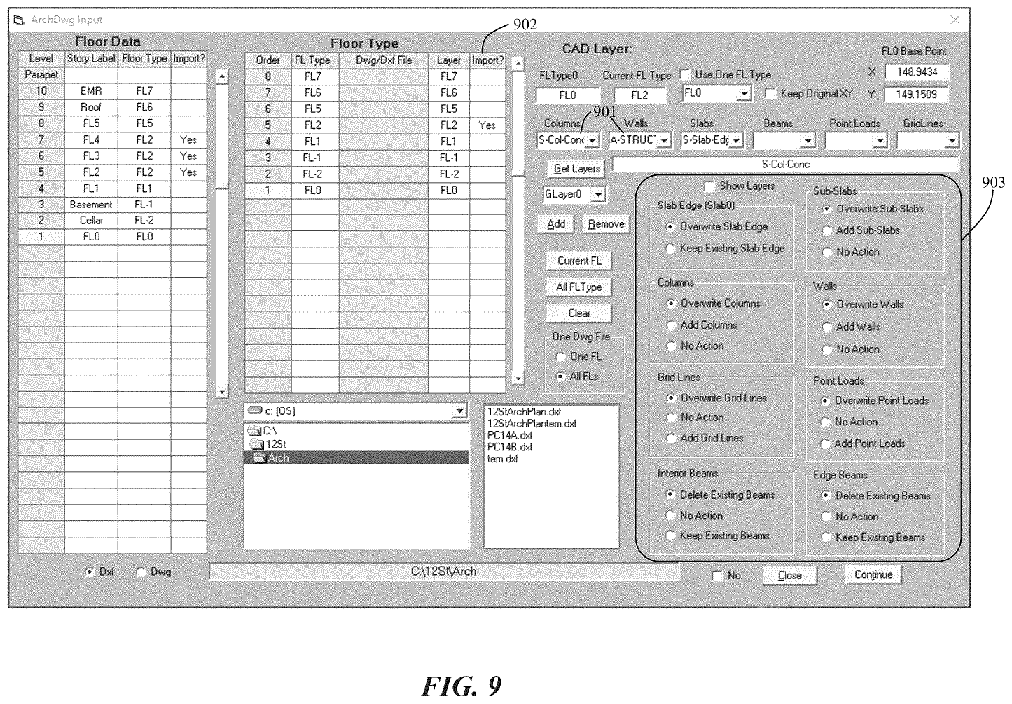

FIG. 9 is an interface used to obtain structural items from architectural drawings into FSDT program automatically with direct method, according to some embodiments of the present disclosure.

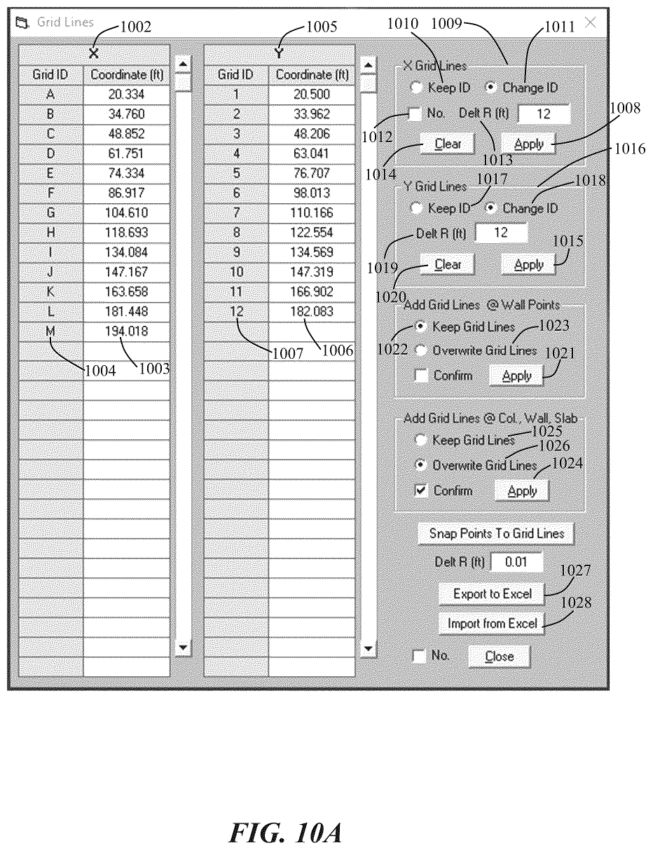

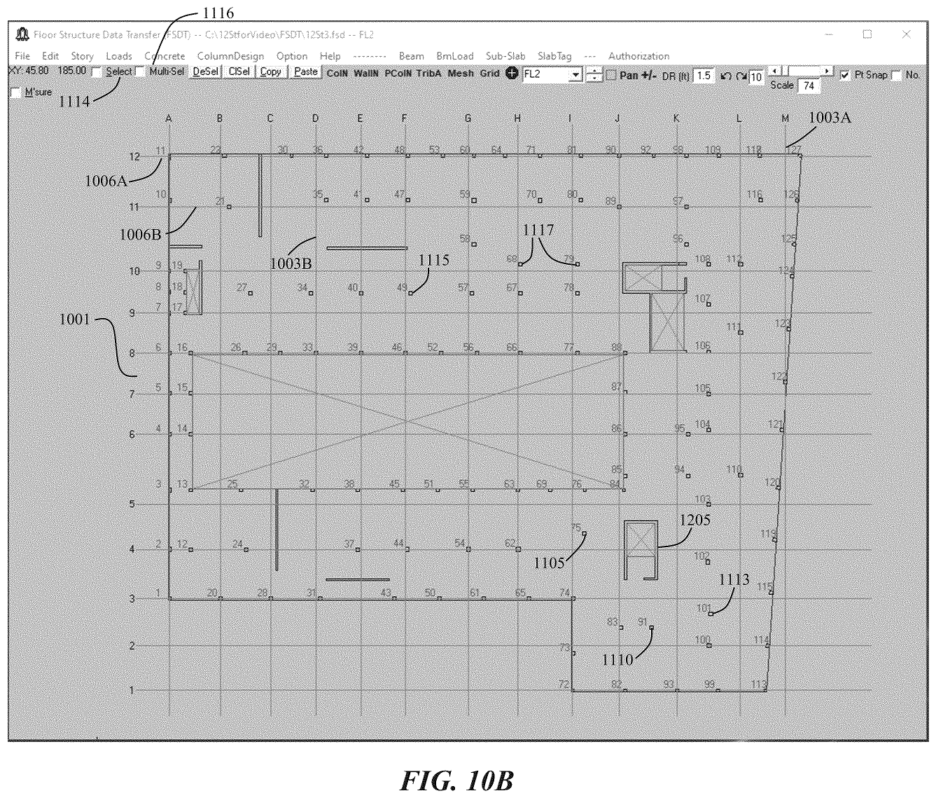

FIG. 10A is an interface used to draw and modify grid lines automatically, according to some embodiments of the present disclosure.

FIG. 10B is the main view interface of the FSDT program with a graphic display area showing grid lines, columns, and walls, according to some embodiments of the present disclosure.

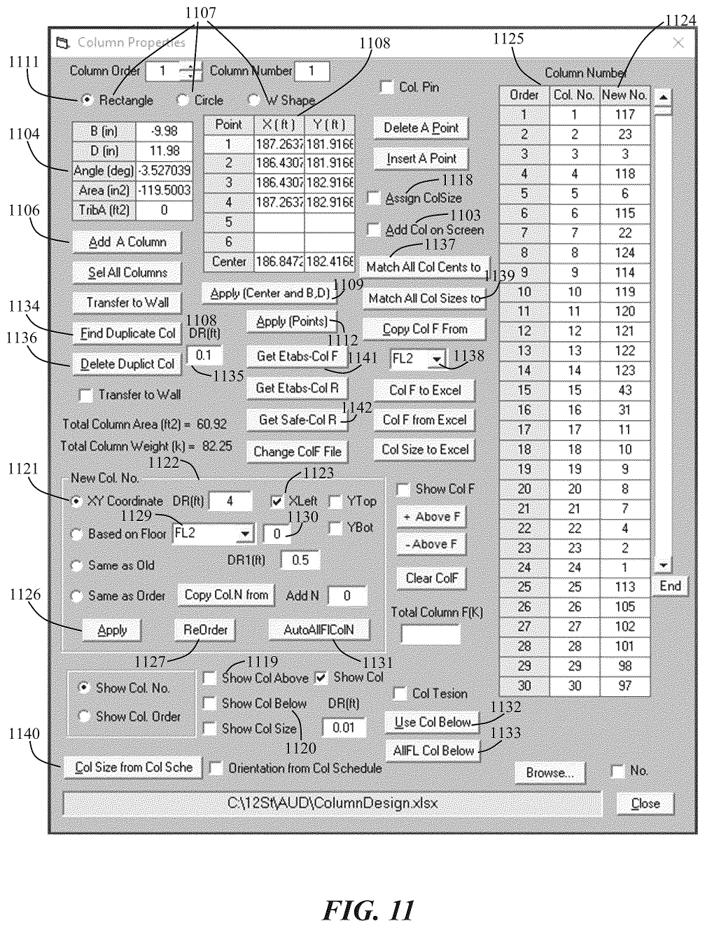

FIG. 11 is an interface used to draw and modify columns automatically, according to some embodiments of the present disclosure.

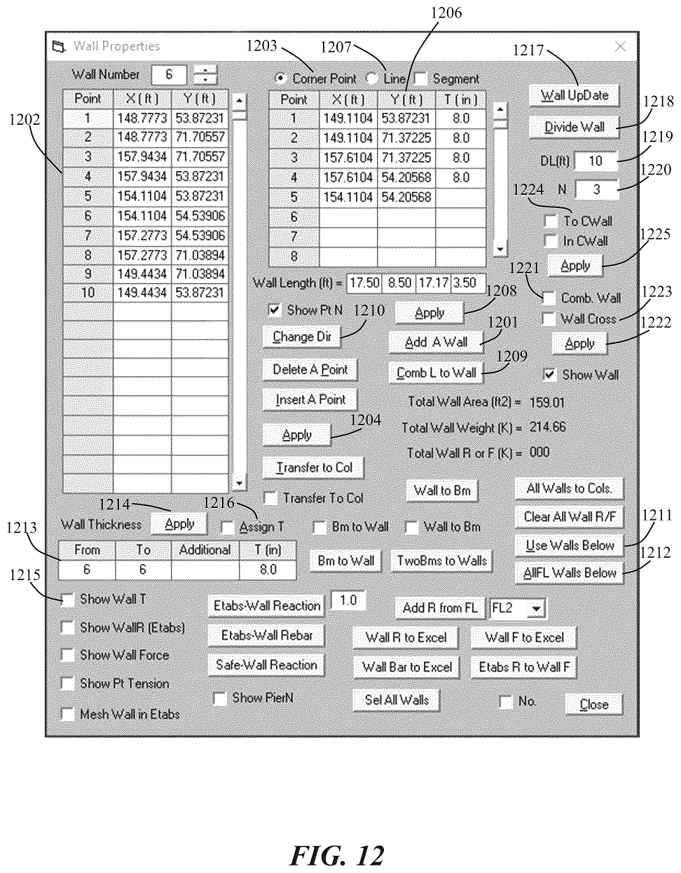

FIG. 12 is an interface used to draw and modify walls automatically, according to some embodiments of the present disclosure.

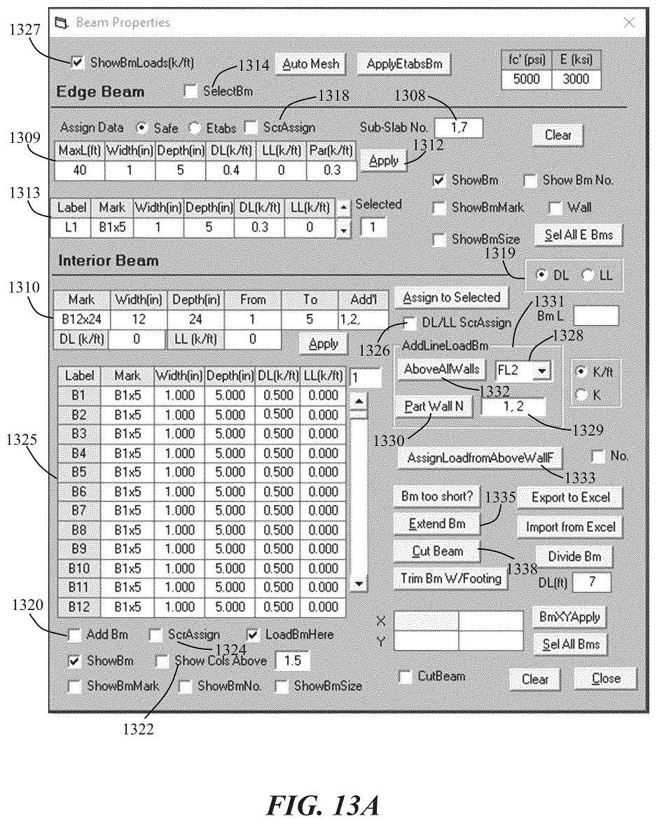

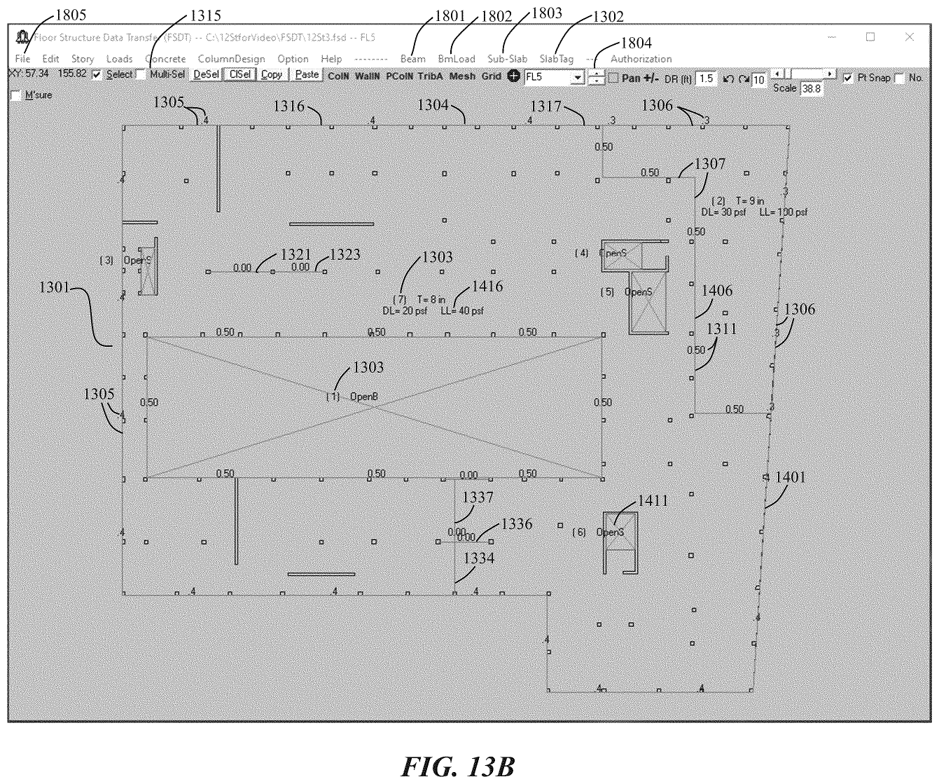

FIG. 13A is an interface used to draw and modify beams automatically, according to some embodiments of the present disclosure.

FIG. 13B is the main view interface of the FSDT program with a graphic display area showing columns, walls, beams, and slabs, according to some embodiments of the present disclosure.

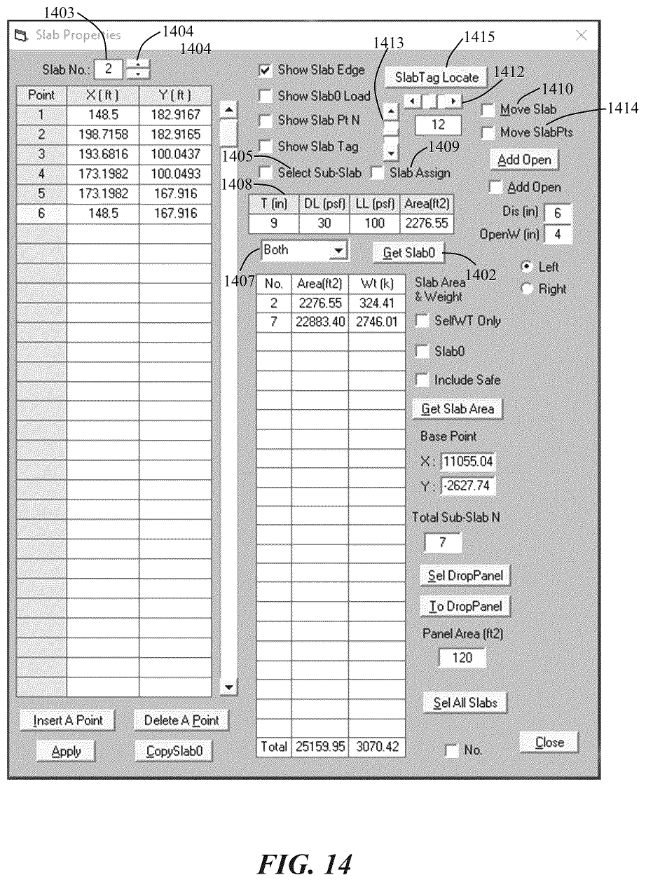

FIG. 14 is an interface used to draw and modify slabs automatically, according to some embodiments of the present disclosure,

FIG. 15A is an interface used to draw and modify drop panels automatically, according to some embodiments of the present disclosure.

FIG. 15B is the main view interface of the FSDT program with a graphic display area showing columns, walls, and drop panels, according to some embodiments of the present disclosure.

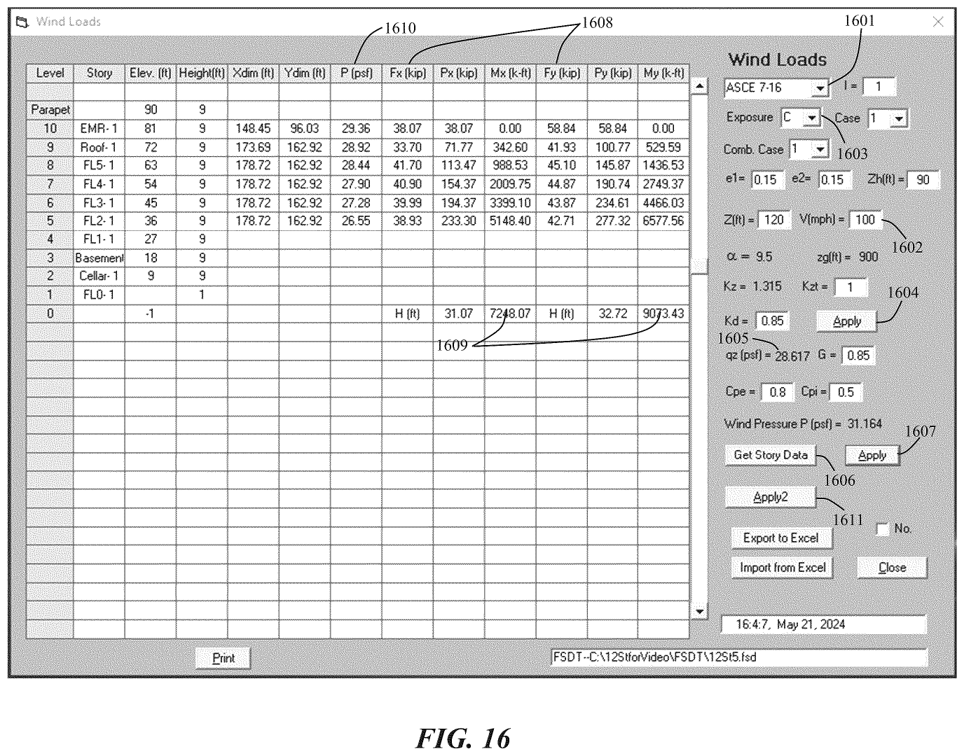

FIG. 16 is an interface used to input wind loads and get wind forces automatically, according to some embodiments of the present disclosure.

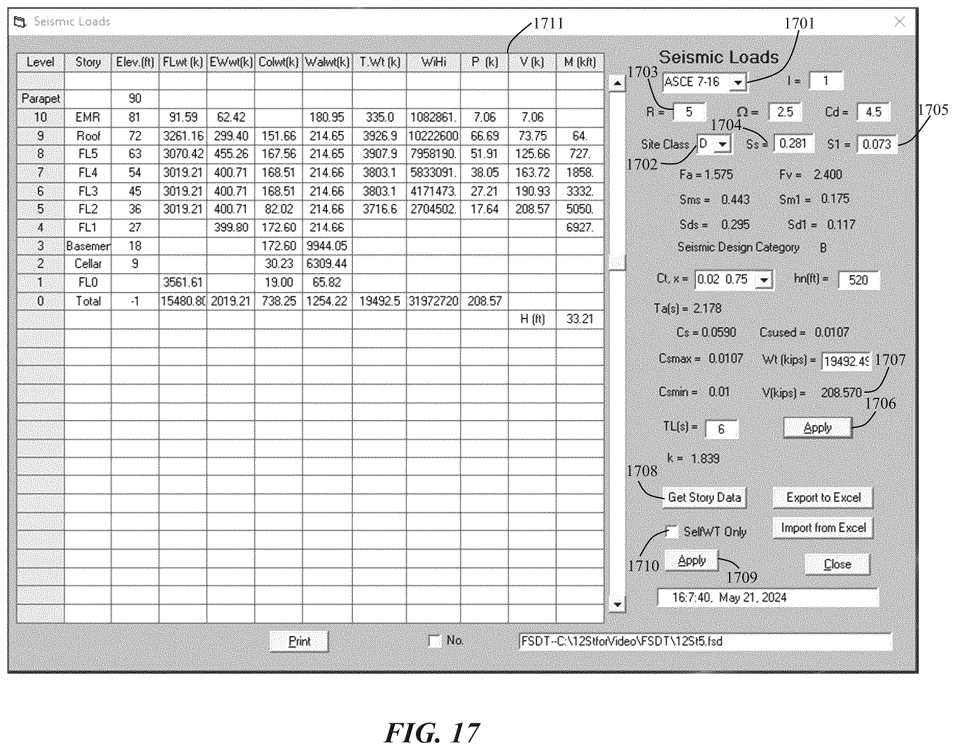

FIG. 17 is an interface used to input seismic loads and get seismic forces automatically, according to some embodiments of the present disclosure.

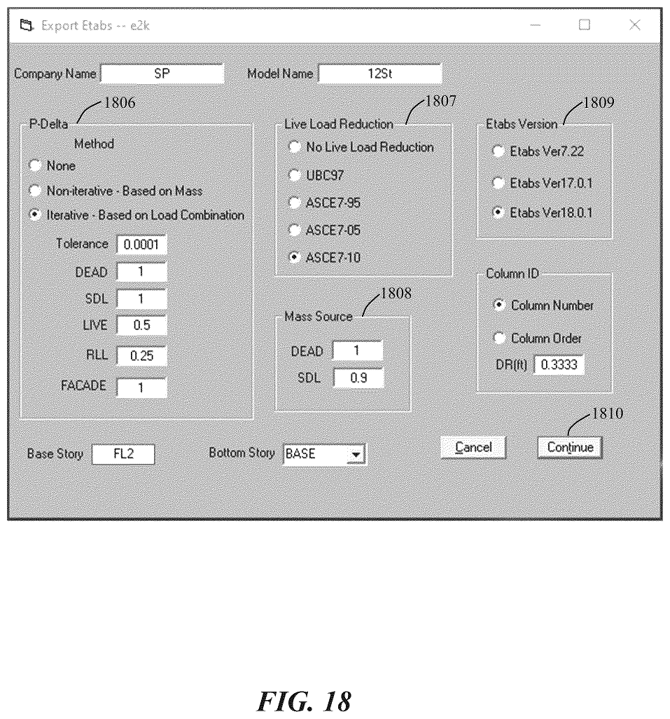

FIG. 18 is an interface used to export e2k file for Etabs model automatically, according to some embodiments of the present disclosure.

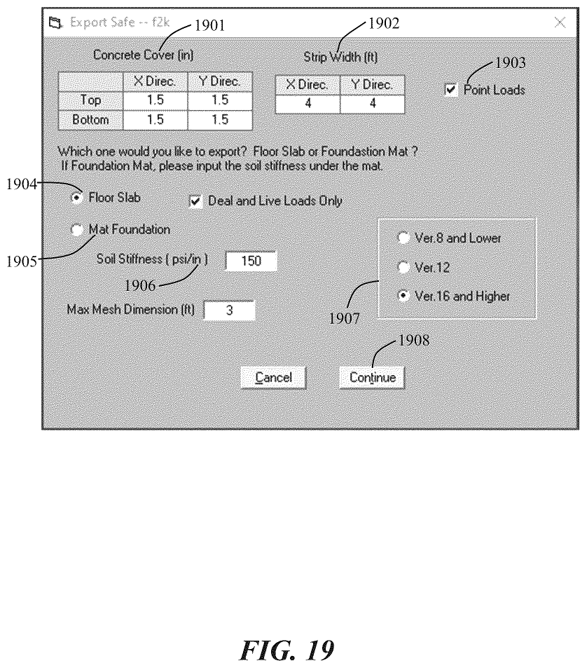

FIG. 19 is an interface used to export f2k file for Safe model automatically, according to some embodiments of the present disclosure.

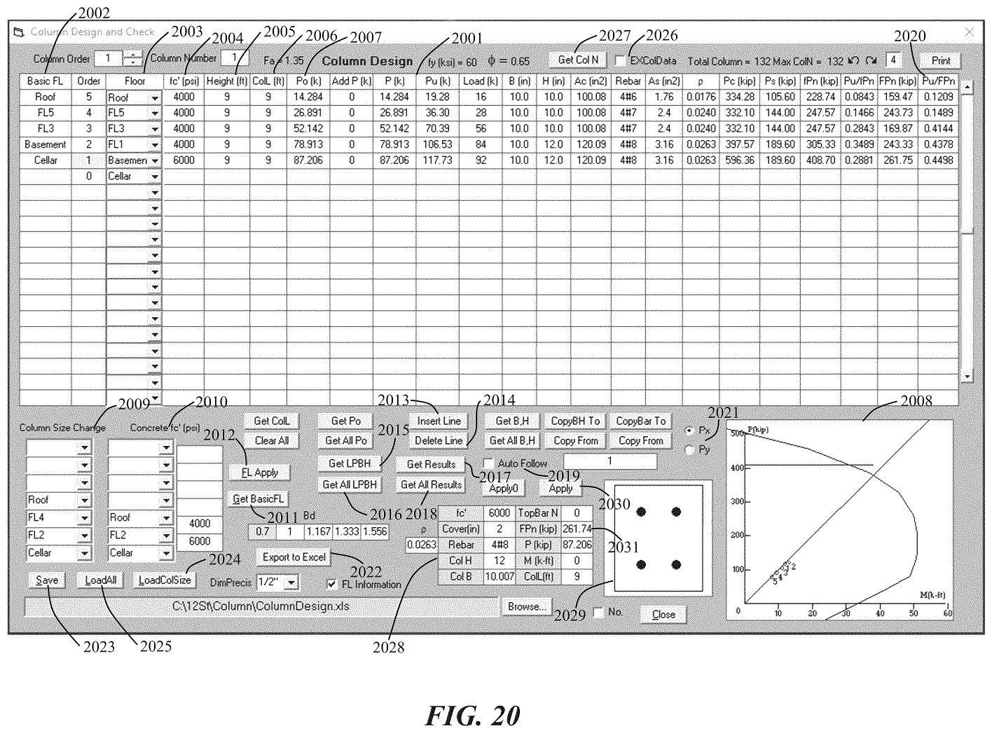

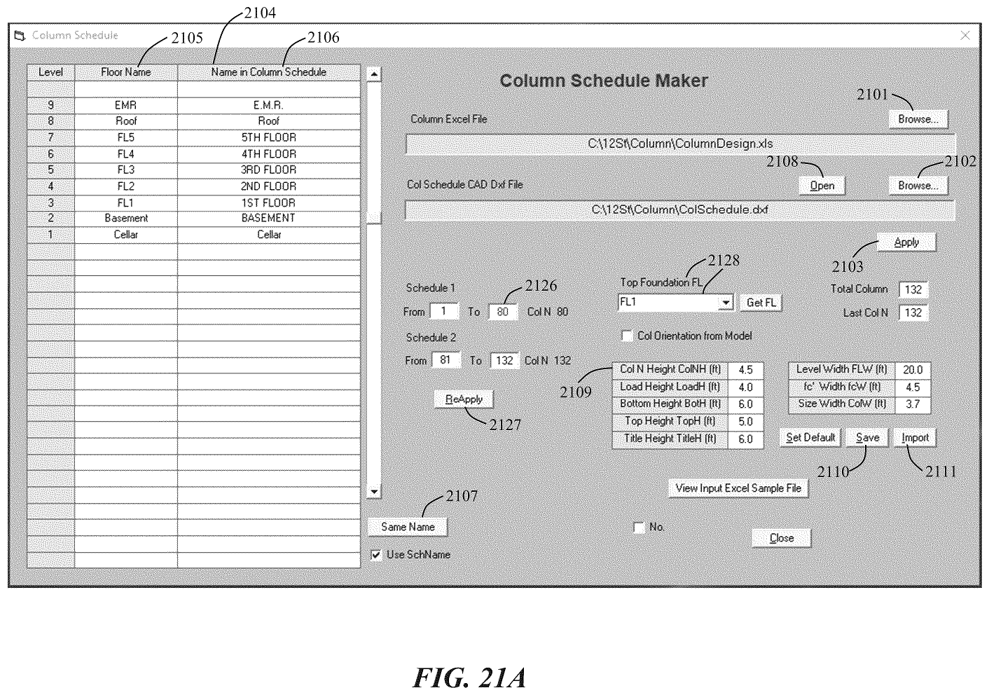

FIG. 20 is an interface used to design and check concrete columns, according to some embodiments of the present disclosure.

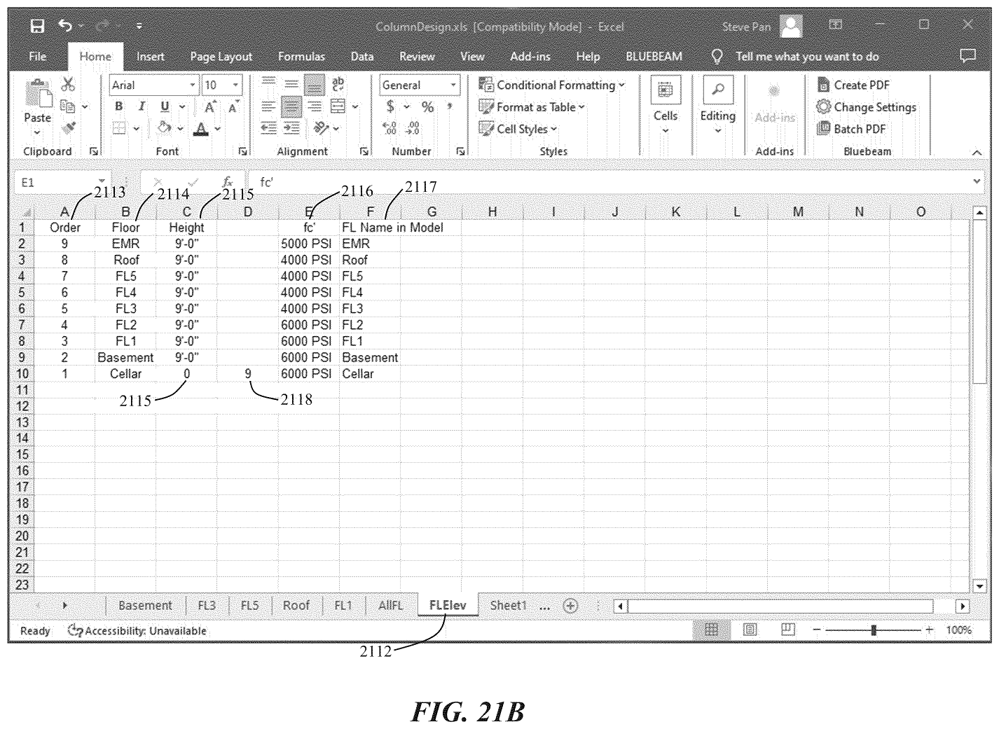

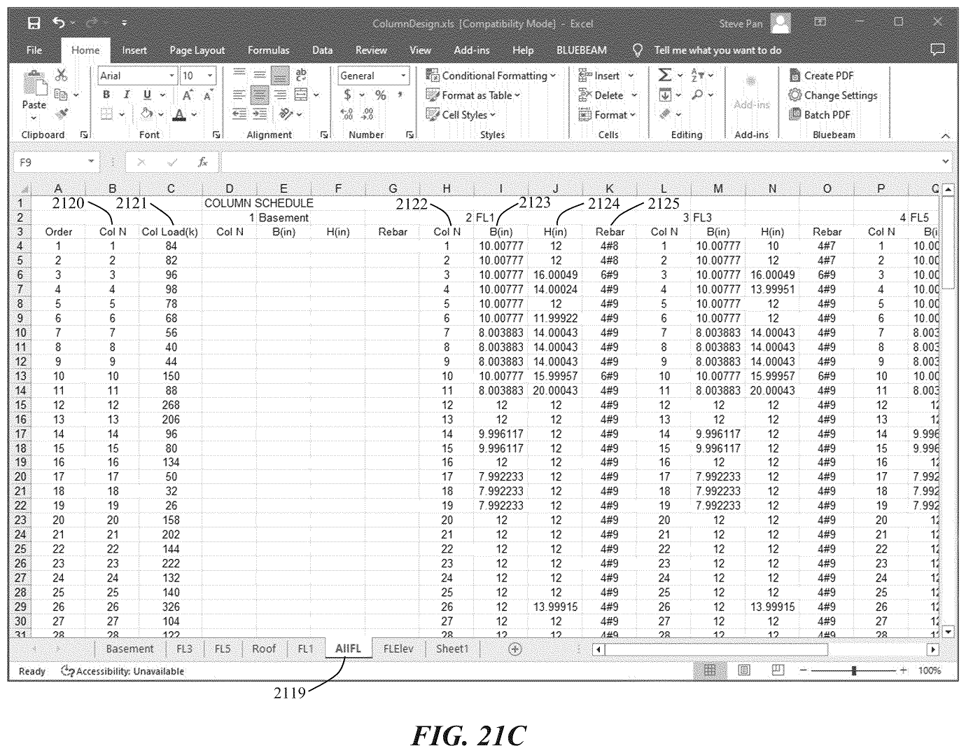

FIG. 21A is an interface used to make AutoCAD Column Schedule with AUD program automatically, according to some embodiments of the present disclosure.

FIG. 21B is the “FLElev” sheet in Column Excel File, according to some embodiments of the present disclosure.

FIG. 21C is the “AllFL” sheet in Column Excel File, according to some embodiments of the present disclosure,

FIG. 22A is the first one of two interfaces used to obtain structural drawing information from architectural drawings into FSDT and AUD programs automatically, according to some embodiments of the present disclosure.

FIG. 2213 is the second one of two interfaces used to obtain structural drawing information from architectural drawings into FSDT and AUD programs automatically, according to some embodiments of the present disclosure.

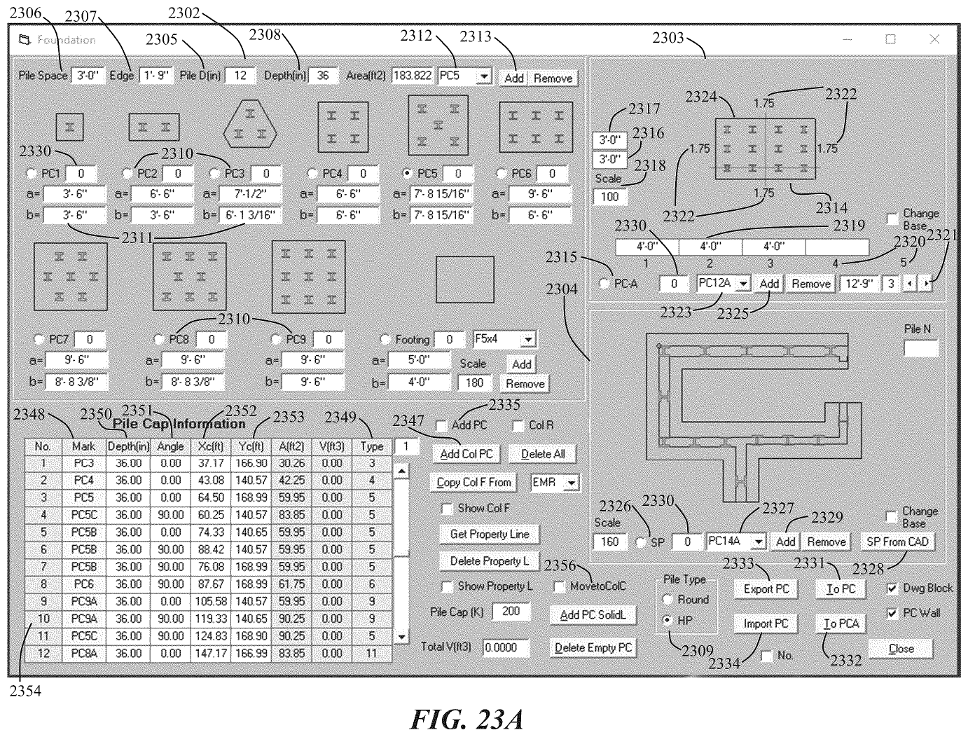

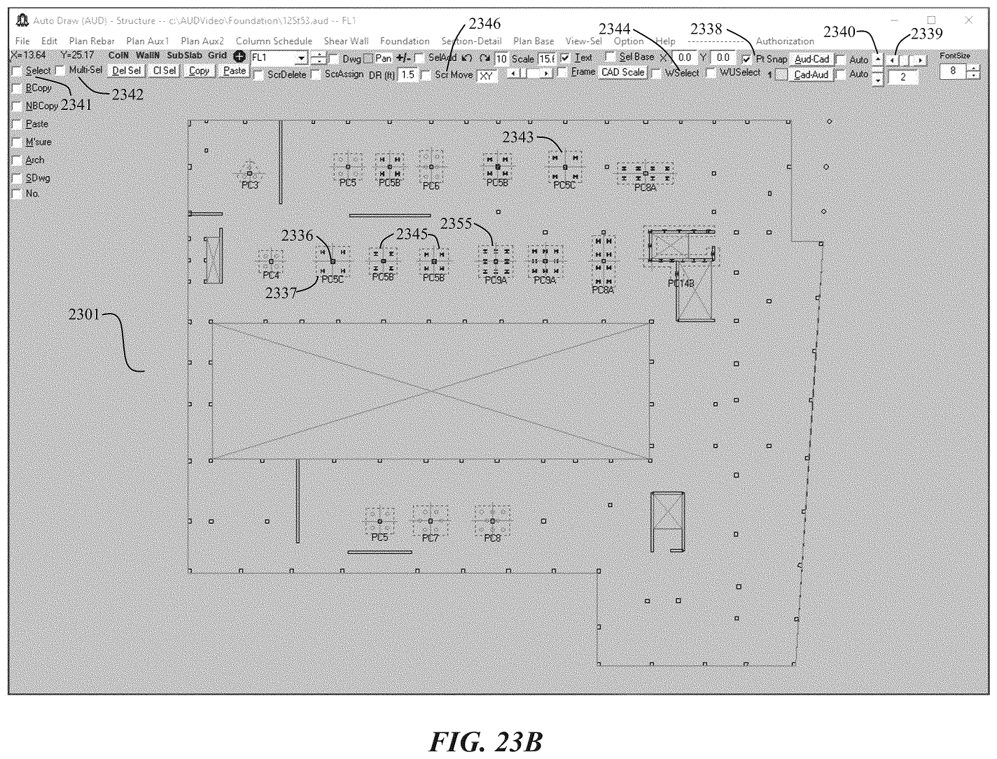

FIG. 23A is an interface used to make Typical Pile Cap Details and add pile caps on plan automatically, according to some embodiments of the present disclosure,

FIG. 2313 is the main view interface of the AU) program with a graphic display area showing columns, walls, and pile caps, according to some embodiments of the present disclosure.

FIG. 24A is an interface used to get original shear walls from the model plan of AUD program or from AutoCAD drawing automatically, according to some embodiments of the present disclosure.

FIG. 24B is the main view interface of the AUD program with a graphic display area showing columns and shear walls, according to some embodiments of the present disclosure.

FIG. 25 is an interface used to modify shear wall plans automatically, according to some embodiments of the present disclosure.

FIG. 26 is an interface used to get the shear wall rebars from the results of Etabs automatically, according to some embodiments of the present disclosure.

FIG. 27A is an interface used to draw and modify plan rebars automatically, according to some embodiments of the present disclosure.

FIG. 27B is the main view interface of the AUD program with a graphic display area showing columns, walls, and rebars, according to some embodiments of the present disclosure.

FIG. 28A is an interface used to draw CAD beams, column above-below symbols, column number symbols, section symbols, different elevation symbols automatically.

FIG. 28B is the main view interface of AUD program with graphic display area showing columns, walls, CAD beams, column above-below symbols, column number symbols, section symbols, and different elevation symbols, according to some embodiments of the present disclosure.

FIG. 29 is an interface used to draw and modify Typical Pile Cap Details automatically, according to some embodiments of the present disclosure.

### DETAILED DESCRIPTION OF THE DISCLOSURE

The disclosure will now be described more fully hereinafter with reference to the accompanying drawings, in which exemplary embodiments of the disclosure are shown. This disclosure may, however, be embodied in many different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example using italics and/or quotation marks. The use of highlighting and/or capital letters has no influence on the scope and meaning of a term; the scope and meaning of a term are the same, in the same context, whether or not it is highlighted and/or in capital letters. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only and in no way limits the scope and meaning of the disclosure or of any exemplified term. Likewise, the disclosure is not limited to various embodiments given in this specification.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below can be termed a second element, component, region, layer or section without departing from the teachings of the disclosure.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” to another feature may have portions that overlap or underlie the adjacent feature.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top”, may be used herein to describe one element's relationship to another element as illustrated in the figures. It will be understood that relative terms are intended to encompass different orientations of the device in addition to the orientation shown in the figures. For example, if the device in one of the figures is turned over, elements described as being on the “lower” side of other elements would then be oriented on the “upper” sides of the other elements. The exemplary term “lower” can, therefore, encompass both an orientation of lower and upper, depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, the terms “comprise” or “comprising”, “include” or “including”, “carry” or “carrying”, “has/have” or “having”, “contain” or “containing”, “involve” or “involving” and the like are to be understood to be open-ended, i.e., to mean including but not limited to.

As used herein, the phrase “at least one of A, B, and C” should be construed to mean a logical (A or B or C), using a non-exclusive logical OR. It should be understood that one or more steps within a method may be executed in different order (or concurrently) without altering the principles of the disclosure.

Typically, terms such as “about,” “approximately,” “generally,” “substantially,” and the like unless otherwise indicated mean within 20 percent, preferably within 10 percent, preferably within 5 percent, and even more preferably within 3 percent of a given value or range. Numerical quantities given herein are approximate, meaning that the term “about,” “approximately,” “generally,” or “substantially” can be inferred if not expressly stated.

As used herein, CAD stands for “computer-aided design”. Sometimes CAD means AutoCAD.

As used herein, AutoCAD is a CAD software program developed to draft and draw 2D and 3D models through graphic controllers and commands and developed by AUTODESK. This program aids designers, architects, engineers, and construction professionals in generating high-quality virtual models and drawings, optimizing the design process.

As used herein, Etabs is a structural engineering analysis and design software for earthquake and structural engineering, developed by Computers and Structures, Inc.

As used herein, SAFE stands for “Slab Analysis by Finite Element”. It is a specialized software program designed for the analysis and design of various types of foundation systems, including slabs, mat foundations, and rafts, and developed by Computers and Structures, Inc.

As used herein, FSDT stands for “Floor Structural Data Transfer”. FSDT is a software program that can obtain floor structural data from AutoCAD Drawings automatically and setup Ready-to-Run Etabs model automatically. FSDT is a software program of the invention.

As used herein, AUD stands for “Automatic Drawing”. AUD is a software program that let the user draw the structural drawings automatically. AUD is a software program of the invention.

As used herein, FL Line is a closed polyline, shown on floor plan, that surrounds all structural items and non-structural items of one floor to determine the region of floor area.

Embodiments of the disclosure are illustrated in detail hereinafter with reference to accompanying drawings. It should be understood that specific embodiments described herein are merely intended to explain the disclosure, but not intended to limit the disclosure. In accordance with the purposes of this disclosure, as embodied and broadly described herein, this disclosure, in certain aspects, relates to automatically designing and automatically drawing of building structure.

The method is implemented by operating a graphical display interface and a control operation interface. The graphical display interface is used to display drawing results, and the control operation interface is used to display parameters and command function keys, receive user operation commands, perform automatic processing regarding structural design, set-up calculation model and structural drawings, and display the drawing results on the graphic display interface. The method includes:
Step 1: Read the architectural drawings, obtain structural item information and other non-structural item information related to the structural drawings from the architectural drawings, add FL Lines and base points automatically. Structural items include grid lines, columns, walls, beams, floor slabs and slab opens, information related to structural drawings includes stairs, elevators and CMU walls, etc.
Step 2: Edit the structural items and add loads automatically. The editing of the structural items includes the automatic addition and modification of columns, walls, beams, floor slabs, slab opens, and drop panels, comparison and adjustment of columns between associated floors. Adding loads including floor loads, line loads and point loads on slabs and beams.
Step 3: Export the whole building calculation model data file for Etabs, and floor data file for Safe automatically, Etabs and Safe programs can import the calculation model data file and run the model immediately. If the calculation results meet the predetermined standards, go to step 5, otherwise go to step 4.
Step 4: Obtain the calculation results from the Etabs and Safe programs, adjust and edit the structure items according to the calculation results, and repeat step 3.
Step 5: Design and check all column capacities for whole building with slenderness considered automatically in FSDT and make column schedule automatically with AUD program.
Step 6: Based on Safe results, design beams and make floor framing plans automatically, including CAD beams and slab reinforcement with AUD program.
Step 7: Based on Etabs results, design foundation automatically, including pile cap and footing. make foundation plan drawings with AUD program automatically.
Step 8: Add and modify column above-below symbols, section symbols, CAD beams, column number symbols, different elevation symbols and others automatically with AUD program.
Step 9: Based on Etabs results, design shear walls and make shear wall plans automatically with AUD program.
Step 10: Draw and modify CAD drawings for Typical Pile Cap Details automatically with AUD program.
Step 11: Export special Architectural items as the background of structural drawings automatically, which include columns, walls, slabs, opens, Stair, CMU walls, and others.
Step 12: displaying or printing the structural drawings.

The invention provides special operation interfaces for users, including an interface for graphic display area and an interface for control operation area. The graphic display area is used to display drawing results. The control operation area includes parameter controls and command function keys. The parameter controls are used to input, receive and display structural item parameters, the command function keys are used to execute one or more actions of structural automatic design and drawings, and display the drawing results in the graphics display area. By clicking some function keys, the user not only can perform all processes of automated design and drawing of building structure, but also can control and adjust each step in the automatic design and drawing process. Because the relevant parameters that need to be known and considered are always displayed on the special control operation interface, which can be easily modified immediately, the most operation command function keys are also always on the control operation interface, which can be operated immediately, and the graphical results are displayed immediately, so the user can always well aware of each details regarding the structural automatic design and drawing, and be confident to fast perform the structural automatic design and drawing.

FIG. 1 is a flowchart illustrating the special characteristics of the present disclosure and invention, according to some embodiments of the present disclosure.

In some embodiments, at 102, the method may include putting order numbers for all buttons, checkboxes, textboxes, labels and others on user interfaces to let the user find buttons on user interfaces easily and find their explanation in program manual easily.

The implementation process of putting order numbers for all buttons, checkboxes, textboxes, labels and others on user interfaces to let the user find buttons on user interfaces easily and find their explanation in program manual easily is described below with the reference to FIG. 6. The user interface shown in FIG. 6, used to draw and modify columns automatically, is an example of the implementation process of putting order numbers for all buttons, checkboxes, textboxes, labels and others on user interfaces to let the user find buttons on user interfaces easily and find their explanation in program manual easily, according to some embodiments of the present disclosure.

Click “No.” checkbox 601, the order numbers 602 for all buttons, checkboxes, textboxes, labels and others will be shown in the user interface, then the user can find them in manual of FSDT program easily, since the order numbers of buttons, checkboxes, textboxes, labels and others in manual are same as in this user interface. In same way, if a user likes to find where is the item (the item that is shown in FSDT manual) on this user interface, it will be very easy based on the order number in the manual of FSDT.

In All the user interface of FSDT and AUD programs, the order numbers for buttons, checkboxes, textboxes, labels and others can be shown with one click and the order numbers of buttons, checkboxes, textboxes, labels and others in the manual of FSDT and AUD programs are same as in the user interfaces.

In some embodiments, at 104, the method may include that all commands and parameters are put together.

In FSDT and AUD program, all command buttons 603 and the parameters 604 for structural items or related to structure analysis are put in one user interface together, so that they can be always seen and can be clicked immediately when needed. At present, many computer users have two monitors connected to one computer. In this way, the main graphic display area of drawing layout can be placed on the main monitor, and the control operation interface dedicated to placing command buttons and parameters can be placed on another monitor. It is very convenient to performe the structural automatic design and drawing. The purpose of the FSDT and AUD program is to let the user avoid to close one user interface and open another user interface when process one thing, thereby reducing the automatic design and drawing time.

In some embodiments, at 106, the method may include that the section definition is not required when adding column or beam, and the section definitions are made automatically when need.

When add column or beam, section definition is no more required in FSDT and AUD programs, may be made automatically when need. In FSDT program, the user only needs to open a interface for beam operation, input the beam width, beam height, dead load and live load on it, then the beam can be conveniently added on the plan. The loads are added at the same time automatically. The commands for handling beams are also on this interface, the beam section dimensions and parameters are always shown in the interface, some other beam modification can be done in this interface too. The definitions of the beam sections are automatically made by FSDT program when need to import them into Etsbs and Safe programs.

Columns and walls can also be added in the same way, but without loads. If required, the user can select all the beams with the same section in the FSDT and AUD program. The pile cap can be added with similar way, the definition of the pile cap is automatically completed during the process of adding the pile cap.

FIG. 2A is a flowchart illustrating a method to obtain structural items from architectural drawings, and setup Ready-to-Run Etabs and Safe models automatically with FSDT, according to some embodiments of the present disclosure.

FIG. 2B is a flowchart extending from FIG. 2A and further illustrating the process to obtain structural items from architectural drawings, and setup Ready-to-Run Etabs and Safe models automatically with FSDT, according to some embodiments of the present disclosure.

In some embodiments, at 202, the method may include inputting the story data.

The implementation process of inputting the story data is described below with reference to FIG. 7. FIG. 7 is an interface used to place command buttons and item parameters related to input the story data, according to some embodiments of the present disclosure.

In this interface shown in FIG. 7, there is a Story Data Table 701 which has total 7 items, that is “Level”, “Floor Name”, “Floor Type”, “Height”, “Elev.”, “Diaphragm” and “Story N”. The “Level” is the floor order which cannot be changed by the user. The user can select one floor by clicking the “Level” number at that floor. “Floor Name” can be changed by retype it. “Floor Type” is used for some similar floors whose columns, walls and other structural items are all same. FSDT and AUD programs use one special floor information for these similar floors, called “Floor Type”. “Height” is the floor height. The user can change “Height” by retype it, then the “Elev.” will change automatically. “Elev.” is the floor elevation. To change “Elev.”, just retype it and press Enter key in keyboard. The floor height will change automatically. “Diaphragm” is used for Etabs model, which can be changed by retype it. “Story N” is the story number for this floor name, which is used only for calculating the concrete volume.

The user can input the story data information with this Story Data Table. Click “Insert A Story” button 702 to insert a story, click “Delete A Story” button 703 to delete a story.

Click “Export to Excel” button 704, the story data information is exported to Excel file. The user can make some changes in Excel file, then click “Import from Excel” button 705, the new story data information is imported into the FSDT and AUD programs.

FLType0: FLType0 706 is a special floor type in FSDT program. All items in FLType0 705 will keep in their original location when they are transferred into FSDT model from architectural drawings. For all other floors, all items will be moved based on their base points with FLType0 706. In this way, the same columns, walls and other items will be aligned at the same locations. FLType0 705 floor is determined in this interface. Click the FLType0 Drop-Down Menu 707, then select the FLType0 706. Sometimes in architectural drawings, all floors are far away from the original point (0,0). The user can make a virtual floor which is near original point (0,0). Select this virtual floor as FLType0 706, then all other original real floors will be moved to the location near the original point (0,0).

In some embodiments, at 204, the method may include obtaining structural items from architectural drawings into FSDT and AUD programs Automatically.

The implementation process of obtaining structural items from architectural drawings into FSDT and AUD programs automatically is described below with reference to FIG. 8A, FIG. 8B and FIG. 9. FIG. 8A is the first one of two control operation interfaces used to place command buttons and item parameters related to obtain structural items from architectural drawings into FSDT program automatically, according to some embodiments of the present disclosure. FIG. 8B is the second one of two control operation interfaces used to place command buttons and item parameters related to obtain structural items from architectural drawings into FSDT program automatically, the lower display area of FIG. 8B is the graphic display area 801, according to some embodiments of the present disclosure. FIG. 9 is an interface used to place command buttons and item parameters related to obtain structural items from architectural drawings into FSDT program automatically with direct method, according to some embodiments of the present disclosure.

AUD program, which is a software program in the invention, used to draw structural drawings automatically, also has these two interfaces used to obtain structural items from architectural drawings, as shown in FIG. 8A and FIG. 8B.

The AutoCAD drawings of Architectural drawings or structural drawings can be one floor one file, or all floors are in one file. Structural drawings can also be considered as architectural drawings to obtain structural items.

Click the “Browse” button 802 in FIG. 8A to locate the AutoCAD architectural drawing file in the computer. Click the “Import” button 803 in FIG. 8A to import the architectural drawings, one floor or all floors of the architectural drawings are imported, shown in the graphics display area 801.

After importing the architectural drawings into FSDT program, there are many methods to transfer structural items from architectural drawings into FSDT model, as described below.

Click the “SelItem” checkbox 804 in FIG. 8B, select any structural item in the architectural drawing displayed in the graphic display area 801. If clicking column 805, the edge of column will turn into a different color to indicate that the column is selected. Then click the “Col-Add” button 806 in “Model” frame 807. The columns with the same layer on all floors in the building will be added into FSDT structural items for model. If clicking the “Col-Add” button 808 corresponding to the column in FIG. 8A, it will have same effect. The same method is used to obtain walls and other structural item information. If the user clicks on wall 809, the wall will change color to indicate that the wall is selected. Then click the “Wall-Add” button 810 in “Model” frame 807, the walls in all floors of the building which will have the same layer will be added into FSDT structural items for model.

The user can also select the “SelLayer” checkbox 811 in FIG. 8B to select structural item. Click a structural item on floor plan 801, all structural items with same layer in all floors will be selected. Then add selected items into FSDT structural items for model with same way.

Click structural item checkbox, like “Col” checkbox 812, then click an item 813 which belong to column in architectural drawing 801, all items which have same layer with clicked column 813 are added into FSDT structural items for model.

The layer names for all structural items in architectural drawings are saved in each FSDT file. FSDT program considers all layer names are in one layer-group 814, and the user can name it. One project (or one FSDT file) can have several layer groups 814. The user can use this layer group 814 for all structural items now, and then use another layer group 814 for all structural items later.

The user can change the layer property in Architectural Drawing Layer Table 815, can add or delete structural items for FSDT model. All structural items are shown in “Model” column 816, and the cell in “Model” column 816 can be used to add or change the FSDT item name or delete a layer for FSDT item. To add a layer for FSDT structural item, just add FSDT structural item name at this “Model” column 816, and at the row with the layer name, then press Enter key, the layer will be added. To change the FSDT structural item name for a layer, just retype the name in the cell and press enter key. The layer will be changed to a new FSDT structural item. To delete a layer for FSDT structural item, just delete FSDT item name at this “Model” column 816 and at to be deleted layer's row, then press Enter key, the layer will be deleted.

The user can change the layer property in “Layer Names for FSDT Model” table 817 to change structural items for FSDT model. The layer names are from architectural drawings. All layers in architectural drawings which are shown in this table will be transferred into FSDT structural items. FSDT model has 6 kinds of structural items, that is Col (Column), Wall, Slab (Open considered as slab), Beam, Pload (Point Load) and Grid. Total 5 layers is a limit for each kind of structural items here. If there are more than 5 layers in architectural drawings belong to one item, like wall, the user needs to change the layer name in architectural drawings, as shown in Manual. There are three functions for this table cells. 1) Sometimes, the layer name is very long, so the cell space in this table is not enough. To solve this problem, the user can click this cell, then the layer name in left big table that is same as the layer name in this cell will be highlighted, the user can see the layer name there, where the space is bigger. 2) The user can add, change or delete a layer name in this table, then press Enter key to finish it. 3) The user can change the layer name for the items in architectural drawing with this table. Please see the manual of FSDT for details.

The invention can connect several unconnected straight lines to form floor slabs. First click the “Sel ALine” checkbox 818 and click on some straight lines 819 that make up floor slab in the architectural drawing. The straight lines will turn into different color to indicate that they are selected. Click “ConntoSlab” button 820 in FIG. 8A, the selected straight lines will be automatically connected into floor slab edges.

The invention can easily add rectangular slab open. First click the “Sel ALine” checkbox 818 in FIG. 8A and select some straight lines 821 or polylines in architectural drawings. If wall 822 is used as the edge of the open, it is not required to select it. It will be automatically considered as selected. Click “Add Open” button 823 and click on a point 824 within the open area on the screen, the rectangular open 824 is added automatically.

To separate the region of each floor for a whole building, the invention can automatically add FL Line box 825 for each floor to determine the region of floor area and assign the floor type. And add base points 825 for each floor to obtain relationship of each floor. These FL line boxes 825 can be moved and modified easily and automatically.

Click “AddAll” button 827, FL Lines 825 will be automatically added around each floor of all floors. If there is a problem with a FL Lines 825, the user can add FL lines individually and manually for a floor.

Click “SelItem” checkbox 804, click a FL Line 825 to select it, the FL Line 825 will turn into different color to indicate that it is selected, click Floor Drop-Down Menu 828 and select the floor type name 829 in Floor Drop-Down Menu 828 to assign floor type. The floor type name 830 will be displayed near the selected FL line 825.

Click “Base” checkbox 831 to check it, go to a floor that needs to add base point, click a point 826 on the column, wall, slab or other obvious point of a floor, the base point 826 for this floor is added. A line 832 from the base point 826 to the closest point 833 of FL line 825 is automatically added, indicating the base point 826 for this floor has been added.

In some cases, the contents in architectural or structural drawings are far away from the coordinate origin (0,0). Sometimes the user wants all contents to be close to the coordinate origin (0,0). The present invention can add a virtual floor FL0 near the coordinate origin (0,0), which is a copy of a real floor. Like other floors, a base point is also added to FL0. When the structural items from the architectural drawing are transferred to the structural model, the present invention will move the structural items according to the relationship between the FL0 base point and the base point of each floor, that is, move all real floors so that the base point positions are consistent with the FL0 base point, and all floors are aligned according to the base points. And the contents for all floors will be near the coordinate origin (0,0). Furthermore, all floors can be moved together by moving FL0.

Click “SelItem” checkbox 804 in FIG. 8B, click on a FL line 825 of a certain floor to select it, click “Get FL0” button 834 in FIG. 8B, FLO which is a replica of selected floor is added automatically.

Click “Show Below” checkbox 835 at the bottom of FIG. 8A, the columns and walls below current floor will be shown on the plan. The user can check the columns and walls below and see the columns below are aligned or not.

There is another method in the invention, used to get columns, walls, slabs and other structural items from architectural drawing into FSDT model directly and automatically. The implementation process is described with reference to FIG. 9. In his method, the user just input the CAD layer names (Shown in Layer Name Drop-Down Menu 901 for structural items) for columns, walls, slabs and other structural items, which are in architectural drawings, but will not see the plans directly in FSDT program. Furthermore, there are many options in this method. The user can select several floors to import, and several floors not to import (Shown in “Floor Type” table column “Import?” 902, can select some structural items to import, and some structural items not to import 903, can overwrite the existing structural items or keep the existing structural items 903. For this method, the user needs to make a special AutoCAD drawing, called FSDT drawing, which includes all structural items and some necessary information. The user needs to add FL lines and base points for each floor.

After obtaining all structural items from architectural drawings, click “Get FSDT Model” button 836, the user can get the FSDT model immediately and automatically based on obtained structural items with one floor or all floors. If the architectural drawing is one file one floor, then the user will get one floor plan each time click. If the architectural drawing is one file all floors, then the user will get all floor plans with one time click.

The present invention has a memory function, saving all structural item parameters established when working on a project. No action is required when the architectural drawing is imported for the second time; all the structural items and other items in the architectural drawing are automatically imported into the FSDT model, even if there are some changes in architectural drawings. Furthermore, the invention displays structural item parameters in the Architectural Drawing Layer Table 815 and “Layer Names for FSDT Model” Table 817, so the structural items layer information is very clear at a glance. The users can easily change any parameter in Tables 815 and 817. For example, if the user wants the columns with layer A no longer to be considered, he or she only needs to delete the column name “Col” for layer A in Layer Table 815.

When the architectural drawings are one file for one floor, and when need to consider columns and walls below, it is required to save one floor information for the utilization of another floor. If the “Save” checkbox 837 is checked, any change of columns and walls for current floor will be saved at same time. If this checkbox 837 is not checked, then any change of columns and walls for current floor will not be saved. Click “Save” button 838, the invention will save the information of columns and walls for current floor immediately. In this way, the user can control the time when to save the columns and walls for current floor.

FSDT program can get column sizes from column schedule and update the column sizes in architectural background drawing. Click “ColSize from Col Sche” checkbox 839, select an Excel file, then get column sizes from column schedule (Excel file).

In some embodiments, at 206, the method may include drawing and modifying the grid lines automatically.

The implementation process of drawing and modifying the grid lines automatically is described below with reference to FIG. 10A and FIG. 10B. FIG. 10A is a control operation interface used to place command buttons and item parameters related to draw and modify grid lines automatically, according to some embodiments of the present disclosure. FIG. 10B is the main view interface of FSDT program, the lower display area of FIG. 10B is the graphic display area showing grid lines, columns, and walls 1001, according to some embodiments of the present disclosure.

X Grid Line Table: X Grid Line Table 1002 shows all X grid lines. The user can add, select and revise grid lines in this table. Just type one X coordinate 1003 in table 1002 and press Enter key in keyboard, one X grid line 1003A is added in FIG. 10B. To select a grid line, just click X grid line ID 1004 or coordinate 1003. To revise grid line, just retype the coordinate 1003 and press Enter in keyboard.

Y Grid Line Table: Y Grid Line Table 1005 shows all Y grid lines. The user can add, select and revise grid lines in this table. Just type one Y coordinate 1006 in table 1005 and press Enter key in keyboard, one Y grid line 1006A is added in FIG. 10B. To select a grid line, just click Y grid line ID 1007 or coordinate 1006. To revise grid line, just retype the coordinate 1006 and press Enter in keyboard.

Update the X grid lines: Click the “Apply” button 1008, the FSDT program will update the X grid lines based on the information in X Grid Line Table 1002 and “X Grid Lines” frame 1009. If the “Keep ID” option 1010 is selected, then the X grid line ID 1004 will not change. If the “Change ID” option 1011 is selected, then the X grid line ID 1004 will reorder automatically. If “No.” checkbox 1012 is checked, and “Change ID” option 1011 is selected, the invention will use 1, 2, 3 as X grid line ID 1004. If this “No.” checkbox 1012 is not checked, the invention will use A, B, C as X grid line ID 1004. “Delt R” 1013 is the minimum distance between two near X grid lines. If there are two X grid lines with distance less than “Delt R” 1013 value, one grid line will be deleted. Click “Clear” button 1014 will delete all X grid lines.

Update the Y grid lines: Click the “Apply” button 1015, the FSDT program will update the Y grid lines based on the information in Y Grid Line Table 1005 and “Y Grid Lines” frame 1016. If the “Keep ID” option 1017 is selected, then the Y grid line ID 1007 will not change. If the “Change ID” option 1018 is selected, then the Y grid line ID 1007 will reorder automatically. “Delt R” 1019 is the minimum distance between two near Y grid lines. If there are two Y grid lines with distance less than “Delt R” 1019 value, one grid line will be deleted. Click “Clear” button 1020 will delete all Y grid lines.

Add Grid Lines at wall points: Click “Apply” button 1021 to add grid lines at wall points. Here the wall points are the points in the wall center lint points. If “Keep Grid Lines” option 1022 is selected, the invention will keep the existing grid lines. If “Overwrite Grid Lines” option 1023 is selected, the invention will overwrite the existing grid lines.

Add Grid Lines at column, wall and slab points: The user can click “Apply” button 1024 to add grid lines at column, wall and slab points. A X grid line 1003B and Y grid line 1006B at columns can be seen in FIG. 10B. If “Keep Grid Lines” option 1025 is selected, the FSDT will keep the existing grid lines. If “Overwrite Grid Lines” option 1026 is selected, the invention will overwrite the existing grid lines.

The user can click the “Export to Excel” button 1027 to export all grid lines information to an excel file. After modifying the grid lines parameter values in the excel file, click the “Import from Excel” button 1028 to import grid lines from Excel. The grid lines information will be updated automatically.

In some embodiments, at 208, the method may include drawing and modifying the columns automatically.

The implementation process of drawing and modifying the columns automatically is described below with reference to FIG. 11 and FIG. 10B. FIG. 11 is a control operation interface used to place command buttons and item parameters related to drawing and modifying columns automatically, according to some embodiments of the present disclosure.

The columns in the structural model of the invention can be obtained from architectural drawings or other drawings and can also be added to the plan by the user. The user can change the column sizes, move and delete columns easily, and find and delete duplicate columns automatically.

Add columns Method 1: Select the “Add Col on Screen” checkbox 1103, input or check the column size B, D and angle in column size table 1104, click the mouse anywhere in the graphic display area 1001, a column 1105 is added at the clicked position.

Add columns Method 2: Click “Add A Column” button 1106, select “Rectangle”, “Circle” or “W Shape” option 1107, input or check the size and angle of the column in column size table 1104, input or check the column center in Column Point Table 1108, click “Apply (Center and B,D)” button 1109, a column 1110 is added in FIG. 10B based on column center, width B and height D.

Add columns Method 3: Click “Add A Column” button 1106, select “Rectangle” option 1111, input column points in Column Point Table 1108, click “Apply(Points)” button 1112, a column 1113 is added on plan based on the coordinates of column points.

Modify column method 1: Click “Select” checkbox 1114 in FIG. 10B, select a column 1115 in FIG. 10B. If click “Multi-Sel” checkbox 1116, can select more columns 1117, then select “Rectangle”, “Circle” or “W Shape” option 1107, the selected columns 1115, 1117 are changed immediately. Or retype one of Col. B, D and Angle in column size table 1104, or Center X, Y in Column Point Table 1108, as required and then press Enter key in keyboard, or click “Apply(Center and B,D)” button 1109, the selected columns 1115, 1117 are modified immediately.

Modify column method 2: It is for rectangle column. Click “Select” checkbox 1114 in FIG. 10B, then select a column 1115 in FIG. 10B, if click “Multi-Sel” checkbox 1116, can select more columns 1117, change the column point X, Y values in Column Point Table 1108, click “Apply(Points)” button 1112, the selected columns 1115, 1117 are modified immediately.

Assign column properties on Screen: Select “Rectangle”, “Circle” or “W Shape” 1107, input or check column B, D and Angle in column size table 1104 as required, click “Assign ColSize” checkbox 1118, then click a column on screen in floor plan 1001 to assign column properties, can assign more columns with click one by one.

Move a column: Click “Select” checkbox 1114, select a column 1115, retype column center X or Y in Column Point Table 1108 and then press Enter key in keyboard, or click “Apply(Center and B,D)” button 1109, the selected column is moved.

Click “Show Col Above” checkbox 1119 or “Show Col Below” checkbox 1120, the invention will show columns and walls above or below on the plan, then the user can compare the columns for two floors, to see if a column is continuous to go or stop at certain floor, or to see the columns are aligned or not for two floors. A pick-up column can be found easily in this way.

The column numbers can be numbered according to certain rules automatically. Assign column numbers with “XY coordinate” automatically: Select the “XY coordinate” option 1121 in the “New Col. No.” frame 1122 to select this sorting rule, then select the “XLeft” checkbox 1123. The new column numbers calculated by invention with the new sorting rule will be displayed in the “New No.” column 1124 of “Column Number” table 1125. The “XLeft” option 1123 means that the column numbers will start from the plan left, then start from the plan bottom. Click “Apply” button 1126 in the “New Col. No.” frame 1122, the new column numbers will be assigned to columns 1001 in current floor. Click “ReOrder” button 1127 in the “New Col. No.” frame 1122, the column order in current floor will be re-ordered based on new column numbers.

The above column number assign is for the initial floor column numbers. When assigning column numbers on other floors automatically, this floor with already assigned column numbers will be referenced to ensure that columns at the same location on all floors use the same column numbers. If a column on a certain floor no longer goes up, then this column number does not have a column on that floor, this number is skipped. If a column starts from a certain floor and goes up, the column number will increase by one number automatically. The user can also specify this new added number manually. The number 1130 next to Floor Drop-Down Menu 1129 in the “New Col. No.” frame 1122 is this special manual column number. The user can enter the specified number 1130 here.

The above processes are used for automatically assigning column numbers one floor by one floor. Click the “AutoAllFLColN” button 1131 in the “New Col. No.” frame 1122, the user can assign column numbers for all floors with this one click, based on “XY coordinate” 1121 sorting rule, started from the specified floor shown in the Floor Drop-Down Menu 1129 in the “New Col. No.” frame 1122, and then goes up from the bottom floor to roof. If the conditions of the columns on each floor are different, the newly added columns will automatically be assigned with new column numbers.

Use columns below: In architectural drawings, a column shown on plan usually means this is a column above this floor plan. In Etabs and Safe models, a column shown on plan usually means this is a column below this floor plan. In the invention, the columns shown are same as in Etabs and Safe models. After importing the columns from architectural drawing, the user can click “Use Col Below” button 1132 to replace all columns at current floor with the columns below current floor. The user needs to do it for all floors, starting from roof. The user can click “AllFL Col Below” button 1133 to use the columns below for all floors. The invention will do it automatically, starting from the roof.

The user can click “Find Duplicate Col” button 1134 to find duplicate columns on plan. Duplicate column means two or more columns are very close, their distance is less than a specified value 1135. Click “Delete Duplicate Col.” Button 1136, the invention will delete all duplicate columns, that is keep one for all two or more duplicate columns.

Match all column centers for a floor: Click “Match All Col Cents to” button 1137, all columns will be moved as required on current floor, so that all column centers will be at same locations as the column centers (with same column number) at the floor determined by the Floor Drop-Down Menu 1138.

Match all column sizes for a floor: Click “Match All Col Sizes to” button 1139, all column sizes on current floor will be modified so that the all column sizes will be same as the column sizes (with same column number) at the floor determined by the Floor Drop-Down Menu 1138.

Column sizes from column schedule: Click “Col Size from Col Sche” button 1140, the invention can transfer the column sizes from column schedule (Excel file) into to FSDT model.

In some embodiments, at 210, the method may include drawing and modifying the walls automatically.

The implementation process of drawing and modifying the walls automatically is described below with the reference to FIG. 12 and FIG. 10B. FIG. 12 is a control operation interface used to place command buttons and item parameters related to draw and modify walls automatically, according to some embodiments of the present disclosure.

The walls in the structural model of the invention can be obtained from architectural drawings or other drawings, and can also be added on the plan by the user. The user can change the wall size, move walls and delete walls easily and automatically.

Add a wall method 1: Click “Add A Wall” button 1201, input X and Y coordinates of all the wall points in Wall Point Table 1202, confirm “Corner Point” option 1203 is selected, click “Apply” button 1204, a wall 1205 with predetermined wall point coordinates 1202 is added in FIG. 10B.

Add a wall method 2: Click “Add A Wall” button 1201, input the wall center line data in Wall Line Table 1206, including X and Y coordinates and wall thickness T, confirm “Line” option 1207 is selected, click “Apply” button 1208, a wall 1205 with predetermined center line data and wall thickness T in Wall Line Table 1206 is added in FIG. 10B.

Combine lines to walls: When importing walls from architectural drawings, sometimes the walls are made of some lines which are not connected together. In this situation, the user can click “Comb L to Wall” button 1209 to connect these lines to form real walls automatically.

Change the wall points order direction: The invention calculates the wall thickness from its point X, Y coordinates. If the first point number is not correct, then the wall cent line and wall thickness are not correct. Click the “Change Dir” button 1210 will change the first number location, then the selected wall cent lines and wall thicknesses may be correct. Continue to click “Change Dir” button 1210, the user will get the correct wall cent lines and wall thicknesses. Select “Line” option 1207, the user can see the wall center lines on plan.

Use walls below: In architectural drawings, a wall shown on plan usually means this is a wall above this floor plan. In Etabs and Safe models, a wall shown on plan usually means this is a wall below this floor plan. In the invention, it is same as in Etabs and Safe models. After importing the walls from architectural drawing, the user can click “Use Wall Below” button 1211 to replace all walls at current floor with the walls below current floor. The user needs to do it starting from the roof. The user can click “AllFL Wall Below” button 1212 to use the walls below for all floors, the invention will do it automatically, starting from the roof.

Assign Wall Thickness 1: Wall Thickness Table 1213 includes “From”, “To”, “Additional” and “T (in)”. The user can type the wall numbers and wall thickness T, then click “Apply” button 1214, the wall thickness will be assigned to the selected walls. Click “Show Wall T” checkbox 1215, the wall thicknesses will be shown on plan.

Assign Wall Thickness 2: If select a wall on plan, the selected wall number will fill the “From” and “To” values 1213. Input the new wall thickness T 1213, then press Enter key, or click “Apply” button 1214, the new wall thickness will be assigned to selected wall on plan. The user can change the “From”, “To” and “Additional” numbers 1213 to assign different walls at this time.

Assign Wall Thickness 3: Click “Assign T” checkbox 1216 to make it checked, check or input new wall thickness 1213, then the user can assign the wall thickness on screen with click one wall by one wall.

Wall Update: In Etabs model, the user may need to cut a complicated continuous shear wall into several part-walls, to get correct bar reinforcement, but the shear walls in structural drawings are usually shown in continuous. In the prevention, the user can click “Wall Update” button 1217, then the invention will cut the shear wall into some part-walls, as well as correct walls automatically if some walls are made not correctly.

Divide walls: Click “Divide Wall” button 1218 to divide/cut the selected walls into several part-walls. If DL 1219 is greater than 0, then the selected walls will be divided by length DL 1219. If DL 1219 is less than or equal to 0, and “N” 1220 is greater than 0, then the selected walls will be divided by number “N” 1220.

Combine walls: Click “Comb. Wall” checkbox 1221, select some walls on plan which are next each other, then click “Apply” button 1222, the selected walls are combined into one.

Wall Cross: Sometimes, the end of one wall (Wall1) is at the middle of another wall (Wall2). In Etabs model, it will be much better if cut wall 2 at middle into two walls, then three walls can be connected at their three ends. Click “Wall Cross” checkbox 1223, select two walls, and then click “Apply” button 1222 to achieve this purpose.

Closed wall means a shear wall which is closed without door or window open. The concrete wall for elevator pit usually has no door open, so it is usually a closed wall. The user can combine some part-walls into closed wall (CWall). Click “To CWall” checkbox 1224, click some part-walls required for CWall to select them, click “Apply” button 1225, the selected part-walls are combined into CWall. If there are some walls inside of CWall, the user needs to combine inside part-wall into CWall one by one after getting CWall.

In some embodiments, at 212, the method may include drawing and modifying the beams automatically.

The implementation process of drawing and modifying the beams automatically is described below with reference to FIG. 13A and FIG. 13B. FIG. 13A is a control operation interface used to place command buttons and item parameters related to draw and modify beams automatically, according to some embodiments of the present disclosure. FIG. 1313 is the main view interface of FSDT program, the lower display area of FIG. 13B is the graphic display area showing columns, walls, beams, and slabs 1301, according to some embodiments of the present disclosure.

There are two kinds of beams, edge beam and interior beam in the invention. Edge beams are used mainly for the line loads of exterior walls around the perimeter of building, which are usually added by FSDT program automatically. Interior beams are the real beams, can be imported from AutoCAD drawings, or added by FSDT program. Some interior beams are special for line loads too.

Click “SlabTag” button 1302 in Manu bar in FIG. 13B, the user will see the Sub-Slab numbers 1303 on plan. The Non-Roof-Sub-Slab 1304 is the slab that is not the roof, but there is slab or roof above. The invention can add edge beams 1305 around the perimeters of slabs which are composed of all Non-Roof-Sub-Slabs 1304 and add edge beams 1306 on parapets 1306 automatically.

Interior load beam: When there is set-back for a building in a floor, then there are some building perimeters 1307 above this floor which are different from the building perimeters below this floor. The invention can add some load beams on these different perimeters 1307. These beams are interior beams, but are load beams, not real beams, called interior load beam.

The user can add line load beams automatically, including edge beams and interior load beams. Input Non-Roof Sub-Slab numbers 1303 in the textbox 1308, input DL(Dead load), LL(Live load), Par(Parapet load) in Edge Beam Assign Data Table 1309, input DL in Interior Beam Assign Data Table 1310 for the interior load beams 1311 in FIG. 13B. Click “Apply” button 1312, the line load edge beams 1305 for Non-Roof Sub-Slab, the line load edge beams 1306 for parapet and the interior load beams 1311 are added automatically. The numbers 1305, 1306, 1311 as shown for load beams are the line load values. The added load beams will use the beam size shown in Edge Beam Assign Data Table 1313.

Change edge beam mark, size and line load: Click “SelectBm” checkbox 1314 in FIG. 13A, click “Multi-Sel” checkbox 1315 on FIG. 13B can select more edge beams. Select edge beams on plan by clicking the beams 1316, 1317, retype edge beam Mark, Width, Depth, DL and LL in Selected Edge Beam Data Table 1313, the edge beam mark, size and loads of selected beams are changed automatically.

Assign edge beam line loads on screen: Click “ScrAssign” checkbox 1318, select the option DL or LL 1319, check DL or LL value in Edge Beam Assign Data Table 1313 is right, click an edge beam 1305, 1306 on plan, the deal load or live load are changed immediately. Can window select the edge beams to assign more edge beam line loads.

Add interior beam: Click “Add Bm” checkbox 1320, input interior beam data in Interior Beam Assign Data Table 1310. If select an existing beam on plan, the beam size and loads will fill the Interior Beam Assign Data Table 1310. Click two points on plan, an interior beam 1321 is added.

Click “Show Cols Above” button 1322, the columns and walls above the current floor will be shown on plan, then the user can add a beam for pick-up column or wall easily.

Change interior beam mark, size and loads: Click “SelectBm” checkbox 1314, click “Multi-Sel” checkbox 1315 on FIG. 13B, then can select more interior beams, select interior beams 1321, 1323 on plan, retype interior beam Mark, Width, Depth, DL and LL in Interior Beam Assign Data Table 1310, the interior beam mark, size and loads of selected interior beams are changed automatically.

Assign interior beam mark, size and loads on screen: Click “ScrAssign” checkbox 1324, check beam mark, size and loads in Interior Beam Assign Data Table 1310, click an interior beam on plan 1321, 1323, the beam mark, size and loads will be assigned. Can window select the interior beams to assign more interior beams. The user can select an existing beam, then the beam size and load will fill the Interior Beam Assign Data Table 1310.

Change interior beam Mark, Size and Loads in Interior Beam Table 1325: Retype interior beam Mark, Width, Depth, DL and LL in Interior Beam Table 1325, the interior beam Mark, Width, Depth, DL and LL will be changed automatically.

Assign beam loads on screen: Check the values of DL and LL in the Interior Beam Assign Data Table 1310, select option DL or LL 1319, click “DL/LL ScrAssign” checkbox 1326, click the beam 1321, 1323 on plan to assign the DL or LL automatically. Can check the “ShowBmLoads(k/ft)” checkbox 1327 to show the beam load DL or LL.

Add line loads for part above walls or all above walls of specified floor: Check beam mark, size and loads in Interior Beam Assign Data Table 1310 are right, select a floor as above floor in Floor Drop-Down Menu 1328, input part wall numbers in “Part Wall N” textbox 1329, click “Part Wall N” button 1330 in “AddLineLoadBm” frame 1331, the line loads for part above walls will be added. Can click “AboveAllWalls” button 1332 to add Line Loads for all Above Walls.

Click “AssignLoadfromAboveWallF” button 1333, the invention will assign the beam line loads based on above wall force of specified floor.

Extend Beam: The step details are: Click “SelectBm” checkbox 1314, select an interior beam 1334 on plan that needs to extend. Click “Extend Bm” button 1335 to extend the beam 1334. If the beam 1334 does not touch the beam 1336, then the beam 1334 will extend to beam 1336. If the extended point of beam 1334 is already at beam 1336, it will extend to the next beam, but the extended part is changed to a new beam 1337. The extension point of the beam depends on the selected point when clicking a beam to select. The endpoint of the beam, which is closer to the select point, is the extended point.

Cut Bm: Click “Cut Bm” button 1338 to cut all the interior beams as required. If two beams cross over, they will not connect at cross point. After clicking the “Cut Bm” button 1338, these two beams will be cut at the cross point, then two beams become four beams, and four beams are connected together at the cross point.

In some embodiments, at 214, the method may include drawing and modifying the slabs automatically.

The implementation process of drawing and modifying the slabs automatically is described below with reference to FIG. 14 and FIG. 13B. FIG. 14 is a control operation interface used to place command buttons and item parameters related to draw and modify slabs automatically, according to some embodiments of the present disclosure.

Slabs are usually obtained from AutoCAD drawings, but the user can add the slabs in FSDT program. Whole one floor concrete slab is called Slab0 1401. Based on the different thickness or different loads, the whole one floor slab can be separated into some slabs, called Sub-Slab. Slab open is also considered as Sub-Slab. Slab properties include slab coordinates, thickness, dead load DL, live load LL and slab type. Slab type includes “Etabs”, “Safe”, “Both”, “Etabs Open”, “Safe Open”, “Both Open” and “None”. “Both” means for both Etabs and Safe, “None” means the slab is in not imported into Etabs or Safe program. Slab0 always is “None”, can not be changed.

The invention can get slab0 1401 automatically. If there is no slab0 1401, or slab0 1401 is not correct, then the user can click “Get Slab0” button 1402 to get new slab0 1401.

Select slab: Input a slab number at “Slab No.” textbox 1403, press Enter, the specified slab will be selected, or click “Slab No.” scroll bar 1404 up or down to select a slab, or click “Select Sub-Slab” checkbox 1405, then select a slab 1406 on plan by click it. If click “Multi-Sel” checkbox 1315 on FIG. 13B, then can select more slabs.

Slab Property Assign: Select one or more slabs, click Slab Type Drop-Down Menu 1407 to assign slab type, like Etabs, SafeOpen and others, or retype slab T. DL, LL in Slab Property Table 1408 as required to assign new slab properties.

Slab Property Assign on screen: Click “Slab Assign” checkbox 1409, click Slab Type Drop-Down Menu 1407 to select slab type, like Etabs, SafeOpen and others, retype the T, DL, LL in Slab Property Table 1408 as required for assigning slab properties, then click slab 1406 on plan one by one to assign the slab properties.

Slab Property Assign on screen with existing slab properties: click “Select Sub-Slab” checkbox 1405, select a slab 1406 on FIG. 13B, the slab properties of selected slab will be shown on Slab Property Table 1408, change some items as required. Click “Slab Assign” checkbox 1409, click slab on plan one by one to assign the slab properties.

Move Slab: Click Move Slab checkbox 1410, select an open 1411 or slab 1406 on floor plan, if click “Multi-Sel” checkbox 1315 on FIG. 13B, can select more opens and slabs, use Left/Right Scroll Bar 1412 and Up/Dow Scroll Bar 1413 to move selected opens or slabs.

Move Slab Points: click “Move SlabPts” checkbox 1414, select some points on slab in floor plan, can use window method to select slab points. Use Left/Right Scroll Bar 1412 and Up/Dow Scroll Bar 1413 to move slab points.

Slab tag location: Click “SlabTag Locate” button 1415 to locate the slab tag 1416 location automatically. To move the slab tag 1416, select one or more Sub-Slab, click Left/Right Scroll Bar 1412 to move slab tag left or right, click Up/Dow Scroll Bar 1413 to move slab tag up or down.

In some embodiments, at 216, the method may include drawing and modifying the drop panels automatically.

The implementation process of drawing and modifying the drop panels automatically is described below with the reference to FIG. 15A and FIG. 15B. FIG. 15A is a control operation interface used to place command buttons and item parameters related to draw and modify drop panels automatically, according to some embodiments of the present disclosure. FIG. 15B is the main view interface of FSDT program, the lower display area of FIG. 15B is the graphic display area showing columns, walls, and drop panels 1501, according to some embodiments of the present disclosure.

Add drop panel: Check the values of DX1, DX2, DY1, DY2 and angle 1502, change it as required, click “Add Drop Panel” checkbox 1503, click a column 1504 or a point on plan, a new drop panel 1505 is added with the data shown 1502. If there is a column near click point, the center of added drop panel will be on the center of the column. If the click point is near edge of slab 1506, or near slab open 1507, the added drop panel will be cut automatically.

Add all drops: Click “Add All Drops” button 1508, the invention will add drop panels on all columns 1505, 1506, 1507, 1509. If one column already has drop panel on it, the invention will not add drop panel again. If a column is near edge of slab 1506, or near slab open 1507, the added drop panel will be cut automatically.

DX1, DX2, DY1 and DY2 1502: DX1 is the drop panel dimension in the left of the column, DX2 is the drop panel dimension in the right of the column, DY1 is the drop panel dimension below column, DY2 is the drop panel dimension above column. The “Independent” checkbox 1510 is used to control the DX1, DX2, DY1 and DY2 change properties. If “Independent” checkbox 1510 is unchecked, then: (1) If change DX1, all other DX2, DY1 and DY2 will be same as DX1, (2) If change DX2, all other DX1, DY1 and DY2 will not change, (3) If change DY1, DY2 will be same as DY1, DX1 and DX2 will no change, (4) If change DY2, all other DX1, DX2 and DY1 will not change. If Independent checkbox 1510 is checked, then if change any one, all other three will not change.

Select drop panel: The user can input the drop number at drop panel number box 1511 and then press Enter key on the keyboard to select a drop panel, or click the scroll bar 1512 to select a drop panel. Or click the “Select” checkbox 1513 in FIG. 15B, then click drop panel 1505 on the screen to select it. If click “Multi-Sel” checkbox 1514, can select more drop panels. The selected drop panels will be shown in red color, and the drop panel properties will be shown in the user interface in FIG. 15A. Then the user can revise the drop panels.

When add a drop panel, drop panel Thickness 1515 is used. Select one or more drop panels, change “Thickness” 1515 value, the drop panel thicknesses of all selected drop panels will be changed automatically.

Assign drop panel DX1, DX2, DY1, DY2 1502 together on screen: Check the values of DX1, DX2, DY1, DY2 1502, change them as required, click “Scr AssignDrop” checkbox 1516 to check it, click drop panel on plan one by one 1505, 1509, DX1, DX2, DY1, DY2 1502 of drop panels will be assigned.

Assign drop panel DX1, DX2, DY1, DY2 1502 separately on screen: Check the values of DX1, DX2, DY1, DY2 1502, change them as required, click “Scr AssignDXDY” checkbox 1517 to check it, click a drop panel edge line 1518 on screen, DX1, DX2, DY1, DY2 1502 will be assigned separately. Can click one edge line by one edge line to assign more edge lines.

Move drop panel edge line: Click “Sel Line” checkbox 1519, select a drop panel edge line 1518 on plan, if click Multi-Sel checkbox 1514 in FIG. 15B, can select more edge lines, use Left/Right Scroll Bar and Up/Dow Scroll Bar 1520 to move selected edge lines 1518.

Adjust DX and DY on screen with column spacing: Check the value in text box 1521, change it as required, which means about ⅙ of column spacing, select a round off value in Round Off Drop-Down Menu 1522, click “Scr Adjust DXDY” checkbox 1523, then click two related columns in two drop panels 1524 on floor plan, DX or DY values of the drop panels 1524 related to these two columns will be changed.

Drop panel update: Usually the drop panels are automatically adjusted based on slab edges and opens when you add them or move them. If some drop panels 1525 are not automatically adjusted based on slab edge and opens, the user can click “Drop Panel Update” button 1526 to adjust drop panels based on slab edges and opens automatically.

In some embodiments, at 218, the method may include Inputting the wind load and seismic load.

The implementation process of inputting the wind load and seismic load is described below with the reference to FIG. 16 and FIG. 17. FIG. 16 is a control operation interface used to place command buttons and item parameters related to input the wind load, according to some embodiments of the present disclosure. FIG. 17 is a control operation interface used to place command buttons and item parameters related to input the seismic load, according to some embodiments of the present disclosure.

Input the wind load parameters and get wind loads: Select the ASCE code and year 1601, input wind speed V 1602, exposure 1603 and other data, click “Apply” button 1604 to get wind pressure 1605. Click “Get Story Data” button 1606 to get story data, click “Apply” button 1607 to get wind forces 1608 on building. The user gets wind forces and moments 1608 at each floor as well as total wind force and moment 1609 for whole building. Wind pressure P(psf) 1610 in the table can be changed, and then the user can update the wind forces by clicking “Apply2” button 1611. Wind forces and moments 1608, 1609 will not be imported into Etabs model. Only ASCE Code and year 1601, wind speed V 1602, exposure 1603 and some other data are imported into the Etabs model. Etabs itself will calculate the wind forces based on these input data.

Input the seismic load parameters and get seismic loads: Select the ASCE code and year 1701, input site class 1702, response modification coefficient R 1703, mapped MCE spectral response acceleration parameters Ss 1704 and S1 1705, and some other data, click “Apply” button 1706 to get seismic force 1707. Click “Get Story Data” button 1708 to get story data, click “Apply” button 1709 under “SelfWT Only” checkbox 1710 to get seismic force on building. The user gets seismic forces and moments 1711 at each floor as well as total seismic force and moment for whole building. Seismic force and moment will not be imported into the Etabs model. Only Code and year 1701, site class 1702, response modification coefficient R 1703, mapped MCE spectral response acceleration parameters Ss 1704 and S1 1705, and some other data are imported into Etabs model. Etabs itself will calculate the seismic force based on these input data.

In some embodiments, at 220, the method may include setting up Ready-to-Run Etabs and Safe Models.

The implementation process of Setting up Ready-to-Run Etabs and Safe models is described below with the reference to FIG. 18, FIG. 13B and FIG. 19. FIG. 18 is an interface used to place command buttons and item parameters related to export e2k file for Etabs model automatically, according to some embodiments of the present disclosure. FIG. 19 is an interface used to place command buttons and item parameters related to export f2k file for Safe model automatically, according to some embodiments of the present disclosure.

After finishing the treatment for all columns, beams, walls, slabs and other structural items, assigning all deal loads, live loads, wind load and seismic load, point loads, line loads and surface loads, concrete strength, making load combinations, FSDT program will setup Ready-to-Run Etabs model and Safe model automatically. The user can export e2k file for Etabs model and Safe f2k file for Safe model. The Etabs program can import the e2k file and run the model immediately. The Safe program can import the f2k file and run the model immediately.

In the invention, all concrete shear walls are automatically segmented according to the segment length requirements determined by the user. Furthermore, all wall segments are even can be aligned for all floors of the building, and are imported into Etabs program.

The invention can automatically add pier numbers for shear walls for Etabs program, and automatically make elevation views for all pier loacations. The invention can get wall reactions, wall reinforcement form Etabs, get slab reinforcement from Safe.

The step details to export Etabs e2k file:
Step 1: Click “Beam” 1801 at Manu bar in FIG. 13B to show beams if the beams are not show. Click “BmLoad” 1802 at Manu bar to show beam loads if the beam loads are not show. Check all information to make sure that all beams and beam loads are correct.
Step 2: Click “Sub-Slab” 1803 at Manu bar in FIG. 13B to show sub-slab if the sub-slabs are not show. Click “SlabTag” 1302 at Manu bar to show slab properties and loads if they are not show. Check all information to make sure that all slab thickness, slab loads and opens are correct.
Step 3: Check all floors by click the up/down scroll bar 1804.
Step 4: If everything is OK, then Goto File 1805->Export->ETABS—e2k file to Export Etabs e2k file.
Step 5: In the user interface “Export Etabs—e2k” in FIG. 18, select “P-Delta” 1806 method, “Live Load Reduction” 1807, “Mass Source” 1808, “Etabs Version” 1809 and other information, click “Continue” button 1810 to continue.
Step 6: In the pop-out interface, select the file location for Etabs e2k, or input the file name. Click OK to export e2k file.
Step 7: Use Etabs program to import e2k file and run the model.

The step details to export Safe f2k File:
Step 1: Check all beams, beam loads, slab and slab loads are shown, same as shown above to Export Etabs e2k File, and check them to make sure they are all correct.
Step 2: If everything is OK, then go to File 1805->Export->SAFE—f2k file to Export Safe f2k file.
Step 4: In the user interface “Export Safe—f2k” in FIG. 19, check the “Concrete Cover” 1901 and “Strip Width” 1902, change them as required. Click “Point Loads” checkbox 1903 to check it if point loads apply.
Step 5: Select “Floor Slab” option 1904 or “Mat Foundation” option 1905. “Floor Slab” 1904 is the model in which all columns and walls support slab. “Mat Foundation” 1905 is the model in which soil support the slab, and all columns and walls above will be the loads. If it is “Mat Foundation” 1905, the user needs to input “Soil Stiffness” 1906.
Step 6: Select option “Ver.12” or “Ver 16 and Higher” 1907.
Step 7: Check all data and then click “Continue” button 1908 to continue.
Step 8: In the pop-out interface, select the file location for Safe f2k file, or input the file name. Click OK to export f2k file.
Step 9: Use Safe program to import f2k file and run the model.

FIG. 3 is a flowchart illustrating a method of designing and checking concrete columns one by one with FSDT program automatically and drawing column schedule with AUD program automatically, according to some embodiments of the present disclosure.

In some embodiments, at 302, the method may include getting column forces from Etabs model automatically with FSDT program.

The implementation process of getting column forces from Etabs model automatically with FSDT program is described below with the reference to FIG. 11 which is a control operation interface used to place command buttons and item parameters related to draw and modify columns automatically, according to some embodiments of the present disclosure.

Get column forces from Etabs: In Etabs program, export the column forces for all columns with a text file. Click “Get Etabs-Col F” button 1141 in FIG. 11. The user interface “Open Etabs Result File . . . ” will pop out, select the column force text file in the interface, click “OK” button to import Etabs column forces. The column forces will be shown on plan immediately. Then go to other floors, and click “Get Etabs-Col F” button 1141 again, this time the column forces will be shown on plan immediately, not required to select the column force text file.

In some embodiments, at 304, the method may include getting column forces from Safe model automatically with FSDT program.

The implementation process of getting column forces from Safe model automatically with FSDT program is described below with the reference to FIG. 11 which is a control operation interface used to place command buttons and item parameters related to draw and modify columns automatically, according to some embodiments of the present disclosure.

Get column forces from Safe: In Safe program, export the column reactions for all columns with a text file. Click “Get Safe-Col R” button 1142 in FIG. 11. The user interface “Open Safe Result File . . . ” will pop out, select the column reaction text file in interface, click “OK” button to import Safe column forces. The column forces will be shown on plan immediately. Then go to other floors, get the column forces with the same way.

In some embodiments, at 306, the method may include designing and checking conrete columns one by one automatically with FSDT program.

The implementation process of designing and checking conrete columns one by one automatically with FSDT program is described below with the reference to FIG. 20 which is a control operation interface used to place command buttons and item parameters related to designing and checking conrete columns one by one automatically, according to some embodiments of the present disclosure.

In the control operation interface FIG. 20, there are big table Column Design and Check Table 2001, including “Basic FL” 2002, floors basically required with the column size change and concrete fc′ change, “Floor” 2003, the column design floor, “fc′(psi)” 2004, concrete strength, “Height (ft)” 2005, the floor height, “ColL (ft)” 2006, the column design length determined by the floor height, “Po (k)” 2007, the column force, . . . and others.

In the control operation interface in FIG. 20, the user can get column sizes, column lengths, and column forces for all columns, all floors of whole building from finished FSDT model. The data will be filled in the Column Design and Check Table 2001 automatically. The user can input concrete strength and other column design information, then design and check the columns one by one with slenderness considered automatically. The user can change the column size, rebar size, column length, concrete strength, some other parameters, and see the design results immediately. Can check the columns one by one, or check all columns together. When check a column, the results will be shown in the table and shown in Column Capacity Graph 2008 immediately.

Get basic floors for column design and check: Check story data in the user interface “Story Data” in FIG. 7, input column size change floors in “Column Size Change” table 2009 in FIG. 20, input concrete fc′ change floors in “Concrete fc′” table 2010, click “Get BasicFL” button 2011, the user gets the basic floors 2002 which are based on the column size change floors 2009 and concrete fc′ change floors 2010. These basic floors will be shown in the Column Design and Check Table 2001 at column “Basic FL” 2002.

Click “FL Apply” button 2012, the user will get the real design and check floors, same as Basic FL 2002 and shown at column “Floor” 2003. At the meantime, the user will get “fc′” 2004 and “Height” 2005 for real design and check floors. The user then can click “Insert Line” button 2013 to insert a real design and check floor, or click “Delete Line” button 2014 to delete a real design and check floor as required.

Get LPBH: LPBH includes floor height, column length L, column force P, column size B and H, click “Get LPBH” button 2015 to get the floor heights, column design lengths, the column forces, and the column size width B and depth H for current column of current FSDT model. It will also get the results for current column.

Get All LPBH: Click “Get All LPBH” button 2016 to get the floor heights and column design lengths, the column forces, and the column size width B and depth H for all columns of current model. It will also get the results for all columns.

Get Results: Click “Get Results” 2017 button to check the current column and get the initial results for column reinforcement. Click “Get All Results” button 2018 to check all columns and get the initial results for all columns.

If there is a project, each column sizes for all floors are same, that is no column size change for different floors, then it can be just one floor group. If each column has two sizes, above small and below big, then it can be two floor groups. The FSDT program can make column size floor groups automatically based on column size change information shown in “Column Size Change” table 2009. A project may have one floor group, two floor groups, or more.

Column size auto follow: The column sizes within a same floor group will keep the same size. Based on the column size change information 2009, all floors can be separated into several groups. If “Auto Follow” checkbox 2019 is not checked, then when the user changes column sizes in one floor, the column sizes within same group will change automatically, but the column sizes in other groups will not change. If “Auto Follow” checkbox 2019 is checked, then when the user changes column sizes in one floor, not only the column sizes within same group will change automatically, but also the column sizes in other groups will change if the floor is higher than the floor in which the user changed the column sizes.

Rebar size auto follow: If Auto Follow checkbox 2019 is not checked, then when the user changes rebar sizes in one floor, the rebar sizes in other floors will not change. If Auto Follow checkbox 2019 is checked, then when the user changes rebar sizes in one floor, the rebar sizes in other floors will change if the floor is higher than the floor in which the user changed the rebar sizes.

Design and check conrete column one by one automatically: Above column automatic design just get the initial results, then the user can design and check the column in detail one by one by using Column Design and Check Table 2001. The user can change the column size and rebar sizes for a column at any floor. The column capacity results without slenderness considered will be updated immediately. If the user presses Enter key in keyboard after the data change, the invention will give out column capacity results “FPn” 2020 with slenderness considered, as well as Column Capacity Graph 2008 immediately.

If click “Pu/FPn” 2020 at any floor in Column Design and Check Table 2001, the invention will also check the current column capacity with slenderness considered at that floor, and show the results in table 2001 and Column Capacity Graph 2008 immediately.

When check the column capacity with slenderness considered at one floor, the user can select the column capacity along axis X or Y, by click option Px or Py 2021.

Click “Export to Excel” button 2022, all data required for the Column Schedule will be exported to an Excel file. Then the user can make Column Schedule based on this Excel file with AUD program of the invention.

Keep the previous column design data: Sometimes, the column layout changed, so the column number changed. When start the column design and check again, the users hope some columns can keep their previous design data, such as column size, rebar and capacity, because these columns are kept at the same area and the column layout in fact is not changed, only the column numbers are changed. To keep the previous column design data, the step details are:
Step 1: Before change the column layout, open the previous FSDT file, go to this user interface “Column Design and Check” as shown in FIG. 20, click “Save” button 2023 to save the previous column design data.
Step 2: Change the column layout, save as the fsd file as new file name, then finish the new column layout with new column numbers, and then save the file again.
Step 3: Go to this user interface “Column Design and Check”, click “LoadColSize” button 2024 to load the saved previous column sizes and rebar data only. Or click “Load” button 2025 to load the saved previous all column design data, including column sizes, rebars, column length, column force, and floor information.
Step 5: Click “EXColData” checkbox 2026 (To keep the existing column size, rebar and capacity).
Step 6: Click “Get Col N” button 2027 to get the previous column design data into new column design.

Single column design and check: Column Data Table 2028, column section 2029 with rebars on it and Column Capacity Graph 2008 can be used for a single column capacity design and check, whatever the column is related to or not related to current project. Input or change the data in Column Data Table 2028, press Enter key in keyboard or click “Apply” button 2030, the invention will give out column capacity results “FPn” 2031 and Column Capacity Graph 2008.

In some embodiments, at 308, the method may include making AutoCAD Column Schedule automatically with AUD program.

The implementation process of making AutoCAD Column Schedule automatically with AUD program is described below with the reference to FIG. 21A, FIG. 21B and FIG. 21C. FIG. 21A is a control operation interface used to place command buttons and item parameters related to making AutoCAD Column Schedule with AUD automatically, according to some embodiments of the present disclosure, FIG. 21B is the “FLElev” sheet in Column Excel File and FIG. 21C is the “AllFL” sheet in Column Excel File, according to some embodiments of the present disclosure.

Click “Browse” button 2101, locate the “Column Excel File” to get all data required for the column schedule. Click “Browse” button 2102, locate the “Col Schedule CAD Dxf File” in the computer. Click “Apply” button 2103, the user will get column schedule in AutoCAD drawing automatically.

Floor Name Table: The Floor Name Table 2104 includes “Floor Name” 2105 used in FSDT and AUD programs and the floor “Name in Column Schedule” 2106. When read the “Column Excel File”, the invention will get the floor names used in FSDT and AUD programs and fill the Floor Name Table 2104. The user can click “Same Name” button 2107 to let the floor “Name in Column Schedule” 2106 same as the “Floor Name” used in FSDT and AUD programs. The user can change the floor “Name used in Column Schedule” 2106 as required.

The step details to make Column Schedule are:
Step 1: Finish the “Column Excel File” with FSDT program or manually. In this Excel file, there should be two sheets “FLElev” (shown in FIG. 21B) and “AllFL” (shown in FIG. 21C). The sheet names should be exactly same as these.
Step 2: In the user interface “Column Schedule” in FIG. 21A, click “Browse” button 2101 to select “Column Excel File” in computer. Click “Browse” button 2102 to select “Col Schedule CAD Dxf File” in computer.
Step 3: Click “Apply” button 2103 to get Column Schedule in AutoCAD. Click “Open” button 2108 to open Column Schedule in AutoCAD.

The parameters that control the Column Schedule include the height of the row which contains column numbers, the height of the row which contains column loads, the height of the bottom row which is under “Floor” row to separate the floors from column loads and column numbers below, the height of the row (Floor row) which contains column size and rebar size, the height of the top row which is above “Floor” row to separate the floors from the column numbers and Column Schedule title above, the height of the row which contains Column Schedule title. And include the width of column which contains floor data, the width of column which contains concrete strength fc′, the width of column which contains column size and rebar size.

The user can change all these data by retype their value except floor height which is determined by real floor height imported in Column Schedule data from the Column Excel File.

Column Schedule Width and Height Dimensions: The user can see the Column Schedule Width and Height Dimensions 2109 (Like Col N Height ColNH (ft) . . . ) in the middle of the interface “Column Schedule” in FIG. 21A. Column Schedule Sample in AUD manual shows the means of these dimensions 2109 clearly. All these parameters 2109 can be changed here to meet the user's requirement.

Click “Save” button 2110, all Width and Height Dimensions 2109 for Column Schedule will be saved as a txt file for the next time use. Click “Import” button 2111 to import these parameters when needs to use again,

Sheet “FLElev” in Column Excel File: Sheet “FLElev” 2112 in FIG. 21B has 5 excel columns that are Order 2113, “Floor” 2114, “Height” 2115, “fc′” 2116 and “FL Name in Model” 2117. “Floor” 2114 column is for each level floor name of the building. The floor names for each level in the AutoCAD drawing of Column Schedule will be exact same as one the user inputs here. “Height” 2115 column is the height of each floor below. If basement is the bottom level of the building, then the height is zero. If there is cellar lower than basement, than basement height is not zero, cellar is the bottom level of the building with zero height. All floor “Height” 2115 should be in ft-inch type. The bottom level has two numbers, that is floor “Height” 2115 and decimal elevation(ft) 2118. “fc′” 2116 column is the concrete strength of the column. If the concrete strength is not required to shown in Column Schedule, just leave it empty. “FL Name in Model” 2117 column is the floor name in model which is required if the user wants the column size orientation to be automatically determined based on the structural model.

Sheet “AllFL” in Column Excel File: Sheet “AllFL” 2119 in FIG. 21C has “Col N” 2120 and “Col Load” Columns 2121 first, these two Excel columns are used to put the column loads in Column Schedule. And then has 4 excel columns for each floor, that is “Col N” 2122, column section width “B” 2123, column section height “H” 2124, and reinforcement “Rebar” 2125. These 4 excel columns are for concrete column data of one floor, but only typical floor column data are required to put here. If the conditions of all columns for some continuous floors are all the same, then just put column data of lowest floor (called typical floor) here, the invention will fill the Column Schedule for other floors with the column data same as this typical floor. Separate the Column Schedule: If the Column Schedule is too long, the user can separate the column schedule into Column Schedule 1 and Column Schedule 2. After get Column Schedule shown above, close Column Schedule file in AutoCAD, change the “To” number 2126 (Shown in Red) as required, the new number 2126 is the last column number of Column Schedule 1, click “ReApply” button 2127 to get two new Column Schedules. The column scheduler can be separated into three or more column schedules with similar way.

Top Foundation Floor: A building project, may have one or more foundation floors in which there are pile caps or footings. “Top Foundation FL” 2128 is the floor with highest elevation in these floors. The user can input the “Top Foundation FL” by click the Floor Drop-Down Manu 2128. In each foundation floor, if there is a column that starts at this floor, then there will be a heavy line shown in Column Schedule which indicates the bottom of column.

FIG. 4 is a flowchart illustrating a method of drawing and modifying the structural drawings with AUD programs automatically, according to some embodiments of the present disclosure.

In some embodiments, at 402, the method may include obtaining structural drawing information from FSDT program and architectural drawings automatically.

The implementation process of obtaining structural drawing information from FSDT program and architectural drawings automatically is described below with the reference to FIG. 22A and FIG. 22B. FIG. 22A is the first one of two interfaces used to place command buttons and item parameters related to obtain structural drawing information from architectural drawings into FSDT or AUD programs automatically, according to some embodiments of the present disclosure. FIG. 22B is the second one of two interfaces used to place command buttons and item parameters related to obtain structural drawing information from architectural drawings into FSDT or AUD programs automatically, the lower display area of FIG. 22B is the graphic display area 2201, according to some embodiments of the present disclosure.

FSDT and AUD programs not only obtain columns, walls, beams, slabs and other structural items from architectural drawings for FSDT model, Etabs and Safe models, but also obtain these items for structural drawings. Furthermore, FSDT and AUD can obtain some special items, which are not the structural model items and are not required to import into Etabs and Safe models, but will be shown in structural drawings. These items include CMU wall, stair, elevator and some others. At this situation, the invention will call all structural items and special items as architectural items. FSDT and AUD programs will export these architectural items, that is columns, walls, beams, slabs and other structural drawing information, and those CMU wall, stair, elevator and some others special items into AutoCAD, to be an Architectural Drawings as the part of structural drawings, and which are architectural background of structural drawings, so called Architectural Background Drawing (ABG).

AUD programs can read the FSDT file, so can also obtain columns, walls, beams, slabs and other structural items information from FSDT program.

FSDT and AUD programs have total 9 kinds of Architectural items, that is Col, Wall, Slab, Open, Stair, CMU, Arch1, Arch2 and Arch3 2202. The user can select some layers in architectural drawings and assign them into these 9 kinds of Architectural items 2202.

Add Architectural Drawing items into ABG Drawings: Select the “SelItem” checkbox 2203 in FIG. 22B, select any ABG item in the architectural drawing displayed in the graphic display area 2201. If click a column 2204, the edge of column will turn into a different color to indicate that the column is selected. Then click the column “add” button 2205 in “ABG” frame 2206, the column information with the same layer on all floors in the building will be added into ABG Drawings. If click the “Add” button 2207 corresponding to the column in FIG. 22A, it will have same effect. The same method is used to obtain wall and other ABG item information.

The user can also select the “SelLayer” checkbox 2208 in FIG. 22B, then click an ABG item on floor plan to select, all ABG items with same layer will be selected. Then add selected items into ABG Drawings with same way.

Click ABG item checkbox, like “Col” checkbox 2209, then click an item 2204 which belong to column in architectural drawing, all items which have same layer with clicked column 2204 are added into ABG Drawings.

After obtain all Architectural Background (ABG) Drawing information from architectural drawings, the FSDT and AUD programs will save all AutoCAD layer names for ABG drawings. Therefore, next time some items in architectural drawings are changed, like moved or dimension changed, just import the architectural drawings again, then the user can obtain ABG drawings from architectural drawings immediately, nothing else is required to do for it. In this way, the invention can obtain the ABG drawing items from architectural drawings automatically.

The Layer Names used for Architectural Background Drawing are saved in each fsd and aud file. FSDT and AUD programs consider these layer names and colors as ABG layer group, and the user can name it. One project can have several ABG layer groups. All layer group names are put in ABG Layer Drop-Down Menu 2210. The ABG layer Group in ABG Layer Drop-Down Menu 2210 can be added or removed easily. The user can select current ABG layer Group by click the Drop-Down Menu 2210. All new selected ABG layer names and colors will be set as current, and the layer colors in “Layer Colors for items in Arch Background” 2211 will be updated.

The saved all AutoCAD layer names for an ABG drawings are shown in some special tables, the user can change the layer names, delete and add the layer names directly, to let the user change and control the final ABG drawings easily. FSDT and AUD programs even can save the layer names for different projects and different situation. FSDT and AUD programs can give the special name for different situations.

All ABG items are shown in ABG column 2212 of Architectural Drawing Layer Table 2213. The user can change or delete the ABG item name in this table. To change the ABG item name, just retype the name in the cell and press Enter key. The related layer will be changed to new ABG Item. To delete a layer for ABG item, just delete ABG item name at this ABG column and then press Enter key. The user can see all ABG layer names for one ABG item in ABG Layer Drop-Down Menu 2214, if select an ABG item in ABG Item Drop-Down Menu 2215. The user can remove a layer in ABG Layer Drop-Down Menu 2214 by click Remove button 2216.

Click “Export to File” button 2217 to export Architectural Background Drawing as AutoCAD dwg file. The AutoCAD can open it and then take it as attached file of the structural drawings. If “Col Below” checkbox 2218 is checked, the columns and walls below for each floor will be exported when export ABG drawing. Click “Export to Dwg” button 2219 to export ABG into opened AutoCAD drawing.

In some embodiments, at 404, the method may include making Typical Pile Cap Details and adding pile caps on plan automatically.

The implementation process of making Typical Pile Cap Details and adding pile caps on plan automatically is described below with the reference to FIG. 23A and FIG. 23B. FIG. 23A is a control operation interface used to place command buttons and item parameters related to make Typical Pile Cap Details and add pile caps on plan automatically, according to some embodiments of the present disclosure. FIG. 23B is the main view interface of AUD program, the lower display area of FIG. 23B is the graphic display area showing columns, walls, and pile caps 2301, according to some embodiments of the present disclosure.

There are three kinds of pile caps in the invention: Regular pile cap 2302, that is normal pile cap PC1 to PC9; PC-A pile cap 2303, the pile cap that has piles with regular columns and rows; SP pile cap 2304, special pile cap with any pile number, and the piles can be at any location. The parameters of pile cap include pile number, pile diameter D 2305, pile space 2306, the edge of pile center to pile cap 2307, cap depth 2308 and pile type 2309 which can be Round or HP shape.

Regular pile cap 2302: Option PC1 to PC9 2310 are options for regular pile cap 2302. To assign a regular pile cap as current pile cap, just click it. The size “a=” and “b=” 2311 are pile cap dimensions in two directions, which are given out by AUD program, can not be changed.

Add a new regular Pile Cap Detail: The regular pile cap Drop-Down Menu 2312 includes all regular Pile Cap Details the user already may have. Select a pile cap in PC1 to PC9 2310, change the values for pile space 2306, edge 2307, pile D 2305 and pile type 2309 as required, click “Add” button 2313, a new regular Pile Cap Detail is added into regular pile cap Drop-Down Menu 2312, the name of new regular Pile Cap Detail is named by AUD program automatically. If there is more than one regular Pile Cap Details with the same number of piles, the second Pile Cap Detail will start to add a letter after the name to show the difference, like PC5A, and the next one will be PC5B.

PC-A pile cap 2303: PC-A pile figure area 2314 is shown on up-right of FIG. 23A. To assign a PC-A type pile cap as current pile cap, just click the PC-A option 2315.

Two textboxes 2316, 2317 above Scale (PC-A) 2318 are pile spaces for rows. The piles totally can have three rows, so provide two textboxes 2316, 2317. The first value 2316 indicates the pile space between first row and second row. The second value 2317 indicates the pile space between second row and third row. If the first value 2316 is 0, then the pile cap has one row. If the first value is greater than 0 and the second value is 0, then the pile cap has two rows. If the first value and second value are all greater than 0, then the pile cap has three rows.

The textboxes 2319 above value 1, 2, 3, 4 and 5 2320 are pile spaces for pile columns. These pile spaces can be different. If there are more than 4 pile spaces, the user can click the left-right Scroll Bar 2321 to move the pile space values 2319. The user can change any one of pile spaces 2319, and just press Enter to get new results.

In PC-A pile cap figure area, there are four numbers 2322, which are pile cap edges with in left, right, top and bottom respectively. The user can change them 2322 and press Enter to get the new result. Next to PC-A option is the PC-A pile cap Drop-Down Menu 2323. This PC-A pile cap Drop-Down Menu 2323 includes all PC-A Pile Cap Details the user may already have.

Add a new PC-A Pile Cap Detail: Change the values for pile space 2316, 2317, 2319, edge 2322, pile D 2305 and pile type 2309 as required, if press Enter after change, the user will see the PC-A pile cap diagram 2324 changed immediately, input the new PC-A pile cap name in PC-A Drop-Down Menu 2323, click “Add” button 2325, a new PC-A Pile Cap Detail is added in PC-A Drop-Down Menu 2323. The name of new PC-A Pile Cap Detail can be any, but it cannot be same as regular pile cap name.

SP pile cap: The user can use AutoCAD to draw the pile cap which includes piles and walls, then use AUD program to import it into AUD program. Wall can be used for pile cap base. Draw circle as pile in AutoCAD drawing, even the piles are HP type. After AUD program get it, they can be changed to round or HP easily. To make SP pile cap as current, just click the SP option 2326. Next to SP option 2326 is the SP pile cap Drop-Down Menu 2327. This SP pile cap Drop-Down Menu 2327 includes all SP Pile Cap Details the user may already have.

Add a new SP Pile Cap Detail: Get SP pile cap information from AutoCAD drawing. The user can click “SP From CAD” button 2328 to import a SP pile cap from AutoCAD drawing. A new interface will pop-out, then input the layer names for pile cap, pile, wall or column, and find the dxf file name and location, then click “Continue” button to import the SP pile cap. Revise the SP pile cap, like change the pile orientation as required if the pile is HP type, input the new SP pile cap name at SP pile cap Drop-Down Menu 2327, click “Add” button 2329 to add new SP Pile Cap Detail.

The textbox next to Option PC1 to PC9, PC-A or SP is the pile cap angle 2330. The color of angle 2330 for current pile cap is shown as red. These angle textboxes 2330 have three functions: 1) Click the angle 2330 will make it as current pile cap. 2) Change the angle value 2330 and then press Enter, the angle will be changed. 3) Double-click the angle value, some angles will change automatically within 0 and 90, or within 0, 90, 180 and 270.

Click “ToPC” button 2331, SP Pile Cap Detail can be tranferred into regular pile cap 2302, or Click “ToPCA” button 2332, it will be transferred into PC-A pile cap 2303 if suitable.

Change Pile Cap Detail: Select the Pile Cap Detail in pile cap Drop-Down Menu 2312, 2323, 2327, change the pile space 2306, 2316, 2317, 2319 pile cap edge 2307, 2322, pile diameter D 2305 and pile type 2309, press Enter key at just changed button or textbox, or press Enter key at pile cap Drop-Down Menu 2312 for regular Pile Cap Detail, press Enter key at pile cap Drop-Down Menus 2323, 2327 for PC-A Pile Cap Detail 2303 and SP Pile Cap Detail 2304, the data of current and existing Pile Cap Detail will be changed. If click “Add” buttons 2313, 2325, 2329 at this time, a new Pile Cap Detail will be added. After changing a Pile Cap Detail, if there are some pile caps on plan which use the changed Pile Cap Detail, then they will be changed automatically.

Usually all Pile Cap Detail information will be saved when the user saves the AUD file, and when open the AUD file next time, all Pile Cap Detail information will be import again. But if the user wants specially to save all Pile Cap Detail information in a separate file, can click Export PC button 2333 to save it. After click Export PC button 2333, AUD program will ask the user for the file name and location to save it. In this way, another AUD file or another project can use it by clicking “Import” button 2334 to import it.

Add pile cap on plan: Select a pile cap option, can be regular pile cap 2310, PC-A pile cap 2315, or SP pile cap 2326. The user can change some data as required, check pile cap base as required if it is PC-A pile cap 2303 or SP pile cap 2304, click “Add PC” button 2335, click a point 2336 on plan, a pile cap 2337 is added on plan.

When click a point on plan to add pile cap, if the “Pt Snap” checkbox 2338 in FIG. 23B is checked, and the point is close to a structural item point 2336, the add point will snap to structural item point automatically. If the “Pt Snap” checkbox 2338 is not checked, then the add point 2336 can be at any location on plan.

Move the pile caps on plan with Left/Right Scroll Bar 2339 and Up/Dow Scroll Bar 2340: Click “Select” checkbox 2341 in FIG. 23B, select pile cap 2337 that needs to move, can click “Multi-Sel” checkbox 2342 to select more pile caps 2343, or click “WSelect” checkbox 2344 to window select more pile caps 2345, use Left/Right Scroll Bar 2339 and Up/Dow Scroll Bar 2340 to move the selected pile caps.

Screen move the pile cap on plan: Click “Scr Move” checkbox 2346 in FIG. 23B, click a pile cap 2337 that needs to move. Can click “Multi-Sel” checkbox 2342 to select more pile caps, keep mouse pressed, move mouse as required to move the selected pile caps, release the mouse to finish the movement. If part of the pile cap is out of slab, the solid lines of pile cap will be changed automatically after moving.

Change the Pile Cap Detail for the pile caps on plan: All pile caps use specified Pile Cap Details, and the user can change the Pile Cap Details. Select pile caps 2337, 2343, 2345 on plan which need to change, then select the Pile Cap Detail in pile cap Drop-Down Menu 2312, 2323, 2327 for regular pile cap, PC-A pile cap, or SP pile cap, press Enter key on pile cap Drop-Down Menu 2312, 2323, 2327 or on angle 2330 of selected Pile Cap Detail, the selected pile caps on plan will be changed to new Pile Cap Detail.

Change the pile space 2306, 2316, 2317, pile cap edge 2307, 2322, pile diameter D 2305, pile cap angle 2330 and pile type 2309 for the pile caps already added on plan: Select the pile caps 2337, 2343 which have same Pile Cap Detail name, change the pile space 2306, 2316, 2317 pile cap edge 2307, 2322, pile diameter D 2305, or current pile cap angle 2330, press Enter key, the data of the related Pile Cap Detail, called current Pile Cap Detail, will be changed automatically, and the selected pile caps 2337, 2343 on plan will be changed with the change of current Pile Cap Detail. If select pile caps are with different Pile Cap Detail names, then all selected pile caps will be the same as the new current Pile Cap Detail. If some other pile caps related the current Pile Cap Detail are not selected, then the data for the related Pile Cap Detail can not be changed because they are using it, then the invention will create a new Pile Cap Detail as new current Pile Cap Detail. The invention will set a name for regular Pile Cap Detail 2302 automatically, and ask the user to input the new name for PC-A Pile Cap Detail 2303 or SP Pile Cap Detail 2304, and the selected pile caps 2337, 2343 on plan will use new Pile Cap Detail.

Add pile caps for all columns on plan automatically: Click “Add Col PC” button 2347, the AUD program will find all column locations, required regular Pile Cap Details 2302 based on column force and pile capacity, and add regular pile caps 2302 for all columns on plan automatically.

Pile Cap Information table 2348 gives the user the information for all pile caps. “Type” 2349 is a number which means the type of pile cap. 1 to 9 are regular pile cap 2302, also indicate the pile number, 10 is the footing, 11 is PC-A pile cap 2303, 12 is SP pile cap 2304. Some data in the table can be changed, they are pile cap Depth 2350, Angle 2351, center Xc 2352 and Yc 2353. To change them, just change them and press Enter key. The user can find a pile cap on plan by find the pile cap in the table. For example, if the user needs to find a pile cap with pile cap order number 10. Click the “Select” checkbox 2341 in FIG. 23B, then click pile cap No.10 2354 in Pile Cap Information table 2348, the No.10 pile cap 2354 will be selected in the table, and the No.10 pile cap 2355 on plan will be selected too, it will be shown in red color on plan.

The pile caps are shown on plan usually as dash line. If whole pile cap is under the concrete slab, all pile cap lines will be shown as dash lines. If part of pile cap is not under concrete slab, then the lines of pile cap which are out of slab will be shown as solid lines. When add a pile cap on plan, the solid lines will be added automatically. When move the pile cap, the solid lines will be changed automatically.

Move pile cap to the center of column: If the columns or pile caps moved, click “MovetoColC” checkbox 2356, click a pile cap on plan 2337, AUD program will automatically move the pile cap so that the center of the pile cap will be on the center of column.

All pile caps on plan can be exported into AutoCAD drawings automatically.

In some embodiments, at 406, the method may include drawing and modifying shear wall plans automatically.

The implementation process of drawing and modifying the shear wall plans automatically include getting original shear walls from model plan of this AUD program or from AutoCAD drawing automatically, drawing and modifying the shear wall plans automatically.

The implementation process of getting original shear walls from the model plan of this AUD program or from AutoCAD drawing automatically is described below with the reference to FIG. 24A and FIG. 24B. FIG. 24A is a control operation interface used to place command buttons and item parameters related to get original shear walls from the model plan of this AUD program or from AutoCAD drawing automatically, according to some embodiments of the present disclosure. FIG. 24B is the main view interface of AUD program, the lower display area of FIG. 24B is the graphic display area showing columns and shear walls 2401, according to some embodiments of the present disclosure.

Get original shear walls from model plan part-wall by part-wall: Click “Get Shear Wall” checkbox 2402, click a FL cell 2403 in “Shear Wall Original FL and Wall No.” table 2404 to specify new shear wall location in the table 2404, click a part-wall 2405 of a shear wall in model plan, the selected part shear wall 2405 will be imported as a part-wall 2406 shown in FIG. 24A. Click another part-wall 2407 in model plan, the selected part shear wall 2407 will be imported. Continue to import all part-walls to import a whole shear wall.

Get original shear walls from model plan with window selection: Click “Get Shear Wall” checkbox 2402, click a FL cell 2403 in “Shear Wall Original FL and Wall No.” table 2404 to specify new shear wall location in the table, window select a whole shear wall 2408 in model plan by draw a box surrounding the whole shear wall 2408 on plan, whole shear wall 2408 will be imported with one time.

Get original shear walls from AutoCAD: Open AutoCAD program and show the shear wall in AutoCAD clearly. Check “Get Shear Wall” checkbox 2402 to make it checked, click a FL cell 2403 in “Shear Wall Original FL and Wall No.” table 2404 to specify new shear wall location in the table. Check the layer names 2409 in “Layer Name” table 2410, input the layer name 2409 as required. Click “SW from CAD” checkbox 2411, go to AutoCAD drawing again and click a point on AutoCAD drawing, then window select all part walls of a shear wall in AutoCAD drawing by draw a box on plan. Whole shear wall inside the box will be imported into AUD program.

Click “Show CenL” checkbox 2412, the obtained shear wall 2406 will show the center lines 2413. If the center lines 2413 are OK, then the shear wall 2406 is correct and ready to add reinforcement. If the center lines 2413 are not OK, then click “Wall Update” button 2414 to let AUD program modify it automatically. AUD program can cut and combine shear walls, as well as modify other data as required automatically, to make the shear walls correct and ready to add reinforcement. If some part walls are adjacent but not connected, AUD program can combine them automatically.

If the center lines are all OK, the user can go to next step, modify the shear walls in the interface “Shear Wall Detail” of FIG. 25. Click “Add Initial Bar Data for All Walls” button 2415 to let the shear walls have their initial bar data and other information, provide the initial drawings for shear wall plans automatically. The user can also add initial bar data in the interface “Shear Wall Detail” in FIG. 25.

The implementation process of drawing and modifying the shear wall plans automatically is described below with the reference to FIG. 25. FIG. 25 is a control operation interface “Shear Wall Detail” used to place command buttons and item parameters related to draw and modify the shear wall plans automatically, according to some embodiments of the present disclosure.

Assign Bar Number for Zone Bar: Click “Show BarN” checkbox 2501, the numbers for all zone bars will be shown at their locations 2502 on shear wall plan, change the zone bar number, and press Enter key, the zone bar number 2503 in shear wall plan will be changed. The bar number 2503 for Zone Bar here is not the zone bar number in zone bar callout 2504, it is the bar number 2503 shown in shear wall plan on the drawing.

Click “Select” checkbox 2512, select dimensions 2505, zone bulb line 2506, zone bar callout 2504, basic bar callout 2507, cross tie tag 2508, additional line 2509 and other items that need to move, can click “Multi-Sel” checkbox 2513 to select more items, use Left/Right Scroll Bar 2510 and Up/Dow Scroll Bar 2511 to move the selected items. If zone bar callout text 2515 is selected only, when move zone bar callout 2504, the connect line 2516 between zone bar callout 2504 and the bulb 2517 will not follow. If the user wants the connect line 2516 to follow, then select the connect line 2516 together with zone bar callout text 2515.

For a basic bar callout 2507, the user can select callout text or callout line to move. If selecting the text is not easy, the user can click “Frame” checkbox 2514 to show the frame for text. Then it will be easy to select the text by click the frame.

Screen move dimensions 2505, zone bar bulb line 2506, zone bar callout 2504, basic bar callout 2507 and cross tie tag 2508: Click “Scr Move” checkbox 2518, select items that need to move, can click “Multi-Sel” checkbox 2513 to select more items, keep mouse pressed, move mouse as required to move the selected items, release the mouse to finish the movement. If zone bar callout text 2515 is selected only, when move zone bar callout 2504, the connect line between zone bar callout text 2515 and bulb 2517 will follow, even the connect line 2516 is not selected. If the user wants to move zone bar callout text 2515 only, please use Left/Right Scroll Bar 2510 and Up/Dow Scroll Bar 2511 to move.

Move zone bar bulb 2517 with Left/Right Scroll Bar 2510 and Up/Dow Scroll Bar 2511: Click “SelectBulb” checkbox 2519, select a bulb 2517 that need to move, can click “Multi-Sel” checkbox 2513, to select more bulbs, use Left/Right Scroll Bar 2510 and Up/Dow Scroll Bar 2511 to move the selected bulbs.

Screen Move Zone Bar Bulb: Click “SelectBulb” checkbox 2519, click “Scr Move” checkbox 2518, select a bulb that need to move, can click “Multi-Sel” checkbox 2513 to select more bulbs, keep mouse pressed, move mouse as required to move the selected bulbs, release the mouse to finish the movement.

Delete items on shear wall plan: Click “Select” checkbox 2512, select items that need to delete, can click “Multi-Sel” checkbox 2513, and then select more items, click “Del Sel” button 2520 to delete selected items. To select Zone Bar Bulb 2517, please click “SelectBulb” checkbox 2519 first.

Delete Zone Bar Bulb 2517 by change the zone bar number: Click Show “BarN checkbox” 2501, the numbers for all zone bars will be shown at their locations 2502, change the zone bar number to be less than zero for zone bar bulb 2517 which the user need to delete, then press Enter key, the zone bar bulb 2517 will be deleted.

Restore the Zone Bar Bulb 2517: Click Show “BarN” checkbox 2501, the numbers for all zone bars will be shown at their locations 2502, change the zone bar number for zone bar bulb 2517 which the user need to restore, change it to a number that is 0 or greater than 0, and then press Enter key, the zone bar bulb 2517 will be restored. If a bulb is for additional zone bar 2521, the user can restore the bulb 2521 by adding the additional bar again.

Assign the content of Zone Bar Callout 2504 with “From To” table 2521: Click “Select” checkbox 2512, select zone bar callout 2504 that need to assign, can click “Multi-Sel” checkbox 2513 to select more zone bar callouts. If selecting zone bar callout 2504 is not easy, the user can click “Frame” checkbox 2514 to show the frame for text, then it will be easy to select zone bar callout 2504 by click the frame, the zone bar information for selected zone bar callout 2504 will be shown in “From To” table 2521 located at right side near bottom, can retype the zone bar information to change. The user can click “Insert A Row” button 2522 to insert a row, or click “Delete A Row” button 2523 to delete a row, press Enter key on keyboard to finish the new zone bar callout assignation.

Assign the content of Zone Bar Callout 2504 on screen: Retype the zone bar information in “From To” table 2521. The user can click “Insert A Row” button 2522 to insert a row, or click “Delete A Row” button 2523 to delete a row, click “Assign” checkbox 2524, click zone bar callout 2504 in shear wall plan one by one to assign zone bar callout 2504.

Change the basic bar callout text 2507 directly: Double-click basic bar callout text 2507 shown on shear wall plan. The text 2525 will be shown in red color, change the basic bar callout text 2525, and then press Enter key or click another point 2526 on screen. The basic bar callout will be changed.

Reverse wall number order and center line number order: Click “Reverse Order” button 2527 to reverse wall number order and center line number order, click “Show CenL” checkbox 2528 to show center lines, click “Show Cent N” checkbox 2529 to show the center line numbers, or click Show “SW N” checkbox 2530 to show wall point numbers. The user may uncheck “Text” checkbox 2531, “Frame” checkbox 2514, “Show Dim” checkbox 2532, “Show Bar” checkbox 2533 and “Show Other” checkbox 2534 to turn them off, to show the wall point numbers clearly. The wall dimension location will change after reverse order.

Add a line: Sometimes the user may need to add a line in shear wall plan for dimension or locate the additional zone bar, click “Add Line” checkbox 2535, click two points on shear wall plan, a line is added.

Copy a line: Copy a line is another method to add a line, click “Copy Line” checkbox 2536, check or input the copy distance 2537, click a line to select it as copy source. The selected line will be shown in red color, click the location where the user wants add a line, a new line will be copied to there.

Change concrete cover T for part walls individually: Click “Show Cover” checkbox 2538, the concrete covers for all part walls will be shown, change the value for concrete cover on plan and press Enter key, the concrete cover for a single part wall will be changed.

Usually, the zone bars are located at the ends of walls, which are called basic zone bars, and are added by the AUD program automatically. The user can add a zone bar at some location elsewhere, like in the middle of the part wall. This zone bar is called as additional zone bar.

Add additional zone bar: Use “Add A Line” or “Copy A Line” method described above to add a line, click “Add ZoneBar” checkbox 2539, select a line 2509 which will be shown in red color, click the new zone bar location next to selected line, the new additional zone bar 2521 will be added next to selected line 2509 automatically.

Add cross tie callout: Click “Add CTieTag” checkbox 2540, click a cross tie 2541 in zone bar area, click another location where the added cross tie callout 2508 will be locate, the cross tie callout 2508 is added. The user can move and modify it easily.

Change Cross Tie Direction: Double-click the Cross Tie 2542, the direction of cross tie 2542 will be changed.

Change Cross Tie Callout: Double-click cross tie callout text 2508 shown on shear wall plan, the text 2508 will be shown in red color, change the cross tie callout text 2508, and then press Enter key or click another point on screen, the cross tie callout 2508 is changed.

Add Dimension: All normal dimensions are added by AUD program automatically. The user can add additional dimension: Click “Add Dim” checkbox 2543, click first point for dimension, click second point for dimension, then click the new dimension location, the new additional dimension is added.

Change the wall length by move the center line points: Click “SelectPt” checkbox 2544, select some points 2545, 2546 on shear wall center lines by click them or use window select method to select them, use Left/Right Scroll Bar 2510 or Up/Dow Scroll Bar 2511 to move the selected points. The related shear wall length will be changed. Can change the one-time move distance in the textbox 2547 to get exact wall length.

Change wall thickness: Double-click wall thickness value 2548 shown on shear wall plan, the value will be changed in red color, change the wall thickness 2548, and then press Enter key or click another point on screen, the wall thickness 2548 will be changed.

The AUD program can get the shear wall rebars from the results of Etabs. The implementation process of getting the shear wall rebars from the results of Etabs is described below with the reference to FIG. 25 and FIG. 26. FIG. 26 is a control operation interface used to place command buttons and item parameters related to get the shear wall rebars from the results of Etabs, according to some embodiments of the present disclosure.

Get Etabs Rebar for shear walls: In program Etabs, export e2k file, export Shear Wall Pier Design Summary as txt file. Click “Browse” button 2601 in FIG. 26 to select Etabs e2k File, click “Browse” button 2602 to select Etabs SW Rebar txt File, click “GetEtabsBar” button 2603 to get shear wall rebars from Etabs.

Get Etabs Rebar for the wall shown in the user interface “Shear Wall Detail” in FIG. 25 by select part-wall: Click “WaSelect” checkbox 2604 in FIG. 26, click first Pier Number 2605, this Pier Number 2605 will be the selected one shown in red color, indicate it is current one, select a part-wall 2606 in FIG. 25, the Etabs rebar will be shown under first Pier Number 2605. Click second Pier Number 2607, this Pier Number 2607 will be the selected one shown in red color, select another part-wall 2608, the Etabs rebar will be shown under second Pile Number 2607. If two walls are in different directions and connected at their ends, total rebar for these two ends will be obtained and shown under “CombPt” 2609 automatically, “FaCombPt” 2610 is equal to “Fa*CombPt” and will be shown too.

Get Etabs Rebar for the wall shown in the user interface “Shear Wall Detail” in FIG. 25 by select a point of part-wall: Click “PtSelect” checkbox 2611, select a point 2612 in a shear wall in FIG. 25, the Etabs rebar for two part-walls will be shown under first Pile Number 2605 and second Pier Number 2607. If two part-walls are connected to the selected point 2612, the total rebar for these two ends will be shown under “CombPt” 2609. “FaCombPt” 2610 will be shown too.

Get Etabs Rebar for the wall shown in the user interface “Shear Wall Detail” in FIG. 25 by selecting a point of part-wall with up/down scroll bar 2613: Input number in Wall Pt N textbox 2614, and press Enter key in keyboard, or click the up/down scroll bar 2613 next to Shear Wall Pt N 2614, then the Etabs rebars for the part-walls, which are connected this point, will be shown in “SW Rebars from Etabs” table 2615. If two walls are in different directions and connected at their ends, total rebar for these two ends will be shown under “CombPt” 2609. “FaCombPt” 2610 will be shown too.

In some embodiments, at 408, the method may include drawing and modifying plan rebars automatically.

The implementation process of drawing plan rebars automatically is described below with the reference to FIG. 27A and FIG. 27B. FIG. 27A is a control operation interface used to place command buttons and item parameters related to draw and modify plan rebars automatically, according to some embodiments of the present disclosure. FIG. 27B is the main view interface of AUD program, the lower display area of FIG. 27B is the graphic display area showing columns, walls, and rebars 2701, according to some embodiments of the present disclosure.

There are five kinds of rebars, that is X Top Bar 2702, Y Top Bar 2703, Bottom Bar 2704, Hook Bar 2705 and Bi-Hook Bar 2706. AUD program can add them on plan automatically.

Add X Top Bar 2702 and other bars: Click “AddBar” checkbox 2707 in X Top Bar frame 2702, click a point on plan, the X Top Bar 2708 is added. If the “Pt Snap” checkbox 2709 in FIG. 27B is checked, when the click point on plan is close to column center, the add point will snap to column center automatically, so the rebar will be added at the column center. If the “Pt Snap” checkbox 2709 is not checked, then the rebar can be added at any location on plan. The user can add other four kinds rebars with similar method.

When add Hook Bar 2705, and “Pt Snap” checkbox 2709 in FIG. 27B is checked, the added Hook Bar 2705 can be in two situations, one is perpendicular to slab edge when option “Perpend to Edge” 2713 is selected, and another one is vertical or horizontal when option “Ortho Mode” 2714 is selected. If “Pt Snap” checkbox 2709 on plan is not checked, Hook Bar angle will take the value shown in Hook Bar “Angle” textbox 2715.

If “SelAdd” checkbox 2716 in FIG. 27B is checked, the added rebar will be selected automatically when the user adds rebar on plan, then the user can revise or move the added rebar immediately.

Add rebars on all columns and walls automatically: Click “Auto Add All Bars” button 2717, AUD program will add some rebars automatically on all columns 2718 and walls 2719. The added rebars include X Top Bar 2702, Y Top Bar 2703 and some Hook Bar 2705. The centers of rebars added will be on the centers of columns or wall center line points. If there is bar size 2720 in X Top Bar frame 2702, then this bar size will be used for all added X Top Bars 2702. If the bar size 2720 in X Top Bar frame 2702 is empty or zero, then the bar sizes of all added X Top Bars 2702 will be calculated by AUD program based on “Slab T” 2721 and “Load” 2722. If “Auto BarL” checkbox 2723 is not checked, the X Top Bar 2702 length will adopt the length as shown in length textbox 2724. If “Auto BarL” checkbox 2723 is checked, the X Top Bar 2702 length will be calculated automatically based on column spacing. Y Top Bar 2703 will get the bar sizes and length in the same way. In the direction perpendicular to slab edge, if the column is closed to slab edge, AUD program will add Hook Bar 2705, otherwise AUD program will add X Top Bar 2702 or Y Top Bar 2703.

When add rebar on plan, the rebar 2725 and bar tag 2726 are all added together on plan automatically. The bar tag 2726 can be shown in one line or two lines as the user like and it can be changed easily. When assign the bar length, the content in bar tag 2726 and the real bar length 2725 shown on plan will be both updated automatically. When the content in bar tag 2726 is changed, the real bar length 2725 shown on plan will be modified automatically.

Rebar select method: Click “Select” 2727 checkbox FIG. 27B, select the rebar on plan, can click “Multi-Sel” checkbox 2728, and then select more rebars, or click “WSelect” checkbox 2729 and then window select more rebars.

There are many parameter assign methods shown as below. When select the rebar tag, maybe it is not easy to select it. The user can click “Frame” checkbox 2730 in FIG. 27B to show the frame for text. Then it will be very easy to select rebar tag by click the frame.

Rebar parameter assign method 1, by select bars and press Enter on keyboard. Can be used for: 1) X Top Bar length, Angle, Xc, Yc, rebar size, 2) Y Top Bar length, angle, Xc, Yc, rebar size, 3) Bottom Bar length, angle, Xc, Yc, bebar size, 4) Hook Bar L1, L, angle, Xc, Yc, rebar size Hook Dir, 5) Bi-Hook Rebar length, angle, Xc, Yc, rebar size. The assign details are (Take X Top Bar length 2724 as example): Select X Top Bar or X Top Bar tag that needs to assign, retype X Top Bar length 2724 in X Top Bar frame 2702 as required, press Enter at the X Top Bar length 2724, the lengths for all selected X Top Bars will be assigned, and the drawings on plan will be modified automatically.

Rebar parameter assign method 2, by select bars and click “Assign Selected” button 2731 or assign on screen. Method 2 can assign several rebars and several parameters in one time and can be used for: 1) X Top Bar length, angle, Xc, Yc, rebar size and tag line, 2) Y Top Bar length, angle, Xc, Yc, rebar size and tag line, 3) Bottom Bar length, angle, Xc, Yc, rebar size and tag line, 4) Hook Bar L1, L, angle, Xc, Yc, rebar size Hook Dir and tag line, 5) Bi-Hook Bar length, angle, Xc, Yc, rebar size, tag line. Double-click on the parameters that the user needs to assign, like X Top Bar length 2724, Double-click the X Top Bar length value 2724, then the value color will be changed to red, indicating X Top Bar length is in assign situation. The user can select more parameters to assign. If the user wants to assign the Bottom Bar size 2732, Double-click the Bottom Bar size value 2732, then the value color will be changed to red. The user can select the rebars that need to assign, change the assign parameters as required, click “Assign Selected” button, the selected rebars will be assigned. Or click “ScrAssign” checkbox 2733 in FIG. 27B, then click the rebars on plan one by one to screen assign the rebars.

Rebar parameter assign method 3, by use the rebar length and size Table 2734. Method 3 can be used for: 1) X Top Bar length and size, 2) Y Top Bar length and size, 3) Bottom Bar length and size, 4) Hook Bar length L and size, 5) Bi-Hook Bar length and size. On the user interface “Plan Rebar” in FIG. 27A, there is a Table 2734 that includes “L(ft)” 2735 and “Bar” 2736. “L(ft)” 2735 is the rebar length, and “Bar” 2736 is the rebar size. Check this Table 2734 if it has the rebar length 2735 and rebar sizes 2736 as need. If there is no rebar length 2735 or rebar size 2736 the user need, just change any one of them. The assign details are: Select the rebars 2737 on plan that need to assign, click the rebar length 2735 or rebar size 2736 in the Table 2734, all rebar lengths or rebar sizes of all selected rebars will be assigned.

Rebar parameter assign method 4, by select and scroll bar. Method 4 can be used for: 1) X Top Bar length, 2) Y Top Bar length, 3) Hook Bar length L, 5) Bi-Hook Bar length. The assign details are: Select the rebars 2737 that need to assign, there are scroll bars 2738, 2739, 2740, 2741 for X Top Bar length, Y Top Bar length, Hook Bar length L and Bi-Hook Bar length in their frames separately, just click one of them as the user needs. That is, if the user needs to change X Top Bar length 2724, then click the scroll bar 2738 in X Top Bar frame 2702 to change the X Top Bar length 2724. The rebar length is increased or decreased with 6″ by 6″.

Rebar parameter assign method 5, by select rebars and click text “Angle”. Method 5 can be used for: 1) X Top Bar angle 2742, 2) Y Top Bar angle 2743. The purpose of this method is to change the rebar tag location by changing the rebar angle from 0 to 180 or from 180 to 0 degree. The assign details are: Select the rebars that needs to assign new angle, click the text “Angle” 2742, 2743 in X Top Bar frame 2702 or Y Top Bar frame 2703, the angles of selected rebars are changed, so the rebar tag locations are changed.

Rebar parameter assign method 6, by select and click text “Tag Line”. Method 6 can be used for: 1) X Top Bar tag line, 2) Y Top Bar tag line, 3) Bottom Bar tag line, 4) Hook Bar tag line, 5) Bi-Hook Bar tag line. The assign details are: Select the rebars or rebar tags that need to assign, click the text “Tag Line” 2743, 2744, 2745, 2746, 2747 in their frames, the tag lines of selected rebars are changed, can be one or two.

Rebar parameter assign method 7, by select and click text “Hook Dir” 2748. Method 7 can be used for Hook Bar 2705. The assign details are: Select the Hook Bar on plan that needs to assign, click the text “Hook Dir” 2748 in the Hook Bar frame 2705, the hook directions of selected Hook Bars are changed.

Move Rebars on plan with Left/Right Scroll Bar 2748 and Up/Dow Scroll Bar 2749 in FIG. 27B: Select rebars that need to move, use Left/Right Scroll Bar 2748 and Up/Dow Scroll Bar 2749 to move selected rebars.

Screen move rebars on plan: Click “Scr Move” checkbox 2750 in FIG. 27B, click a rebar that needs to move, can click “Multi-Sel” checkbox 2728 to select more rebars, keep mouse pressed, move mouse as required to move the selected rebars, release the mouse to finish the movement.

Delete Rebars: Select rebars that needs to delete, click “Del Sel” button 2751 in FIG. 27B to delete selected rebars. Or click “ScrDelete” checkbox 2752, then click a rebar that needs to delete, can use window select method to delete the rebars, not required to click “WSelect” checkbox 2729.

Click “Scr AutoAssign BarL” checkbox 2753, click the X Top Bar or Y Top Bar on plan, the clicked top bar will be assigned with a length calculated by AUD program based on column spacing automatically.

Top Bar usually located on plan with its center on the column center, so there are two spans for top bar on each side of column. Click “Scr Adjust BarL” checkbox 2754, and then click two end points of these two spans, the top bar located on the column center will be assigned with a length calculated by AUD program based on the length of these two spans automatically.

Usually the center of the rebar is on the center of column. Sometime, for some reason, the column or rebar moved. The invention can move rebars so that the centers of the rebars are on the centers of columns automatically. Click the “BarToCnt” checkbox 2755, click the rebar that needs to move to column center, the rebar will move so that the center of the rebar is on the center of column. “XY” in the textbox 2756 means to move rebar in both X, Y directions. Can double click XY to change to X or Y. X means to move rebar in X direction only. Y means to move rebar in Y direction only.

Click the “Align All Bar to Col” button 2757, all rebars will move so that the centers of the rebars are on the centers of columns.

Get rebar from Safe Model: In Safe Model, get the bar area file, including Concrete Slab Design Summary 01—Flexural and Shear Data, and Span Definition Data. Click “Browse” button 2758 to select this bar area file, click “GetRebar” button 2759 to get strip bar area from Safe model. Then the AUD program can show the rebars of Safe model results on the plan, and make the plan rebars based on Safe model results.

If the “StripFig” checkbox 2760 is checked, AUD program will show the strip bar area figure for X Top Bar, Y Top Bar, X Bottom Bar or Y Bottom Bar, depend on which checkbox is checked.

If the “BarArea” checkbox 2761 is checked, AUD will show the bar area value for X Top Bar, Y Top Bar, X Bottom Bar or Y Bottom Bar, depend on which checkbox is checked. Top bar is total additional bar area for a point required and based on basic bar reinforcement. Bottom bar is for each strip's additional bottom bar area.

Usually, the concrete slab reinforcements include basic rebars and additional rebars. The structural drawings usually show the additional rebars only on the plan. The user can change the basic rebars, then the additional rebars shown on the plan will be changed automatically.

Click “BarApply” checkbox 2762 to update the final top bars and bottom bars for CAD drawing automatically based on Safe model results.

If “Safe” checkbox 2763 is checked, AUD will give out the bar numbers just based on the Safe model value. If this “Safe” checkbox 2763 is not checked, then AUD will give out the bar numbers based on the Safe model values and min bar number. Min bar number is the number shown in Bar Size textbox 2720, 2764, 2732, 2765, for top bar and bottom bar. If the bar number based on the Safe model is less than the min bar number 2720, 2764, 2732, 2765, then AUD will use min bar number.

In some embodiments, at 410, the method may include drawing CAD beam, column above-below symbols, column number symbols, section symbols, different elevation symbols automatically.

The implementation process of drawing CAD beam, column above-below symbols, column number symbols, section symbols, different elevation symbols automatically is described below with the reference to FIG. 28A and FIG. 28B. FIG. 28A is a control operation interface used to place command buttons and item parameters related to draw CAD beam, column above-below symbols, column number symbols, section symbols, different elevation symbols automatically, according to some embodiments of the present disclosure. FIG. 28B is the main view interface of AUD program, the lower display area of FIG. 28B is the graphic display area showing columns, walls, CAD beams, column above-below symbols, column number symbols, section symbols, and different elevation symbols 2801, according to some embodiments of the present disclosure.

The AUD program can add column above-below symbols 2802, column number symbols 2803, section symbols 2804, different elevation symbols 2805 on plan automatically. After adding them, the user can move, modify them easily and automatically, including the texts of column number symbols 2803, texts in section symbols 2804, and texts in different elevation symbols 2805.

Usually the beams shown in FSDT and AUD programs are used for model calculation programs, such as Etabs and Safe, called model beams. CAD beams 2806 are the beams drawn in structural CAD drawings specially. The model beam is shown as one line, the CAD beam 2806 is shown with two lines or more. The user can add CAD beams 2806 on the plan automatically.

Add a CAD beam with point to point: Click “Point to Point” checkbox 2807, select a beam size in beam size Drop-Down Menu 2808, check or input the beam extension EX1 2809 and EX2 2810, click two points on plan, a CAD beam 2811 is added on plan in FIG. 28B.

Add a CAD beam with point to wall: Click “Point to Wall” checkbox 2812, select a beam size in beam size Drop-Down Menu 2808, check or input the beam extension EX1 2809 and EX2 2810, check or uncheck the Auto Trim checkbox 2813 as required, select perpendicular 2814 or 2nd Pt 2815, click a point on plan first, then click a line on wall 2816 or slab edge. A CAD beam 2817 perpendicular to the clicked line or with an angle will be added. If the Auto Trim checkbox 2813 is checked, the added CAD beam 2817 will be trimmed automatically based the line the user clicked.

When adding CAD beam 2806, it is just to add a line on plan, which is called base line 2818 of CAD beam 2806. AUD program transfers this baseline 2818 into CAD beam 2806 automatically. The base line 2818 can be a center line 2819 of CAD beam 2806 or edge 2820 of CAD beam 2806. If it is edge 2820 of CAD beam 2806, it can be one of two long beam edge lines. “Dir” value 2821 determines which line of CAD beam 2806 the base line 2818 represents.

In AUD program, the user can add extensions in both ends of a CAD beam 2806. Ex1 2809 is the left side extension of the CAD beam 2806, Ex2 2810 is the right side extension of the CAD beam. The user can change the length values of Ex1 2809 and EX2 2810 by retype them and press Enter key, or use left/right scroll bar 2822, 2823 to change them. When add a CAD beam 2806 on plan, the beam length is not determined by beam length L, it is determined based on the points the user selected for adding beam. After adding CAD beam 2806, the beam length is still not changed by changing beam L, the user can use Ex1 2809 or Ex2 2810 to change the beam length. In this way, the user can determine which end of the beam to move to get beam length changed.

Select CAD beams: Click “Select” checkbox 2824 in FIG. 28B to select CAD beam, can click “Multi-Sel” checkbox 2825, then select more CAD beams 2811, 2817. Or click “WSelect” checkbox 2826 and then window select more CAD beams 2827, 2828.

Change CAD beam length with scroll bar: Select CAD beams 2811, 2817, if click the scroll bar 2822 below EX1 2809, the left end of CAD beams 2811, 2817 will move, if click the scroll bar 2823 below EX2 2810, the right end of CAD beams 2811, 2817 will move, thus the beam length changed.

CAD Beam Trim: Click “Trim checkbox” 2829, select a line on plan, the selected line will be shown in red. If no suitable line to select, the user can add line first, then select it, or click “Two Points” checkbox 2830 and then draw a line with 2 points, click the beam part that the user wants to erase out to finish the trim. If the trim line is drawn after click “Two Points” checkbox 2830, the trim line will be deleted automatically after trim is done.

Trim beam with Pile Cap: Click “Trim Bm/Pile Cap” checkbox 2831, click a pile cap on plan, the pile cap will be shown in red, click the beam part that is cross over the pile cap, this part will be trimmed out. Or click the beam part that is inside of the pile cap, this part of beam will be trimmed out.

The column number symbol here is different from the column number used in model, which is a real column number and usually used in the structural model. Column number symbol here is the column number shown in structural drawings, can be called as “CAD Column Number”. Its value is called as CAD number. CAD numbers for column number symbols and the column numbers for structural model can be same or different.

Add column number symbols on plan: Click “Select” checkbox 2824 in FIG. 28B, select a column 2832 which needs to add column number symbol 2803, the user can click “Multi-Sel” checkbox 2825, and then select more columns 2833, or click “WSelect” checkbox 2826 and then window select more columns, check DX 2834, DY 2835 and Dia values 2836 to make sure they are all correct, click “Add” button 2837 to add column number symbols 2838, 2839 for selected columns 2832, 2833. The added column number symbols 2838, 2839 will have the CAD numbers same as column numbers for structural model. If select all columns on plan, then the user will add column number symbols for all columns on plan with one time.

Select column number symbols. Click “Select” checkbox 2824 in FIG. 28B, click column number symbol to select it, can click “Multi-Sel” checkbox 2825 then select more column number symbols, or click “WSelect” checkbox 2826 and then window select more column number symbols.

Assign the column number symbols to be same as column numbers for structural model: Select column number symbols 2838, 2839, click “Assign ColN” button 2840, the CAD numbers for selected column number symbols 2838, 2839 will be same as column numbers in structural model.

Change the column number symbols: Click “Select” checkbox 2824 in FIG. 28B, click the column number symbol 2838 on plan to select it. The column CAD number will be shown in the first textbox 2841 for “ColN”, type a new column CAD number in second textbox 2842, press Enter key, the column CAD number of selected column number symbol will be changed.

Assign CAD numbers to column numbers: Select column number symbols 2838, 2839, click “CAD ColN to Col” button 2843, the CAD numbers of selected column number symbols 2838, 2839 will be assigned to the column numbers for structural model.

“Col Above-Below” symbol 2802, “Section” symbol 2804 and “Different Elev” symbol 2805: Column above-below symbol 2802 has two directions, above and below. Section symbol 2804 has parameters: angle, direction of section, “SizeScale”, section number and sheet number in section. “Different Elev” symbol 2805 is a symbol for different top of slab elevation. “Different Elev” symbol 2805 has parameters: angle, direction “Dir”, “SizeScale”, “ElevDe” and others.

Add column above-below symbols 2802, section symbols 2804, different elev. symbols 2805 on plan: If “SelAdd” checkbox 2844 is checked when the user add these items on plan, the added items will be selected automatically after adding them, then the user can revise or move items immediately. Details to add these items are: Click “Add” checkbox 2845, 2846, 2847, like add column above-below 2802, then just click “Add” checkbox 2845 in “Col Above-Below” frame 2802, check all information shown for column above-below symbols 2802, section symbols 2804, and different elev. symbols 2805 are correct, click a point on plan, the item 2848, 2849, 2850 will be added. The angle of section and different elev. will be determined by AUD program automatically based on the slab edge line near click point.

Select items for column above-below symbol, section symbol and different elev. symbol: Click “Select” checkbox 2824 on plan Manu Bar, click an item 2848, 2849, 2850 on plan to select it, can click “Multi-Sel” checkbox 2824 then select more items, or click “WSelect” checkbox 2826 and then window select more items.

Assign parameters by select and press Enter key on Keyboard, the items can be: 1) Column above-below “SizeScale”, 2) Section angle, “Sec. No”, sheet, “SizeScale”, DA1 and DB1, 3) CAD number DX, DY and Dia, 4) Different elev. angle, “SizeScale”, L, H1, H2 and “ElecDe”, 6) CAD beam size, Ex1, Ex2, angle and TxtSize. The assign details are (Take Sec. No of section as example): Select items 2848, 2849, 2850 on plan that need to assign, retype the value of selected items, like “Sec. No” 2851 in “Section” frame 2804 as required, press Enter key at just typed location, the value of the selected items will be changed.

Screen assign parameters. Assign the parameters on the screen directly and it is to assign the parameters one item by one item. Can assign several parameters in one time and can be used for: 1) Column above-below:SizeScale”, 2) Section angle, “Sec. No”, sheet, “SizeScale”, DA1 and DB1, 3) Column number DX, DY and Dia, 4) Different Elev. angle, “SizeScale”, L, H1, H2 and “ElecDe”, 5) CAD beam size, Ex1, Ex2, angle and TxtSize. The assign details are:

Step 1: Double-click on the parameters that the user wants to assign, like “Sec. No” 2851 of section, double-click the “Sec. No value” value 2851, then the value color will be changed to red. The user can select more parameters. If the user wants to assign the “Sheet” 2852 of section 2804 too, double-click the “Sheet” value 2852, then the value color will be changed to red. Double-click on the parameter again, the parameter will become a non-assign parameter, the value color will be changed to black.

Step 2: Click “ScrAssign” checkbox 2853 in FIG. 28B, click the items on plan one by one to assign new parameters to them.

Change the direction of items by select and click text “Dir”, can be used for column above-below “Dir” 2854, section “Dir” 2855 and different elev. “Dir” 2856. The step details are (Take section “Dir” 2855 as example): Select the section 2849 on plan that need to assign, click the text “Dir” 2855 in the section frame 2804, the “Dir” 2855 of selected section 2849 is changed.

Move Items with Left/Right Scroll Bar 2857 and Up/Dow Scroll Bar 2858 in FIG. 28B: Select items 2811, 2848, 2849, 2850 that need to move, use Left/Right Scroll Bar 2857 and Up/Dow Scroll Bar 2858 to move the selected items.

Screen move Items. Click “Scr Move” checkbox 2859 in FIG. 28B, select items 2811, 2848, 2849, 2850 that need to move, keep mouse pressed, move mouse as required to move the selected items, release the mouse to finish the movement.

In some embodiments, at 412, the method may include drawing and modifying Typical Pile Cap Details automatically.

The implementation process of drawing and modifying Typical Pile Cap Details automatically is described below with the reference to FIG. 29. FIG. 29 is a control operation interface used to place command buttons and item parameters related to draw and modify Typical Pile Cap Details automatically, the lower display area of FIG. 29 is the graphic display area 2901, according to some embodiments of the present disclosure.

In the user interface “Foundation” of AUD in FIG. 23A, the user can make some Typical Pile Cap Details and add pile caps on plan. Here it is to drawing the Typical Pile Cap Details in AutoCAD automatically, including regular pile caps, PC-A pile caps and SP pile caps. When open this user interface “Pile Cap Detail” as shown in FIG. 29, the user can see all Typical Pile Cap Details already there, including the pile cap dimensions. AUD program can make these details in CAD drawings automatically. Then the user can just modify them in this user interface, and export the Typical Pile Cap Details into AutoCAD drawing.

Click “OneCap” checkbox 2902 in FIG. 29 to check it, then click one Typical Pile Cap Detail in the plan 2901, the clicked Typical Pile Cap Detail will be moved to the center of the graphic display area 2901, and is shown with a certain scale, so that it is shown clearly in the plan.

Move whole pile cap, dimension line and text, wall center line text, pile tag, pile cap tag and other items with Left/Right Scroll Bar 2903 Up/Dow Scroll Bar 2904: Click “Select” checkbox 2905, click an item to select it, if click “Multi-Sel” checkbox 2906, then the user can select more items. Use Left/Right Scroll Bar 2903 to move the selected items left or right, use Up/Dow Scroll Bar 2904 to move selected items up or down. The user can change a value on textbox 2907 as to change the moving speed.

Screen move whole pile cap, dimension line and text, wall center line text, pile tag, pile cap tag and other items: Click “Scr Move” checkbox 2908, click the item to select it, if click “Multi-Sel” checkbox 2906, then the user can select more items, keep mouse pressed, move mouse as required, the selected items will move as the user move the mouse, release the mouse to finish the movement.

Add Pile Tag: Check the horizontal line length “DL” 2909 of pile tag, change it as required, click “Add Pile Tag” checkbox 2910, click a pile 2911 in pile cap, click another point around pile cap 2912, a new pile tag 2913 is added. Only one pile tag 2913 can be added for one pile cap 2912. If you add another pile tag for a pile cap 2912, the first one will be deleted automatically.

Add wall center line and modify it: Click “Add WCnt” checkbox 2914, then click a point 2915 at inside of the wall, a wall center line 2916 is added. Use the left Left/Right Scroll Bar 2917 to move the first point of wall center line to change the length, use the right Left/Right Scroll Bar 2918 to move the second point of wall center line 2916 to change the length.

The regular dimensions of pile cap are given out by AUD program automatically. There are two kinds of dimensions, one 2919 is for pile cap 2920 and another one 2921 is for piles 2922. The dimensions can be on both sides of pile cap 2920 or only on one side of pile cap 2920. Click “Dim Sides” checkbox 2923, then click the dimension for pile cap or piles, if the dimension is originally shown on one side, then the dimensions will be shown on both sides. If the dimensions are originally shown on both sides, then it will be shown on one side. Click “Dim Loc” checkbox 2924, then click the dimension for pile cap or piles, the dimension location will change from one side to another side of pile cap 2920.

Delete and add a dimension point in dimension line: Click “Del Dim Pt” checkbox 2925, click a point 2926 in dimension line, the dimension point will be deleted. Click “Add Dim Pt” checkbox 2927, click a dimension line 2921 of pile cap or piles, the dimension 2921 will be selected, click a point on pile center or pile cap, the dimension point 2926 will be added.

Add additional dimensions for Typical Pile Cap Details: Click “Add Dim” checkbox 2928, click two points in pile cap to find two points for dimension, click another point to put new added additional dimension.

The user can add dimensions from a pile to the edge of pile cap for SP pile cap. Click “Add Edim” checkbox 2929, click a point 2930 on screen between the pile and the edge of pile cap, a new additional dimension 2931 from a pile to the edge of pile cap is added.

Move individual dimension lines or original points in whole dimension: Click “Select” checkbox 2905, click “DimL” checkbox 2932 if move dimension lines 2933, click “DimPt” checkbox 2934 if move original points 2935, select an individual dimension line 2936 in whole dimension, a red circle will be shown to indicate the selected individual dimension 2936. If click “Multi-Sel” checkbox 2906, then can select more dimensions, click Left/Right Scroll Bar 2903 and Up/Dow Scroll Bar 2904 to move selected individual dimension lines 2933 or dimension original points 2935.

What is claimed is:

1. An automatic method for designing and drawing a building structure, implemented by operating a graphical display interface for displaying drawing results, a control operation interface operatively coupled with the display interface for displaying parameters and commands, function keys, and receiving user operation commands, and a processor operatively coupled with the control operation interface for performing automatic processing of structural design and model establishment, and producing a construction drawing, wherein the method comprises:
step 1: retrieving information of structural items and other non-structural items from architectural drawings, adding FL Lines and base points automatically, wherein the structural items comprises grid lines, columns, walls, beams, floor slabs, slab opens, and drop panels, and non-structural items comprise stairs, elevators, and CMU walls;
step 2: editing the structural items and adding loads automatically, wherein the editing of the structural items comprises automatic addition and modification of the columns, walls, beams, floor slabs, slab opens, and drop panels, comparison and adjustment of columns between associated floors, and the loads comprise floor loads, line loads, and point loads on the slabs and beams;
step 3: exporting a whole building calculation model data file for an Etabs program, and floor data file for a Safe program automatically, wherein the Etabs and Safe programs can import the calculation model data file and run the model immediately to obtain calculation results, and if the calculation results meet a predetermined standard, skipping step 4 and performing step 5, otherwise performing step 4;
step 4: adjusting and editing the structure items according to the calculation results, and repeating the step 3;
step 5: designing and checking all column capacities for whole building with slenderness considered automatically in FSDT, and making column schedule automatically with AUD program;
step 6: based on Safe results, designing beams and making floor framing plans automatically, including CAD beams and slab reinforcement with AUD program;
step 7: based on Etabs results, designing foundation automatically, including pile cap and footing, and making a foundation plan drawing with AUD program automatically;
step 8: adding and modifying column above-below symbols, section symbols, CAD beams, column number symbols, different elevation symbols automatically with AUD program;
step 9: based on Etabs results, designing shear walls and making shear wall plans automatically with AUD program; and
step 10: preparing and modifying a CAD drawing for Typical Pile Cap Details automatically with AUD program;
step 11: exporting special architectural items as a background of a structural drawing automatically to obtain the completed structural drawing, wherein the special architectural items comprise columns, walls, slabs, opens, Stair, and CMU walls;
Step 12: displaying or printing the structural drawings.

2. The method of claim 1 wherein:
in all user interfaces of FSDT and AUD programs, all order numbers for items including button, checkbox and others can be shown with one click and found by a user in a manual of the programs easily, the order numbers of the items in the manual are same as in the user interfaces of FSDT and AUD, in the same way, the user can find where the items on the interfaces of FSDT and AUID programs based on the order numbers in the manual.
in FSDT and AUD programs, all command buttons and the parameters of structural items are put in one special user interface so that they can be always seen and clicked immediately when needed; at this time, a main drawing layout can be placed on a main monitor, and a user interface dedicated to placing command buttons and parameters can be placed on another monitor;
when adding a column or beam, section definition, when needed, is produced automatically and no longer required in FSDT and AUD programs; to add a beam with FSDT program, the user only needs to open a beam interface, and confirm or input the beam width, beam height, dead load, and live load, then add the beam on plan automatically; the beam section dimensions and parameters are always shown in the interface; column, walls and pile cap can also be added in the same way without loads, and a definition of the pile cap can be made automatically during the process of addition.

3. The method of claim 1, further comprising:
obtaining structural items from the architectural drawing into FSDT and AUD programs automatically, wherein the obtaining step comprises:
reading the contents of AutoCAD architectural drawing files; selecting one structure item in a floor of the architectural drawing and clicking the “Add” function key to automatically obtain the structural items of this type with the same layer for all floors in the architectural drawings; selecting all other types of structures in the architectural drawings in sequence, and automatically obtaining all information on all types of structures on all floors in the architectural drawings; if a structure item has more than one CAD layer, selecting each layer of the structure item in the architectural drawings to automatically obtain the information of a structure item for all CAD layers in the architectural drawings;
automatically saving all AutoCAD layer names for all structural items and parameter information; so that when some structural items are changed in the architectural drawings next time, the user can just import the architectural drawings again, and obtain structural items from architectural drawings, and the structural model is automatically generated immediately based on the saved AutoCAD layer names and parameter information;
showing the saved all AutoCAD layer names for all structural items and other parameters in some special tables so that the user can change the layer names, delete and add the layer names directly, change some parameters, and change and control the final structural items, wherein the FSDT program can save the layer names for different projects and different situations;
adding a virtual floor FL0 at the coordinate origin and base points in all real floors and in FL0, when transferring the structural items in the architectural drawing to the structural drawing, moving the structural items of all real floors according to the relationship between each floor base point and the FL0 base point, so that all the base point positions of the real floor are the same as the FL0 base point, the real floors are moved to near the coordinate origin, and all floors are automatically aligned up and down;
selecting multiple straight lines around the open location in sequence on the graphical user interface and clicking the “Add Open” function key to automatically add a rectangular slab open in the area surrounded by the selected straight lines;
or, in the alternative, inputting the CAD layer names for columns, walls and other structural items which are in architectural drawings, importing structural floor data from architectural drawings directly and automatically, wherein the user needs to make a special AutoCAD drawing, called FSDT drawing, which includes all structural items and some necessary information, and the user needs to add FL lines and base points for each floor, and then using FSDT program to import the FSDT drawing to make FSDT model directly.

4. The method of claim 1, further comprising:
drawing and modifying columns automatically, wherein the drawing and modifying comprise:
adding columns, transferring columns to walls, finding and deleting duplicate columns automatically; changing the column sizes, moving columns, and deleting columns automatically; assigning column numbers with a predetermined rule automatically for one floor and all floors, wherein the column numbers can be reordered automatically;
showing columns and walls above or below so that the user can compare the columns for two floors, check whether the column is continuous to go or stop at a floor and whether the columns are aligned or not, to find pick-up columns; and the user can match all column centers of one floor to another floor, and match all column sizes of one floor to another floor;
after getting the columns from architectural drawings, clicking a button to use the columns below for current floor or all floors automatically.

5. The method of claim 1, further comprising:
drawing and modifying walls automatically; wherein the drawing and modifying comprise:
adding wall with two methods, one being to input X and Y coordinates of a wall in the Wall Point Table, and the other being to input a wall center line and a thickness in Wall Line Table;
connecting some lines which are not connected together to form real walls automatically when importing walls from architectural drawing;
after getting the walls from the architectural drawing, clicking a button to use the walls below for current floor or all floors automatically;
inputting wall numbers, wall thickness, then clicking a button to assign the wall thickness, or assign the wall thickness on the screen by clicking one wall by one wall; and
correcting the walls for some mistakes automatically, cutting the shear walls into some part-walls automatically, importing into Etabs model to meet calculation requirements, combining walls automatically if they are next to each other, and cutting a wall automatically if another wall is connected to this wall in the middle to allow two walls to connect together.

6. The method of claim 1, further comprising:
drawing and modifying beams automatically, wherein the drawing and modifying comprise:
clicking a button to add edge beams around the perimeters of slabs which are composed of all Non-Roof-Sub-Slabs and on parapets automatically, and importing interior beams from AutoCAD drawings or adding the interior beams by FSDT program, wherein the edge beams are used for line loads of exterior walls around the perimeters of building;
clicking two points on the screen to add beams and adding the beam size and load together at the same time automatically;
changing or assigning the beam sizes and loads on beams with beam property table or screen assigning automatically, connecting the beams together at cross point by cutting the beams, extending beams, dividing a long beam into short beams as required, and trimming the beams with pile cap and footing automatically;
producing an Interior Beam Table wherein the user can see the beam properties for all added interior beams in the Table, including beam label, beam mark, beam size, and beam loads, and the user can change the beam properties by retyping them in the table; and
clicking a button to show the columns and walls above the current floor on plan to help the user to add a beam for pickup column or wall easily, and assigning the beam line load based on the wall force at the specified floor.

7. The method of claim 1, further comprising:
drawing and modifying slabs automatically, wherein the drawing and modifying comprise:
separating Slab0 (whole one floor concrete slab) into Sub-Slab based on their different thickness or different loads, wherein Slab Open is also considered as Sub-Slab, and the slab properties comprise slab coordinates, thickness, dead load DL, live load LL, and slab type, and the slab type comprises Etabs, Safe, Both, Etabs Open, Safe Open, Both Open, and None, wherein None means that the slab is not in Etabs and Safe, and Slab0 is always None and cannot be changed;
adding point loads on floor slab for above columns automatically and getting Slab0 automatically;
selecting one or more slabs, clicking Slab Type Drop-Down Menu to assign slab type, and retyping slab T. DL, LL in Slab Property Table as required to assign new slab properties on selected slabs or using Slab Property Assign on screen method;
clicking “SlabTag Locate” button to locate the slab tag location automatically, selecting one or more Sub-Slab, and using Left/Right Scroll Bar and Up/Dow Scroll Bar to move the slab tag.

8. The method of claim 1, further comprising:
drawing and modifying drop panels automatically, wherein the drawing and modifying comprise:
checking and changing values of DX1, DX2, DY1, DY2, and angle as required, clicking “Add Drop Panel” checkbox, then clicking a column or a point on plan, so that a new drop panel with predetermined data is automatically added; if the click point is near edge of slab, or near slab open, then the added drop panel is cut automatically, or in the alternative, adding all drop panels on all columns automatically just with one clicking;
selecting drop panels, or drop panel edge lines on plan, using Left/Right Scroll Bar and Up/Dow Scroll Bar as shown in in FIG. 15A to move the selected drop panels or drop panel edge lines;
adjusting drop panel sizes DX1, DX2, DY1, and DY2, selecting some drop panels on plan, and changing these sizes so that the sizes of selected drop panels on plan are automatically updated; or, in the alternative, screen assigning the drop panel; or clicking “Scr Adjust DXDY” checkbox, and clicking two related columns on plan so that the drop panel sizes are automatically adjusted based on the column spacing; and
if some drop panels are not automatically adjusted based on slab edge and opens, then clicking “Drop Panel Update” button to adjust drop panels based on slab edges and opens automatically.

9. The method of claim 1, further comprising:
setting up Ready-to-Run Etabs and Safe models automatically, wherein the setting up comprises:
after finishing all columns, beams, walls, slabs, and other structural items, assigning all deal loads, live loads, wind load and seismic load, point loads, line loads and surface loads, concrete strength, making load combinations, then FSDT program will setup Ready-to-Run Etabs model and Safe models automatically; exporting e2k File for Etabs model and f2k File for Safe model; importing into the Etabs program the e2k file and running the model immediately; importing into the Safe program the f2k file and running the model immediately;
automatically segmenting all concrete shear walls according to the segment length requirements determined by the user; aligning all wall segments for all floors of the building, and importing the aligned wall segments into Etabs program;
adding pier number of walls and elevation views at all pier loacations for Etabs program automatically; and
getting column forces, wall reactions, wall reinforcement and slab reinforcement from Etabs and Safe programs.

10. The method of claim 1, further comprising:
designing and checking concrete columns one by one automatically, wherein the designing and checking comprise:
obtaining column sizes, column lengths, and column forces for all columns and all floors of whole building from FSDT model; filling the data in the form automatically; inputting concrete strength and other column design information, then designing and checking the columns with slenderness considered; changing the column size, rebar size, column length, and concrete strength, and producing the results immediately; checking the columns one by one, or checking all columns together; when checking a column, causing the results in the table and Column Capacity Graph to be shown immediately; and
keeping some previous column design data when obtaining new column numbers due to column layout changes; after finishing the column design and check, exporting all data required for the column schedule to an Excel file; then making column schedule based on the excel file with AUD program.

11. The method of claim 1, further comprising:
making AutoCAD column schedule automatically, wherein the making comprises:
reading the Column Excel File, making column schedule in AutoCAD drawing automatically; separating the column schedule into two or more column schedules if the column schedule is too long;
changing the parameters that control the column schedule by retyping their value except floor height which is determined by real floor height imported in column schedule data from Column Excel File; and
inputting the “Top Foundation FL” by clicking the Floor Drop-Down Manu, wherein in each foundation floor, if there is a column that starts at this floor, then there will be a heavy line shown in column schedule which indicates the bottom of column, and top foundation floor is the floor with highest elevation in the floors in which there are pile caps or footings;
wherein sheet “FLElev” in Column Excel File has 5 excel columns that are Order, “Floor”, “Height”, “fc” and “FL Name in Model”;
sheet “AllFL” in Column Excel File has “Col N” and “Col Load” Columns first, and these two Excel columns are used to put the column loads in Column Schedule, and then has 4 excel columns for each floor, that is “Col N”, column section width “B”, column section height “H”, and reinforcement “Rebar”, wherein these 4 excel columns are for concrete column data of one floor, but only typical floor column data are required to put here.

12. The method of claim 1, further comprising:
obtaining structural drawing information from FSDT program and the architectural drawings, wherein the obtaining comprises:
obtaining in the FSDT and AUD programs columns, walls, beams, slabs and other structural items from architectural drawings not only for FSDT model, Etabs and Safe models, but also for structural drawings; and obtaining special items, which are not the structural model items and are not required to be imported into Etabs and Safe models, but will be shown in structural drawings, wherein the FSDT and AUD programs export these architectural items into AutoCAD, to be an architectural background of the structural drawing (ABG);
importing the FSDT file into AUD program so as to obtain columns, walls, beams, slabs, and other structural drawing information from the FSDT program;
selecting any ABG item in the architectural drawing, then clicking the related “add” button in ABG Layer frame as shown in FIG. 22B, adding the item information with the same layer on all floors in the building into the ABG Drawings; or, in the alternative clicking ABG item checkbox, then clicking an item which belong to clicked ABG item (like column) in the architectural drawing, and adding all items which have same layer with clicked ABG item (like column) into ABG Drawings.
saving all AutoCAD layer names for ABG drawings so that next time when some items in architectural drawings are changed, the user can just import the architectural drawings again, and obtain ABG drawings from architectural drawings immediately and automatically;
saving all AutoCAD layer names for an ABG drawing shown in some special tables, wherein the user can change the layer names, delete and add the layer names directly, and change and control the final ABG drawing; wherein the FSDT and AUD programs can save the layer names as a ABG layer group for different projects and different situation with a different ABG layer group name;
clicking “Export to File” button to export the ABG drawing as an AutoCAD dwg file which can be opened by AutoCAD taken as an attached file of the structural drawing; wherein if “Col Below” checkbox is checked, the columns and walls below for each floor will be exported when exporting the ABG drawing.

13. The method of claim 1, further comprising:
making Typical Pile Cap Details and adding pile caps on plan automatically,
wherein there are three kinds of pile caps: regular pile cap that is normal pile cap PC1 to PC9; PC-A pile cap, the pile cap that has piles with regular columns and rows; SP pile cap, special pile cap with any pile number, and the piles can be at any location, and wherein the parameters of pile cap include pile number, pile diameter, pile space, the edge of pile center to pile cap, and cap depth and pile type which can be Round or HP shape;
wherein the making Typical Pile Cap Details and adding pile caps on plan automatically, comprise;
making the Typical Pile Cap Details for regular pile cap, PC-A pile cap and SP pile cap automatically; changing some parameters of pile cap; and adding Typical Pile Cap Details for regular pile cap, PC-A pile cap and SP pile cap into their three pile cap Drop-Down Menus to save them;
selecting one Pile Cap Detail in three pile cap Drop-Down Menus, changing the pile space, pile cap edge, pile diameter D and pile type, pressing Enter key at just changed button or textbox, or pressing Enter key at pile cap Drop-Down Menu for regular Pile Cap Detail, pressing Enter key at pile cap Drop-Down Menu for PC-A Pile Cap Detail and SP Pile Cap Detail, so that the data of current and existing Pile Cap Detail is automatically changed;
selecting a pile cap option of regular pile cap, PC-A pile cap, or SP pile cap, changing some data as required, checking pile cap base as required if it is PC-A pile cap or SP pile cap, clicking “Add PC” button, clicking a point on plan, so that a pile cap is automatically added on plan;
clicking “Add Col PC” button, wherein the AUD program can find all column locations, required regular Pile Cap Details based on column force and pile capacity, and adding regular pile caps for all columns on plan automatically;
selecting the pile caps on plan, then selecting the Pile Cap Detail in three pile cap Drop-Down Menus, pressing Enter key on pile cap Drop-Down Menu or on angle of selected Pile Cap Detail so that the selected pile caps on plan is automatically changed to new Pile Cap Detail;
selecting the pile caps on plan, changing the pile space, pile cap edge, pile diameter D, or pile cap angle, pressing Enter key, so that the data of the related Pile Cap Detail is automatically changed, and the selected pile caps on plan is automatically changed with the change of related Pile Cap Detail;
selecting pile caps on plan, using Left/Right Scroll Bar and Up/Dow Scroll Bar to move the selected pile caps, or screen moving the pile caps;
obtaining SP pile cap from AutoCAD drawing; transferring SP pile cap into regular pile cap or PC-A pile cap, if suitable;
changing pile cap Depth, Angle, center Xc and Yc in the Pile Cap Information table, and pressing enter key to update the pile caps on plan with these new data, wherein the Pile Cap Information table gives the user the information for all pile caps on plan;
if whole pile cap is under the concrete slab, then showing all pile cap lines as dash lines; if part of pile cap is not under concrete slab, then showing the lines of pile cap which are out of slab as solid lines; wherein when adding the pile cap, the solid lines are added automatically; and wherein when moving the pile cap, the solid lines are changed automatically; and
if the columns or pile caps moved, clicking “Moveto ColC” checkbox, then clicking a pile cap on plan to move automatically, so that the center of the pile cap is on the center of column.

14. The method of claim 1, further comprising:
getting original shear walls from the model plan of this AUD program or from AutoCAD drawing automatically, wherein the getting comprises:
clicking “Get Shear Wall” checkbox as shown in FIG. 24A, clicking a FL cell in “Shear Wall Original FL and Wall No.” table to specify new shear wall location in the table, clicking a part-wall of a shear wall in model plan as shown in FIG. 24B, so that the selected part shear wall is automatically imported, or window selecting a whole shear wall in model plan by drawing a box surrounding the whole shear wall on plan, so that whole shear wall is automatically imported;
opening the AutoCAD program, checking “Get Shear Wall” checkbox, clicking a FL cell in “Shear Wall Original FL and Wall No.” table to specify new shear wall location, inputting the layer name as required; clicking “SW from CAD” checkbox, going to AutoCAD drawing again and clicking a point on AutoCAD drawing, then window selecting all part walls of a shear wall so that whole shear wall inside the box. is imported into AUD program automatically; and
clicking “Show CenL” checkbox as shown in FIG. 24A, showing the obtained shear wall with the center lines; wherein if the center lines are acceptable, then the shear wall is correct and ready to add reinforcement; clicking “Wall Update” button to let AUD program cut and combine shear walls, modifying other data as required automatically, to make the shear walls correct and ready to add reinforcement.

15. The method of claim 1, further comprising:
drawing and modifying the shear wall plans automatically, wherein the drawing and modifying comprises:
clicking “Show BarN” checkbox as shown in FIG. 25 to show the numbers for all zone bars on shear wall plan as show in FIG. 25, changing the zone bar number, and pressing Enter key so that the zone bar number in shear wall plan is changed and the basic rebars and the dimensions are automatically changed, wherein the bar number for Zone Bar here is the bar number shown in shear wall plan on the drawing and not the zone bar number in zone bar callout;
selecting dimension, zone bulb line or whole bulb, zone bar callout, basic bar callout, cross tie tag, additional line, and other items, using Left/Right Scroll Bar and Up/Dow Scroll Bar to move the selected items; or clicking “Scr Move” checkbox, then screen moving these items;
clicking “Frame” checkbox to show the frame for text, and then selecting the text easily by clicking the frame;
clicking “Select” checkbox, selecting items that need to delete, clicking “Del Sel” button to delete selected items;
selecting zone bar callouts to show the zone bar information for selected zone bar callout in “From To” table, retyping the zone bar information to change, clicking “Insert A Row” button to insert a row, or clicking “Delete A Row” button to delete a row, pressing Enter key to finish the new zone bar assignation for selected zone bar callouts; or clicking “Assign” checkbox, then clicking zone bar callout in shear wall plan one by one to screen assign zone bar callout;
double-clicking basic bar callout text or cross tie callout text shown on shear wall plan as shown in FIG. 25, the text is automatically shown in red color, and changing the callout text and then pressing Enter key or clicking another point on screen so that the basic bar callout or cross tie callout text is changed;
clicking “Add Line” checkbox, clicking two points on shear wall plan, so that a line is automatically added; or clicking “Copy Line” checkbox, checking or inputting the copy distance, clicking a line to select it as copy source, and clicking the location where to add a line so that a new line is copied there;
clicking “Show Cover” checkbox to show the concrete covers for all part walls, changing the value for the concrete cover on plan and pressing Enter key so that the concrete cover for a single part wall is automatically changed;
using “Add A Line” or “Copy A Line” method to add a line, clicking “Add ZoneBar” checkbox, selecting the line whose color is changed to red, and clicking the new zone bar location next to selected line so that the new additional zone bar next to selected line is automatically added;
clicking “Add CTieTag” checkbox, clicking a cross tie in zone bar area, and clicking another location so that the cross tie callout is added; double-clicking the Cross Tie, so that the direction of cross tie is changed;
clicking “Add Dim” checkbox, then adding additional dimension, wherein all normal dimensions are added by AUD program automatically,
clicking “SelectPt” checkbox, selecting some points on shear wall center lines by click them or use window select method to select them, and using Left/Right Scroll Bar and Up/Dow Scroll Bar to move the selected points so that the related shear wall length is changed and changing the one-time move distance in the textbox to get exact wall length;
double-clicking wall thickness value shown on shear wall plan, the color of value is changed to red, changing the wall thickness, and then pressing Enter key or clicking another point on screen so that the wall thickness is changed;
clicking one “Browse” button as shown in FIG. 26 to select Etabs e2k File, clicking another one “Browse” button to select Etabs SW Rebar txt File, and clicking “GetEtabsBar” button to get SW Rebars from Etabs.
clicking “WaSelect” checkbox as shown in FIG. 26, selecting first Pier Number as shown in FIG. 26 as current one, selecting a part-wall as shown in FIG. 25, so that the Etabs rebar is shown under first Pier Number; selecting second Pier Number as current one, selecting another part-wall, so that the Etabs rebar is shown under second Pile Number; if two walls are in different directions and connected at their ends, so that the total rebar for these two ends are obtained and are shown under “CombPt” automatically, wherein “FaCombPt” is equal to “Fa*CombPt” and is shown too;
clicking “PtSelect” checkbox, selecting a point in a shear wall as shown in FIG. 25, so that the Etabs rebars for two part-walls are shown under first Pier Number and second Pier Number; if two part-walls are connected to the selected point, so that the total rebar for these two ends are shown under “CombPt”, “FaCombPt” is shown too; and
inputting number in Wall Pt N textbox as shown in FIG. 26, and pressing Enter key in keyboard, or clicking the up/down scroll bar next to Shear Wall Pt N textbox, then the Etabs rebars for the part-walls, which are connected to this point, are shown in “SW Rebars from Etabs” table.

16. The method of claim 1, further comprising:
drawing and modifying plan rebars automatically, wherein there are five kinds of rebars comprising X Top Bar, Y Top Bar, X Bottom bar, Hook Bar and Bi-Hook Bar, and wherein the drawing and modifying comprise:
selecting a rebar type as shown in FIG. 27A, X Top Bar, Y Top Bar or others, confirming the parameters of rebar, clicking “Add Bar” checkbox, then clicking on the plan, so that the rebar and its bar tag are added automatically, wherein the added Hook Bar is perpendicular to slab edge, vertical or horizontal, or with an angle taking the value shown in Hook Bar “Angle” textbox;
wherein if “SelAdd” checkbox in FIG. 27B is checked, the added rebar is selected automatically when the user adds rebar on plan, then the user can revise or move the added rebar immediately;
clicking “Auto Add All Bars” button, wherein the AUD program adds some rebars automatically on all columns and walls, and the added rebars comprise X Top Bar, Y Top Bar, and some Hook Bar, the centers of rebars added are on the centers of columns, the bars size is determined by the user or calculated by AUD program based on slab thickness and load, the bar length is determined by the user or calculated by the AUD program based on column spacing; if the column is near slab edge, the Hook Bar is added automatically based on the distance from the column to slab edge;
wherein the bar tag is shown in one line or two lines based on the user's preference and can be changed; when assigning the bar length, the content in bar tag and the real bar length shown on plan are both updated automatically; when the content in bar tag is changed, the real bar length shown on plan is modified automatically;
selecting rebars on plan, retyping bar length, angle, Xc, Yc, bar sizes, and other bar parameters as required, pressing Enter key, wherein the bar parameters in FIG. 27A are assigned, and the drawings on plan are modified automatically;
double-clicking on the parameters as shown in FIG. 27A that the user needs to assign, wherein the parameters comprise X Top Bar length, the value color of the parameter is changed to red, indicating that the parameter is in status to be assigned, and the user can select more parameters;
selecting the rebars on plan that need to assign and changing the assign parameters as required, clicking “Assign Selected” button, wherein the selected rebars are assigned; or clicking “ScrAssign” checkbox as shown in FIG. 27B, clicking the rebars on plan one by one to screen assign rebars;
selecting the rebars on plan that need to assign, clicking the rebar length or rebar size in the Table, wherein all rebar lengths or rebar sizes of selected rebars are assigned, and the Table comprises “L(ft)” and “Bar”, wherein “L(ft)” is the rebar length, and “Bar” is the rebar size;
selecting X Top Bar, Y Top Bar, or Hook Bar on plan, clicking their length scroll bars as shown in FIG. 27A to change their bar length, clicking the text “Hook Dir” in Hook Bar frame to change the hook direction of selected Hook Bars;
selecting rebars, using Left/Right Scroll Bar and Up/Dow Scroll Bar to move selected rebars, or clicking “Scr Move” checkbox as shown in FIG. 27B, then screen moving the rebars on plan;
clicking “Scr AutoAssign BarL” checkbox, clicking the X Top Bar or Y Top Bar on plan, wherein the clicked top bar is assigned with a length calculated by the AUD program based on column spacing automatically; or, in the alternative, clicking “Scr Adjust BarL” checkbox, then clicking two end points of two spans for a column, wherein the top bar located on the column center is assigned with a length calculated by AUD program based on the length of these two spans automatically;
obtaining the bar area file from Safe model, clicking “Browse” button to select this bar area file, clicking “GetRebar” button to get strip bar area from Safe model, then the AUD program shows the rebars of Safe model results on the plan, and making the plan rebars based on Safe model results;
showing the Safe strip bar area figure for X Top Bar, Y Top Bar, X Bottom Bar or Y Bottom Bar, if the “StripFig” checkbox is checked;
wherein AUD shows the Safe bar area value for X Top Bar, Y Top Bar, X Bottom Bar or Y Bottom Bar, if the “BarArea” checkbox is checked, top bar is total additional bar area for a point required and based on basic bar reinforcement, bottom bar is for each strip's additional bottom bar area, and the user can change the basic rebars, then the additional rebars shown on the plan are changed automatically; and
clicking “BarApply” checkbox to update the final top bars and bottom bars for CAD drawing automatically based on Safe model results.

17. The method of claim 1, further comprising:
drawing CAD Beam, column above-below symbols, column number symbols, section symbols, different elevation symbols automatically, wherein the drawing comprises.
clicking “Point to Point” checkbox, selecting a beam size in beam size Drop-Down Menu, checking or inputting the beam extension EX1 and EX2, clicking two points on plan, wherein a CAD beam is added on plan automatically, or, in the alternative, clicking the “Point to Wall” checkbox to add a CAD beam with a similar method;
wherein the base line of CAD beam is a center line of CAD beam or edge of CAD beam;
adding extensions in both ends of a CAD beam, wherein EX1 is the left side extension of the CAD beam, and EX2 is the right side extension of the CAD beam, retyping them and pressing Enter key to change the length values of EX1 and EX2, or using left/right scroll bar to change them, wherein the CAD beam length can be changed by using EX1 or EX2;
selecting columns which need to add column number symbols, checking DX, DY and Dia values to make sure they are all correct, clicking “Add” button in “CAD Column Number” frame as shown in FIG. 28A to add column number symbols for selected columns;
selecting column number symbols, clicking “Assign ColN” button, wherein the CAD numbers for selected column number symbols become column numbers in structural model;
selecting a column number symbol, wherein the column CAD number is shown in the first textbox for “ColN” as shown in FIG. 28A, typing a new column CAD number in second textbox, pressing Enter key, wherein the column CAD number of selected column number symbol is changed;
clicking “Add” checkbox in “Col Above-Below” frame as shown in FIG. 28A, checking all information shown for column above-below symbol, clicking a point on plan, wherein a column above-below symbol is added automatically, adding section symbols, different elevation symbols with same way, wherein the angles of section symbol and different elev. symbol are determined by AUD program based on the slab edge line near click point automatically;
selecting items on plan that need to be assigned, retyping the value of selected items as required, wherein the selected items comprise “Sec. No” in “Section” frame, pressing Enter key at just typed location, wherein the value of the selected items is changed automatically;
double-clicking on the parameter that the user wants to assign, wherein the parameter can be “Sec. No” of section, the value color is changed to red, indicating that the corresponding parameter is in status to be assigned, clicking “ScrAssign” checkbox as shown in FIG. 28B, clicking the items on plan one by one to assign new parameters to them;
selecting the section on plan that need to assign, clicking the text “Dir” in the section frame so that the “Dir” of selected section is changed, and changing the direction of column above-below “Dir” and different elev. “Dir” with same way; and
selecting items that need to move, using Left/Right Scroll Bar and Up/Dow Scroll Bar to move the selected items; or clicking “Scr Move” checkbox in FIG. 28B, then screen moving the items.

18. The method of claim 1, further comprising:
drawing and modifying Typical Pile Cap Details automatically, wherein the drawing and modifying comprises:
making Typical Pile Cap Details for regular pile caps, PC-A pile caps and SP pile caps in CAD drawings automatically;
clicking “OneCap” checkbox in FIG. 29 to check it, then clicking one Typical Pile Cap Detail in the plan, wherein the clicked Typical Pile Cap Detail is moved to the center of the graphic display area, and is shown with a certain scale, so that it is shown clearly in the plan;
selecting whole pile cap, dimension line and text, wall center line text, pile tag, pile cap tag and other items, using Left/Right Scroll Bar and Up/Dow Scroll Bar to move the selected items, or, in the alternative, clicking “Scr Move” checkbox, then screen moving the selected items;
checking the horizontal line length “DL” of pile tag, changing it as required, clicking “Add Pile Tag” checkbox, clicking a pile in pile cap, clicking another point around pile cap, wherein a new pile tag is added automatically, click “Add WCnt” checkbox, then clicking a point at inside of the wall, wherein a wall center line is added automatically, using the left Left/Right Scroll Bar to move the first point of wall center line to change the length, using the right Left/Right Scroll Bar to move the second point of wall center line to change the length;
wherein the regular dimensions of pile cap are given out by AUD program automatically, wherein dimensions are on both sides of pile cap or only on one side of pile cap, clicking some buttons to change the situation;
clicking “Del Dim Pt” checkbox, clicking a point in dimension line, wherein the dimension point is deleted, clicking “Add Dim Pt” checkbox, clicking a dimension line of pile cap or piles, wherein the dimension is selected, clicking a point on pile center or pile cap, wherein the dimension point is added;
clicking “Add Edim” checkbox, clicking a point on screen between the pile and the edge of SP pile cap, wherein a new additional dimension from a pile to the edge of pile cap is added automatically;
clicking “DimL” checkbox, then moving individual dimension line with Left/Right Scroll Bar and Up/Dow Scroll Bar; click “DimPt” checkbox, then moving individual original points of dimension.

19. A non-transitory machine-readable storage medium storing instructions which, when executed, cause a processing device to implement the method of claim 1.

20. A system, comprising:
a memory; and
a processing device communicably coupled to the memory, wherein the memory storing instructions which, when executed, cause the processing device to implement the method of claim 1.
